SEQUENCE LISTING (33 sequences)

SEQ ID NO: 1 - DNA, 8763 bp, Homo sapiens
  CDS (593)...(2185)
gcgatgctcggggaaagcaggaccccaaagccccgtaaacaccgcgcgaccacccgggccaagatcttcaagaggttcttttcagaaggatcggagagcaattcccgattggtagaagaacttgctgtaatacacacgtactctgacgaccccgccccaacgactagcccctcctctgtgcaaccccgagagtttggggtcatgcagggggcgccacgagctcgtttcggaagccggaccccgcccgcagccgcagaagcctcgagtccacatctgggtctctaaagtctcgccgtagccagatcccggatccccaccttcttcaccagttcccgggcgtcctccaggcattggcgaggcagcctgtcaatcaggagctcgggcggcagccccccgcgcgggggctcggcgatgccagcctcagcgacaggcggcggcggcggcggccacggcacagacacacaccctcccacacgcgcgcaccagggcagacccggcgggcaggcggcggaggcaccctcggagcccggcgcccggcggggaggggacgtgctccgagggaccggccccgaggcgccggatggaggaagagatgcagccggcagaggaggggcccagcgtccccaaaatctacaagcagcgcagcccctacagcgtcctcaagacgttccccagcaagagaccggcgctggccaagcgctacgagcgacccaccctggtggagctgccgcacgtgcgggcgcccccgccgcccccgccgcccttcgcgccgcacgccgccgtctccatcagcagcagcgagccgccgccgcagcagttccaggcgcagagctcctacccccccgggcccggccgggccgccgccgccgcttcgtcgtcgtcgccgtcctgcacgcccgccacatcccagggccacttgaggactccggcgcagccgccgcccgcgtcccccgccgcctcctcgtcgtcttcgttcgccgctgtcgtcaggtatggcccaggcgcggcggcggccgccggcaccggcggcacgggtagcgacagcgccagcctggagctcagcgcagagagtcgaatgatcttggatgcctttgcccagcagtgcagtcgagttcttagcctcttaaattgtggaggaaaactcctggactccaaccattctcagtccatgatttcttgcgtaaagcaggaaggctcaagttacaacgaaagacaggagcactgtcacattgggaaaggggtccacagtcagacctcagacaatgtagacatagagatgcagtatatgcaaaggaaacaacaaacttctgcctttttgagggttttcactgactctctacaaaattacctgctctcgggaagctttccaactccaaacccctcgtcagccagtgaatatggccatctggccgacgtggatcctctgtcaacctctcctgtgcatacattaggtggctggacttccccagcaacgtccgaatcccatggccacccatcttcatctacactgccagaagaggaggaggaggaggacgaggaaggctattgtcctcgatgccaagagctggagcaggaggttatttcactgcaacaagaaaatgaagagctcagaaggaaattagagagcatcccagtgccctgccagaccgttttagattacttgaagatggttctgcagcaccacaaccaactcctgataccacagccagctgaccagccgacagagggaagcaagcagctgttgaacaactatcctgtctacataacgagcaaacagtgggatgaggctgtaaattcttcaaagaaagatgggagacggctccttcgatacctcatcagatttgttttcacaaccgatgagcttaagtactcatgcggccttgggaaaaggaaaaggtcagtgcagtcaggagagacaggtcccgaaagacgccctctggatccagttaaagtaacatgcctccgagaattcattaggatgcattgtacctccaaccccgattggtggatgccctcggaagagcagataaacaaagtgttcagcgacgctgtcggtcacgcccgacaggggcgggcggtggggactttcctgcacaacggtggctcattttatgaagggatcgatcaccaggcttctcaggatgaagtcttcaataaaagttcccaggatggatctggggattagtggacagaatcttcctgttgtagcagctggtcctctcaagagttccaattgtgaatgtcctgttcctgtcacctgagagtccaaagcctgtcattctgccatagtctacacattctcagctgccacagtacccaaatagaaatccattttagggttgtttgggaagtctgtggcacctacaacagacttttggaatattatattataaaaagaaaaaactacatctgatttttaaatgattactagctagatcatgagggtgaaaaaataggtgagctcctagttacctttctgaaatcttcaaactctgctacctgggcagagatagtccccaaggtaggctggggtagtgtttctgcccatgggagaaggtggagacatggagttgtgttaagggacaagaagcaaacattctcttaattcaaataagttgtctttatgttttccaaagacttgacttcatatttctcggcaaagacataggatagatgacatcatataccattttgacattaataatgtctattactaaaaggaaaccagagaacagaggcaacatctgcagacagtgattaattacaggtcaactgtttttctgttgtttaaaaaccactgtgttgatcaagaaggcactatttgatctctggagtttacaaacagtagtcatttttcattgttagtcaagaaacatccaaagatccaaaaccattttcaaatgctcagttttgtaggttaataaatccgcagtttccatagccttaaatcaggctttgttgacacaatgccaaagtgatgggtagaacaatgaaaatttaaagcaattagttgtttggtgcactgaagaccaaacaagtggtgtgactgatggtattcgctgaattgactagatgttctggcattgtatacacacagcttcaaggcgattctgacaactatgcaatgggcttgtcagtaattgctctgaaatttgagggtctttctctgctgagctgatctttagaatttgtatgaaacttgtttcccattgtccttgatgaaaacatttcatcccctccgtgcctcctttaccccaatgtaccccttagctatggctaagtcagcactgtgccgctatcccctggttaatttgttgagttccatatgtgaaattagtggtatctttggaaactttccatattggcaaatgctatagaggtgctagagtcatcatttctgagggcttcctgtttggactcaggagaggctttctttaccaaactagtccagattactacattctttgtagagcaaagggctaaatggacagcgtttattgaaggctactaatgtcatctacagacatgaccaagggtttttgaaaattggttggagattcaggttaatgagcatccattgataaagggtttttgggctatttttgtcaacataaactcataaattgtcctttagatttaatatttagtttgtattcactatatacaaagtcctagaaacaggtctttctgtagcttttgtttattagcttttttgtattactagaattcatccattgaaaagtttaatgtttatggaggtggtcatctgtcagatctgctcaatgatgtagtgggcactaatatttcaatcctgttttgagaaaattaactaaaatttgtcatatcattcaatggaatagggagaaccaatattcaattctatttggggcaaattagctaaaatttggaagtaaaagaaatgatatgggcaaatgccatgttcttacggcagccatgagaccagtctctttggctctccaaggaagaaagatacctcttaaagcattttttagaggtccgagaagtcagtgtctgtcttataagattctttgacaacatgacatcttcgctagaagaaaaacaccaccatagcctcatctgtttttccatcttaccttaatttttcattggccttaagttgtccttactgctgaatacatcgttctgtttttctaaagcaacaatatttgatcactgcttttaagaaaaacagactagcccttcttgtttttctggaagtttgagagtcctgaatatttcttcatatccaaatatcatcttggagccctatcgtgctggtcttcgctgaggctgatgagagcactttctgcacccctgctccatggccgtacatgacaacgcacctgcaccactgctgcaagggcggggggcagcagcctgtgttttggctgtcactgttacctcctgagaaggctgctgtcccaggtttgcacaccacttttgttccaaagttacacatggtctcttcctccctcgcacccattccaggttaatcatttctctatcagctgtttctccatccacagattctgaatgttgagactaattgttgggcatctcttttgcacaaggctgacagactccatactcagcatcgcacagccagttctaactcctctgctgggtctcggacctacagcttttgcctgagtgaaatgttcctacgacttttgctcctgagtgagatattccattgtacttctactgtttgtgtatctgctgggttcctttagccaagcctagcgtctgacgcaggcactagccgccactgaggccgtgatacagcatcactgtggacactgctggctcctctccttgggacatatccacactgccccttgagcttcacctttaaggctggtatgtacgtaagttcacggtggtcgtctgcatggtctcctcttgtttaaatcaggaccaacaaaggatgttcatttgtattttggcaaggcccattgggcctctgtgtagccaggttaaaagctcactcactaggatcggatgctgtcattgctctgtgagcctttcagttgaaatccttggagacttgaaggtgttgcttattattttgatttgattttctgcatctttatctggcaaatggacagattgctctcacaagaaacttagtcatgtcagcttttagagtccttcttgagtcatgttagcattggtagtgtaaaatagattgagttaaaacagctcaggatgcagctgtgcccccacttaattggtgagaggaggaggtcacggggctggcttgacaacaaagactaaatgtggcttttttgtcggtgactaggtgtggtccataagcagaagagccatacctacaaaaagtgacaactgtcctgtgttttccaaattaaaatcttgttacaaagatcatgccggcttttcgcagtgagttgaagccccaagctcagttccagccaggctcaggatgaccctcaaatgatatgtattggatagtgtaggtcaggagcctgtggaggggaccagtattttgcaagcagttactaaagtcacatttctcactgactcttgacggtgcattgttcaaaatctcatggcttaaccttagtgttaaatgctttcaagaaaaactgtaaccatttcaattttacaagtactttctcattttacttgaacattttacaagtactttctgtatttacttgtaaatatttcctctagcccttgaacccgcgcatcacttttttggttttcctcattccaccacagcatttaggtgaccgttaccatttatgtttcattaagcttcactaggaatgtaaggataatattagagcatttgcagaaaattgttatctccttttgtaggggattcgagacatatttgtagctacttcacggctgtagagttagtgggtgatcgggtattctgcattgttccttatccctttgtcagtgacagacacattgacataagagattcctacaggattataaggagagataaattattaaccatttttttacttgatccaactactccatgtcccatcaactagtggtaactgatgttgataggattttttttaagtccagtaactattcttgcagtatcagatgtttaccccaaattaggcaataacccagacttcgaatctgtaggtttatgattcctacattcccctgccgctctcaatggcttgttgcctcccttctgttgctctcagaaaacagatggagatcaggtaaagatgaaacgtgcactatatgttcagaaaagcaaacatccattgtcctcatttagattccatccttcaatttatgctctagaacctaaacctaatacccattgactacctcctgagtttcttaggtttcaattatttttttgaaatgtcatccatggataatagcttcaattttaggaaagatttaaatgtataactttcctcattcagtgctgtgtcatttcacagtacagatctgcgttaatttttgacagctcatatatacagatttttagaaatgtaatagaaaatgattttgcacatatggtgcaagtcttgctggtgtatgtttaatgtggcaacacgtgccagaactgtttggcaaaacatgtcaaatggagtgcttgagtcagaactctaatgtaaatgtgtctaaacagcagtatgtatcattatgatgtatttttgtaaacatagtgatggctgctttcagtcatgtaagtgctggataaaaataaccacttcagttggagtaatgtaggaaaacgtcacccagcagatgggtagtcctctgcaaagttacactgtcagccagtggcactggttcttttatttatgttgggtttttgttttttttttagaggagagtgaagaattgacatcagacaacatggagtgcaaaaataataacccatcaatatttgccttctaaatgtaaaatgtaaaagtttaactgatctgtgtacacattagagaccactttcacacgccacaatatgttcagttgcaggttaacactgagaggttgagacttccctcatctgatgaccagcttggttaatttgacttctgaaggcactaaattaccaagtatttgcagtaatggggaccggattaattttcctcacaattctctatagctgtctgatataagggctgtgtttttattgaatcacagatcctcaaattacagtgaaagcatgtcttgctagtaagactcatttgaaaacctctttattcttggaataattgggccagtacaagtggccagatgtatcctggccacattggaaaactatttgggcccgttcagaaccacttaactgcaacaacagtagtaactatagttaatatctatctattgagttattgtgtgacagttacttggataagtactttaatgcattctcattttaatcctcacagctaccctatgaggctgttactgttcttatccccattgtattgataaggaaactgcccagggtactcagctaagaagaggattgctttgggcataggaagcagaatgacgagttcagtcttcctcagtagttggagcacagttctcaaagcccatcaacactttggaatggatttgttgttttatttatgccatcaagggagagttgatatttgtgtattgctaaaaactactaaagtatgtcgatgcttaggtaggaacatacaaaccatatatcctctgggatctgcccaggtttctgtataaggcttgacctacgtaagatcctatgatgaagaccagaaaactttttttaaaagtaggtaaattaaaattaaaatcacgagtttgttcacatttgtcccataggttcctagtgcaaaaatgcagggagataaaagcaaacatttgaactcagtgaagtgagagtctttgggaactcctagatgttagaaatagcaccggggcatcaggtagccaacgttcaattcacttttcacgtttgtgtctttgtagctttagagctgatgagtctgattggtttggaagagagagttttaatttatgatgtcactgtgagaactgttgtgaaaattttgtaagaaaatacagtaatctgttgattttttcctgtagttttggctttcacatccctttggctgtgtttaagttcaagagcatgccaaggccatgagggtcctggcttgcacttcttgggaacagggcatgctagaggtgggtcatgaagctttcaaggtcactgttccagcccgaccctgcgcaatttaggcattgcctttatgtctctcctctctggaacttcatgtagcagcctaacaccggggccgagttgcctttactctattttctatgatgaatacttgtggagaaactgtgacaaatccattgatcctgatatttttattgttggagtcttgttgattctctatgaataatttctatttgattgtactgtgtagagttaatacccactagggatatgttaataaagctacaaatgcatagtgtaatatagaatagcaagatttttttgtgaacaatttatatagaagagtaagttgttttttaagtgttaggctcatttcttttagaaacttaaaatgttataaaagttttttaaacattcaatatttttaattataagagacatttgttactagagccaattatttcaggtgttctaattggagtgttgattttattacctcatatacctctagaatgccacgtgttctgttggggataaaattgcacaataaatgtcaagtctctgtt

SEQ ID NO: 2 - protein, 530 aa, Homo sapiens
MQPAEEGPSVPKIYKQRSPYSVLKTFPSKRPALAKRYERPTLVELPHVRAPPPPPPPFAPHAAVSISSSEPPPQQFQAQSSYPPGPGRAAAAASSSSPSCTPATSQGHLRTPAQPPPASPAASSSSSFAAVVRYGPGAAAAAGTGGTGSDSASLELSAESRMILDAFAQQCSRVLSLLNCGGKLLDSNHSQSMISCVKQEGSSYNERQEHCHIGKGVHSQTSDNVDIEMQYMQRKQQTSAFLRVFTDSLQNYLLSGSFPTPNPSSASEYGHLADVDPLSTSPVHTLGGWTSPATSESHGHPSSSTLPEEEEEEDEEGYCPRCQELEQEVISLQQENEELRRKLESIPVPCQTVLDYLKMVLQHHNQLLIPQPADQPTEGSKQLLNNYPVYITSKQWDEAVNSSKKDGRRLLRYLIRFVFTTDELKYSCGLGKRKRSVQSGETGPERRPLDPVKVTCLREFIRMHCTSNPDWWMPSEEQINKVFSDAVGHARQGRAVGTFLHNGGSFYEGIDHQASQDEVFNKSSQDGSGD

SEQ ID NO: 3 - DNA, 8692 bp, Homo sapiens
  CDS (593)...(1906)
gcgatgctcggggaaagcaggaccccaaagccccgtaaacaccgcgcgaccacccgggccaagatcttcaagaggttcttttcagaaggatcggagagcaattcccgattggtagaagaacttgctgtaatacacacgtactctgacgaccccgccccaacgactagcccctcctctgtgcaaccccgagagtttggggtcatgcagggggcgccacgagctcgtttcggaagccggaccccgcccgcagccgcagaagcctcgagtccacatctgggtctctaaagtctcgccgtagccagatcccggatccccaccttcttcaccagttcccgggcgtcctccaggcattggcgaggcagcctgtcaatcaggagctcgggcggcagccccccgcgcgggggctcggcgatgccagcctcagcgacaggcggcggcggcggcggccacggcacagacacacaccctcccacacgcgcgcaccagggcagacccggcgggcaggcggcggaggcaccctcggagcccggcgcccggcggggaggggacgtgctccgagggaccggccccgaggcgccggatggaggaagagatgcagccggcagaggaggggcccagcgtccccaaaatctacaagcagcgcagcccctacagcgtcctcaagacgttccccagcaagagaccggcgctggccaagcgctacgagcgacccaccctggtggagctgccgcacgtgcgggcgcccccgccgcccccgccgcccttcgcgccgcacgccgccgtctccatcagcagcagcgagccgccgccgcagcagttccaggcgcagagctcctacccccccgggcccggccgggccgccgccgccgcttcgtcgtcgtcgccgtcctgcacgcccgccacatcccagggccacttgaggactccggcgcagccgccgcccgcgtcccccgccgcctcctcgtcgtcttcgttcgccgctgtcgtcaggtatggcccaggcgcggcggcggccgccggcaccggcggcacgggtagcgacagcgccagcctggagctcagcgcagagagtcgaatgatcttggatgcctttgcccagcagtgcagtcgagttcttagcctcttaaattgtggaggaaaactcctggactccaaccattctcagtccatgatttcttgcgtaaagcaggaaggctcaagttacaacgaaagacaggagcactgtcacattgggaaaggggtccacagtcagacctcagacaatgtagacatagagatgcagtatatgcaaaggaaacaacaaacttctgcctttttgagggttttcactgactctctacaaaattacctgctctcgggaagctttccaactccaaacccctcgtcagccagtgaatatggccatctggccgacgtggatcctctgtcaacctctcctgtgcatacattaggtggctggacttccccagcaacgtccgaatcccatggccacccatcttcatctacactgccagaagaggaggaggaggaggacgaggaaggctattgtcctcgatgccaagagctggagcaggaggttatttcactgcaacaagaaaatgaagagctcagaaggaaattagagagcatcccagtgccctgccagaccgttttagattacttgaagatggttctgcagcaccacaaccaactcctgataccacagccagctgaccagccgacagagggaagcaagcagctgttgaacaactatcctgtctacataacgagcaaacagtgggatgaggctgtaaattcttcaaagaaagatgggagacggctccttcgatacctcatcagatttgttttcacaaccgatgagcttaagtactcatgcggccttgggaaaaggaaaagaattcattaggatgcattgtacctccaaccccgattggtggatgccctcggaagagcagataaacaaagtgttcagcgacgctgtcggtcacgcccgacaggggcgggcggtggggactttcctgcacaacggtggctcattttatgaagggatcgatcaccaggcttctcaggatgaagtcttcaataaaagttcccaggatggatctggggattagtggacagaatcttcctgttgtagcagctggtcctctcaagagttccaattgtgaatgtcctgttcctgtcacctgagagtccaaagcctgtcattctgccatagtctacacattctcagctgccacagtacccaaatagaaatccattttagggttgtttgggaagtctgtggcacctacaacagacttttggaatattatattataaaaagaaaaaactacatctgatttttaaatgattactagctagatcatgagggtgaaaaaataggtgagctcctagttacctttctgaaatcttcaaactctgctacctgggcagagatagtccccaaggtaggctggggtagtgtttctgcccatgggagaaggtggagacatggagttgtgttaagggacaagaagcaaacattctcttaattcaaataagttgtctttatgttttccaaagacttgacttcatatttctcggcaaagacataggatagatgacatcatataccattttgacattaataatgtctattactaaaaggaaaccagagaacagaggcaacatctgcagacagtgattaattacaggtcaactgtttttctgttgtttaaaaaccactgtgttgatcaagaaggcactatttgatctctggagtttacaaacagtagtcatttttcattgttagtcaagaaacatccaaagatccaaaaccattttcaaatgctcagttttgtaggttaataaatccgcagtttccatagccttaaatcaggctttgttgacacaatgccaaagtgatgggtagaacaatgaaaatttaaagcaattagttgtttggtgcactgaagaccaaacaagtggtgtgactgatggtattcgctgaattgactagatgttctggcattgtatacacacagcttcaaggcgattctgacaactatgcaatgggcttgtcagtaattgctctgaaatttgagggtctttctctgctgagctgatctttagaatttgtatgaaacttgtttcccattgtccttgatgaaaacatttcatcccctccgtgcctcctttaccccaatgtaccccttagctatggctaagtcagcactgtgccgctatcccctggttaatttgttgagttccatatgtgaaattagtggtatctttggaaactttccatattggcaaatgctatagaggtgctagagtcatcatttctgagggcttcctgtttggactcaggagaggctttctttaccaaactagtccagattactacattctttgtagagcaaagggctaaatggacagcgtttattgaaggctactaatgtcatctacagacatgaccaagggtttttgaaaattggttggagattcaggttaatgagcatccattgataaagggtttttgggctatttttgtcaacataaactcataaattgtcctttagatttaatatttagtttgtattcactatatacaaagtcctagaaacaggtctttctgtagcttttgtttattagcttttttgtattactagaattcatccattgaaaagtttaatgtttatggaggtggtcatctgtcagatctgctcaatgatgtagtgggcactaatatttcaatcctgttttgagaaaattaactaaaatttgtcatatcattcaatggaatagggagaaccaatattcaattctatttggggcaaattagctaaaatttggaagtaaaagaaatgatatgggcaaatgccatgttcttacggcagccatgagaccagtctctttggctctccaaggaagaaagatacctcttaaagcattttttagaggtccgagaagtcagtgtctgtcttataagattctttgacaacatgacatcttcgctagaagaaaaacaccaccatagcctcatctgtttttccatcttaccttaatttttcattggccttaagttgtccttactgctgaatacatcgttctgtttttctaaagcaacaatatttgatcactgcttttaagaaaaacagactagcccttcttgtttttctggaagtttgagagtcctgaatatttcttcatatccaaatatcatcttggagccctatcgtgctggtcttcgctgaggctgatgagagcactttctgcacccctgctccatggccgtacatgacaacgcacctgcaccactgctgcaagggcggggggcagcagcctgtgttttggctgtcactgttacctcctgagaaggctgctgtcccaggtttgcacaccacttttgttccaaagttacacatggtctcttcctccctcgcacccattccaggttaatcatttctctatcagctgtttctccatccacagattctgaatgttgagactaattgttgggcatctcttttgcacaaggctgacagactccatactcagcatcgcacagccagttctaactcctctgctgggtctcggacctacagcttttgcctgagtgaaatgttcctacgacttttgctcctgagtgagatattccattgtacttctactgtttgtgtatctgctgggttcctttagccaagcctagcgtctgacgcaggcactagccgccactgaggccgtgatacagcatcactgtggacactgctggctcctctccttgggacatatccacactgccccttgagcttcacctttaaggctggtatgtacgtaagttcacggtggtcgtctgcatggtctcctcttgtttaaatcaggaccaacaaaggatgttcatttgtattttggcaaggcccattgggcctctgtgtagccaggttaaaagctcactcactaggatcggatgctgtcattgctctgtgagcctttcagttgaaatccttggagacttgaaggtgttgcttattattttgatttgattttctgcatctttatctggcaaatggacagattgctctcacaagaaacttagtcatgtcagcttttagagtccttcttgagtcatgttagcattggtagtgtaaaatagattgagttaaaacagctcaggatgcagctgtgcccccacttaattggtgagaggaggaggtcacggggctggcttgacaacaaagactaaatgtggcttttttgtcggtgactaggtgtggtccataagcagaagagccatacctacaaaaagtgacaactgtcctgtgttttccaaattaaaatcttgttacaaagatcatgccggcttttcgcagtgagttgaagccccaagctcagttccagccaggctcaggatgaccctcaaatgatatgtattggatagtgtaggtcaggagcctgtggaggggaccagtattttgcaagcagttactaaagtcacatttctcactgactcttgacggtgcattgttcaaaatctcatggcttaaccttagtgttaaatgctttcaagaaaaactgtaaccatttcaattttacaagtactttctcattttacttgaacattttacaagtactttctgtatttacttgtaaatatttcctctagcccttgaacccgcgcatcacttttttggttttcctcattccaccacagcatttaggtgaccgttaccatttatgtttcattaagcttcactaggaatgtaaggataatattagagcatttgcagaaaattgttatctccttttgtaggggattcgagacatatttgtagctacttcacggctgtagagttagtgggtgatcgggtattctgcattgttccttatccctttgtcagtgacagacacattgacataagagattcctacaggattataaggagagataaattattaaccatttttttacttgatccaactactccatgtcccatcaactagtggtaactgatgttgataggattttttttaagtccagtaactattcttgcagtatcagatgtttaccccaaattaggcaataacccagacttcgaatctgtaggtttatgattcctacattcccctgccgctctcaatggcttgttgcctcccttctgttgctctcagaaaacagatggagatcaggtaaagatgaaacgtgcactatatgttcagaaaagcaaacatccattgtcctcatttagattccatccttcaatttatgctctagaacctaaacctaatacccattgactacctcctgagtttcttaggtttcaattatttttttgaaatgtcatccatggataatagcttcaattttaggaaagatttaaatgtataactttcctcattcagtgctgtgtcatttcacagtacagatctgcgttaatttttgacagctcatatatacagatttttagaaatgtaatagaaaatgattttgcacatatggtgcaagtcttgctggtgtatgtttaatgtggcaacacgtgccagaactgtttggcaaaacatgtcaaatggagtgcttgagtcagaactctaatgtaaatgtgtctaaacagcagtatgtatcattatgatgtatttttgtaaacatagtgatggctgctttcagtcatgtaagtgctggataaaaataaccacttcagttggagtaatgtaggaaaacgtcacccagcagatgggtagtcctctgcaaagttacactgtcagccagtggcactggttcttttatttatgttgggtttttgttttttttttagaggagagtgaagaattgacatcagacaacatggagtgcaaaaataataacccatcaatatttgccttctaaatgtaaaatgtaaaagtttaactgatctgtgtacacattagagaccactttcacacgccacaatatgttcagttgcaggttaacactgagaggttgagacttccctcatctgatgaccagcttggttaatttgacttctgaaggcactaaattaccaagtatttgcagtaatggggaccggattaattttcctcacaattctctatagctgtctgatataagggctgtgtttttattgaatcacagatcctcaaattacagtgaaagcatgtcttgctagtaagactcatttgaaaacctctttattcttggaataattgggccagtacaagtggccagatgtatcctggccacattggaaaactatttgggcccgttcagaaccacttaactgcaacaacagtagtaactatagttaatatctatctattgagttattgtgtgacagttacttggataagtactttaatgcattctcattttaatcctcacagctaccctatgaggctgttactgttcttatccccattgtattgataaggaaactgcccagggtactcagctaagaagaggattgctttgggcataggaagcagaatgacgagttcagtcttcctcagtagttggagcacagttctcaaagcccatcaacactttggaatggatttgttgttttatttatgccatcaagggagagttgatatttgtgtattgctaaaaactactaaagtatgtcgatgcttaggtaggaacatacaaaccatatatcctctgggatctgcccaggtttctgtataaggcttgacctacgtaagatcctatgatgaagaccagaaaactttttttaaaagtaggtaaattaaaattaaaatcacgagtttgttcacatttgtcccataggttcctagtgcaaaaatgcagggagataaaagcaaacatttgaactcagtgaagtgagagtctttgggaactcctagatgttagaaatagcaccggggcatcaggtagccaacgttcaattcacttttcacgtttgtgtctttgtagctttagagctgatgagtctgattggtttggaagagagagttttaatttatgatgtcactgtgagaactgttgtgaaaattttgtaagaaaatacagtaatctgttgattttttcctgtagttttggctttcacatccctttggctgtgtttaagttcaagagcatgccaaggccatgagggtcctggcttgcacttcttgggaacagggcatgctagaggtgggtcatgaagctttcaaggtcactgttccagcccgaccctgcgcaatttaggcattgcctttatgtctctcctctctggaacttcatgtagcagcctaacaccggggccgagttgcctttactctattttctatgatgaatacttgtggagaaactgtgacaaatccattgatcctgatatttttattgttggagtcttgttgattctctatgaataatttctatttgattgtactgtgtagagttaatacccactagggatatgttaataaagctacaaatgcatagtgtaatatagaatagcaagatttttttgtgaacaatttatatagaagagtaagttgttttttaagtgttaggctcatttcttttagaaacttaaaatgttataaaagttttttaaacattcaatatttttaattataagagacatttgttactagagccaattatttcaggtgttctaattggagtgttgattttattacctcatatacctctagaatgccacgtgttctgttggggataaaattgcacaataaatgtcaagtctctgtt

SEQ ID NO: 4 - protein, 437 aa, Homo sapiens
MQPAEEGPSVPKIYKQRSPYSVLKTFPSKRPALAKRYERPTLVELPHVRAPPPPPPPFAPHAAVSISSSEPPPQQFQAQSSYPPGPGRAAAAASSSSPSCTPATSQGHLRTPAQPPPASPAASSSSSFAAVVRYGPGAAAAAGTGGTGSDSASLELSAESRMILDAFAQQCSRVLSLLNCGGKLLDSNHSQSMISCVKQEGSSYNERQEHCHIGKGVHSQTSDNVDIEMQYMQRKQQTSAFLRVFTDSLQNYLLSGSFPTPNPSSASEYGHLADVDPLSTSPVHTLGGWTSPATSESHGHPSSSTLPEEEEEEDEEGYCPRCQELEQEVISLQQENEELRRKLESIPVPCQTVLDYLKMVLQHHNQLLIPQPADQPTEGSKQLLNNYPVYITSKQWDEAVNSSKKDGRRLLRYLIRFVFTTDELKYSCGLGKRKRIH

SEQ ID NO: 5 - DNA, 22 bp, Artificial Sequence
  An artificially synthesized primer sequence for RT-PCR
gtgacaaatccattgatcctga

SEQ ID NO: 6 - DNA, 23 bp, Artificial Sequence
  An artificially synthesized primer sequence for RT-PCR
gaacacgtggcattctagaggta

SEQ ID NO: 7 - DNA, 9 bp, Artificial Sequence
  An artificially synthesized spacer sequence for siRNA
ttcaagaga

SEQ ID NO: 8 - DNA, 19 bp, Artificial Sequence
  An artificially synthesized target sequence for siRNA
gatggttctgcagcaccac

SEQ ID NO: 9 - DNA, 19 bp, Artificial Sequence
  An artificially synthesized target sequence for siRNA
gaagcagcacgacttcttc

SEQ ID NO: 10 - DNA, 47 bp, Artificial Sequence
  An artificially synthesized oligonucleotide sequence for hairpin siRNA
gatggttctgcagcaccacttcaagagagtggtgctgcagaaccatc

SEQ ID NO: 11 - DNA, 51 bp, Artificial Sequence
  An artificially synthesized oligonucleotide sequence for construction of siRNA expression vector
caccgatggttctgcagcaccacttcaagagagtggtgctgcagaaccatc

SEQ ID NO: 12 - DNA, 51 bp, Artificial Sequence
  An artificially synthesized oligonucleotide sequence for construction of siRNA expression vector
aaaagatggttctgcagcaccactctcttgaagtggtgctgcagaaccatc

SEQ ID NO: 13 - DNA, 4863 bp, Artificial Sequence
  An artificially constructed plasmid sequence of siRNA expression vector
gacggatcgggagatctcccgatcccctatggtgcactctcagtacaatctgctctggatccactagtaacggccgccagtgtgctggaattcggcttggggatcagcgtttgagtaagagcccgcgtctgaaccctccgcgccgccccggccccagtggaaagacgcgcaggcaaaacgcaccacgtgacggagcgtgaccgcgcgccgagcgcgcgccaaggtcgggcaggaagagggcctatttcccatgattccttcatatttgcatatacgatacaaggctgttagagagataattagaattaatttgactgtaaacacaaagatattagtacaaaatacgtgacgtagaaagtaataatttcttgggtagtttgcagttttaaaattatgttttaaaatggactatcatatgcttaccgtaacttgaaagtatttcgatttcttggctttatatatcttgtggaaaggacgaaacacctttttacatcaggttgtttttctgtttggttttttttttacaccacgtttatacgccggtgcacggtttaccactgaaaacacctttcatctacaggtgatatcttttaacacaaataaaatgtagtagtcctaggagacggaatagaaggaggtggggcctaaagccgaattctgcagatatccatcacactggcggccgctcgagtgaggcggaaagaaccagctggggctctagggggtatccccacgcgccctgtagcggcgcattaagcgcggcgggtgtggtggttacgcgcagcgtgaccgctacacttgccagcgccctagcgcccgctcctttcgctttcttcccttcctttctcgccacgttcgccggctttccccgtcaagctctaaatcgggggctccctttagggttccgatttagtgctttacggcacctcgaccccaaaaaacttgattagggtgatggttcacgtagtgggccatcgccctgatagacggtttttcgccctttgacgttggagtccacgttctttaatagtggactcttgttccaaactggaacaacactcaaccctatctcggtctattcttttgatttataagggattttgccgatttcggcctattggttaaaaaatgagctgatttaacaaaaatttaacgcgaattaattctgtggaatgtgtgtcagttagggtgtggaaagtccccaggctccccagcaggcagaagtatgcaaagcatgcatctcaattagtcagcaaccaggtgtggaaagtccccaggctccccagcaggcagaagtatgcaaagcatgcatctcaattagtcagcaaccatagtcccgcccctaactccgcccatcccgcccctaactccgcccagttccgcccattctccgccccatggctgactaattttttttatttatgcagaggccgaggccgcctctgcctctgagctattccagaagtagtgaggaggcttttttggaggcctaggcttttgcaaaaagctcccgggagcttgtatatccattttcggatctgatcaagagacaggatgaggatcgtttcgcatgattgaacaagatggattgcacgcaggttctccggccgcttgggtggagaggctattcggctatgactgggcacaacagacaatcggctgctctgatgccgccgtgttccggctgtcagcgcaggggcgcccggttctttttgtcaagaccgacctgtccggtgccctgaatgaactgcaggacgaggcagcgcggctatcgtggctggccacgacgggcgttccttgcgcagctgtgctcgacgttgtcactgaagcgggaagggactggctgctattgggcgaagtgccggggcaggatctcctgtcatctcaccttgctcctgccgagaaagtatccatcatggctgatgcaatgcggcggctgcatacgcttgatccggctacctgcccattcgaccaccaagcgaaacatcgcatcgagcgagcacgtactcggatggaagccggtcttgtcgatcaggatgatctggacgaagagcatcaggggctcgcgccagccgaactgttcgccaggctcaaggcgcgcatgcccgacggcgaggatctcgtcgtgacccatggcgatgcctgcttgccgaatatcatggtggaaaatggccgcttttctggattcatcgactgtggccggctgggtgtggcggaccgctatcaggacatagcgttggctacccgtgatattgctgaagagcttggcggcgaatgggctgaccgcttcctcgtgctttacggtatcgccgctcccgattcgcagcgcatcgccttctatcgccttcttgacgagttcttctgagcgggactctggggttcgaaatgaccgaccaagcgacgcccaacctgccatcacgagatttcgattccaccgccgccttctatgaaaggttgggcttcggaatcgttttccgggacgccggctggatgatcctccagcgcggggatctcatgctggagttcttcgcccaccccaacttgtttattgcagcttataatggttacaaataaagcaatagcatcacaaatttcacaaataaagcatttttttcactgcattctagttgtggtttgtccaaactcatcaatgtatcttatcatgtctgtataccgtcgacctctagctagagcttggcgtaatcatggtcatagctgtttcctgtgtgaaattgttatccgctcacaattccacacaacatacgagccggaagcataaagtgtaaagcctggggtgcctaatgagtgagctaactcacattaattgcgttgcgctcactgcccgctttccagtcgggaaacctgtcgtgccagctgcattaatgaatcggccaacgcgcggggagaggcggtttgcgtattgggcgctcttccgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcatagctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaagaacagtatttggtatctgcgctctgctgaagccagttaccttcggaaaaagagttggtagctcttgatccggcaaacaaaccaccgctggtagcggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttaaattaaaaatgaagttttaaatcaatctaaagtatatatgagtaaacttggtctgacagttaccaatgcttaatcagtgaggcacctatctcagcgatctgtctatttcgttcatccatagttgcctgactccccgtcgtgtagataactacgatacgggagggcttaccatctggccccagtgctgcaatgataccgcgagacccacgctcaccggctccagatttatcagcaataaaccagccagccggaagggccgagcgcagaagtggtcctgcaactttatccgcctccatccagtctattaattgttgccgggaagctagagtaagtagttcgccagttaatagtttgcgcaacgttgttgccattgctacaggcatcgtggtgtcacgctcgtcgtttggtatggcttcattcagctccggttcccaacgatcaaggcgagttacatgatcccccatgttgtgcaaaaaagcggttagctccttcggtcctccgatcgttgtcagaagtaagttggccgcagtgttatcactcatggttatggcagcactgcataattctcttactgtcatgccatccgtaagatgcttttctgtgactggtgagtactcaaccaagtcattctgagaatagtgtatgcggcgaccgagttgctcttgcccggcgtcaatacgggataataccgcgccacatagcagaactttaaaagtgctcatcattggaaaacgttcttcggggcgaaaactctcaaggatcttaccgctgttgagatccagttcgatgtaacccactcgtgcacccaactgatcttcagcatcttttactttcaccagcgtttctgggtgagcaaaaacaggaaggcaaaatgccgcaaaaaagggaataagggcgacacggaaatgttgaatactcatactcttcctttttcaatattattgaagcatttatcagggttattgtctcatgagcggatacatatttgaatgtatttagaaaaataaacaaataggggttccgcgcacatttccccgaaaagtgccacctgacgtc

SEQ ID NO: 14 - DNA, 20 bp, Artificial Sequence
  An artificially synthesized primer sequence
ggggatcagcgtttgagtaa

SEQ ID NO: 15 - DNA, 20 bp, Artificial Sequence
  An artificially synthesized primer sequence
taggccccacctccttctat

SEQ ID NO: 16 - DNA, 30 bp, Artificial Sequence
  An artificially synthesized primer sequence
tgcggatccagagcagattgtactgagagt

SEQ ID NO: 17 - DNA, 29 bp, Artificial Sequence
  An artificially synthesized primer sequence
ctctatctcgagtgaggcggaaagaacca

SEQ ID NO: 18 - DNA, 40 bp, Artificial Sequence
  An artificially synthesized primer sequence
tttaagcttgaagactatttttacatcaggttgtttttct

SEQ ID NO: 19 - DNA, 37 bp, Artificial Sequence
  An artificially synthesized primer sequence
tttaagcttgaagacacggtgtttcgtcctttccaca

SEQ ID NO: 20 - DNA, 51 bp, Artificial Sequence
  An artificially synthesized sequence for siRNA
caccgaagcagcacgacttcttcttcaagagagaagaagtcgtgctgcttc

SEQ ID NO: 21 - DNA, 51 bp, Artificial Sequence
  An artificially synthesized sequence for siRNA
aaaagaagcagcacgacttcttctctcttgaagaagaagtcgtgctgcttc

SEQ ID NO: 22 - DNA, 23 bp, Artificial Sequence
  An artificially synthesized primer sequence for RT-PCR
tcatgatctccctctaagcacat

SEQ ID NO: 23 - DNA, 23 bp, Artificial Sequence
  An artificially synthesized primer sequence for RT-PCR
tgttgctgtgtgttgggtataag

SEQ ID NO: 24 - DNA, 23 bp, Artificial Sequence
  An artificially synthesized primer sequence for RT-PCR
cctgggggtcattatggcatttt

SEQ ID NO: 25 - DNA, 23 bp, Artificial Sequence
  An artificially synthesized primer sequence for RT-PCR
ttctcctactggctaaacaaacg

SEQ ID NO: 26 - DNA, 20 bp, Artificial Sequence
  An artificially synthesized primer sequence for RT-PCR
ggtgcctcttatctccttct

SEQ ID NO: 27 - DNA, 20 bp, Artificial Sequence
  An artificially synthesized primer sequence for RT-PCR
cttccctttttatttcctct

SEQ ID NO: 28 - DNA, 23 bp, Artificial Sequence
  An artificially synthesized primer sequence for RT-PCR
gtacttggcttaaaagcaaccag

SEQ ID NO: 29 - DNA, 22 bp, Artificial Sequence
  An artificially synthesized primer sequence for RT-PCR
ctcagtgacctggatctgacct

SEQ ID NO: 30 - DNA, 21 bp, Artificial Sequence
  An artificially synthesized primer sequence for RT-PCR
aaccacttcttgcgagtcctt

SEQ ID NO: 31 - DNA, 23 bp, Artificial Sequence
  An artificially synthesized primer sequence for RT-PCR
tattcaggttggctggtagtcac

SEQ ID NO: 32 - DNA, 20 bp, Artificial Sequence
  An artificially synthesized primer sequence for RT-PCR
ttggcttgactcaggattta

SEQ ID NO: 33 - DNA, 20 bp, Artificial Sequence
  An artificially synthesized primer sequence for RT-PCR
tggacttgggagaggactgg

(19) United States
(12) Patent Application Publication
(10) Pub. No.: US 2005/0259483 A1
(43) Pub. Date: Nov. 24, 2005

(54) Genes and polypeptides relating to prostate cancers

(75) Inventors: Yusuke Nakamura, Yokohama-shi (JP); Toyomasa Katagiri, Shinagawa-ku (JP); Hidewaki Nakagawa, Shinagawa-ku (JP); Shuichi Nakatsuru, Saitama-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: Oncotherapy Science, Inc., Kawasaki-shi (JP); The University of Tokyo, Bunkyo-ku (JP)

(21) Appl. No.: 11/088,634

(22) Filed: Mar. 23, 2005

Related U.S. Application Data
(63) Continuation-in-part of application No. PCT/JP03/12073, filed on Sep. 22, 2003.
(60) Provisional application No. 60/414,873, filed on Sep. 30, 2002.
(60) Provisional application No. 60/555,810, filed on Mar. 23, 2004.

(51) Int. Cl. G11C 5/00

(52) U.S. Cl. 365/189.07

(57) ABSTRACT

Objective methods for detecting and diagnosing prostate cancer (PRC) or prostatic intraepithelial neoplasia (PIN) are described herein. In one embodiment, the diagnostic method involves the determining an expression level of PRC-associated gene that discriminate between PRC or PIN and nomal cell. The present invention further provides methods of screening for therapeutic agents useful in the treatment of either or both of PRC and PIN, methods of treating either or both of PRC and PIN and method of vaccinating a subject against either or both of PRC and PIN.

### CROSS-REFERENCES TO RELATED APPLICATIONS

This application is a continuation-in-part of PCT/JP2003/012073 (WO 2004/031414), which claims the benefit of U.S. Ser. No. 60/414,873, filed Sep. 30, 2002. This application also claims the benefit of 60/555,810, filed Mar. 23, 2004. All of these applications are incorporated herein by reference.

### FIELD OF THE INVENTION

This invention relates to methods of diagnosing and treating prostate cancer. In particular, the present invention relates to novel polypeptides encoded by a novel gene B3537(CCDC4) relating to prostate cancer. Furthermore, the present invention relates to the novel gene CCDC4. The genes and polypeptides of the present invention can be used, for example, in the diagnosis of prostate cancer, as target molecules for developing drugs against the disease, and for attenuating cell growth of prostate cancer.

### BACKGROUND OF THE INVENTION

Prostate cancer (PRC) is one of the most common malignancies in men and represents a significant worldwide health problem. It is the second most frequent cause of cancer death in the United States (Greenlee et al., CA Cancer J Clin, 51:15-36 (2001)). Incidence of PRC is increasing steadily in developed countries according to the prevalence of Western-style diet and increasing number of senior population. Increasing number of patients also die from this disease in Japan due to adoption of a Western life style (Kuroishi, T., Klinika, 25:43-48 (1995)). Currently, the diagnosis of PRC is based on an increased level of the serum prostate specific antigen (PSA). Early diagnosis provides an opportunity for curative surgery. Patients with organ confined PRC are usually treated and approximately 70% of them are curable with radical prostatectomy (Roberts et al., Urology, 57:1033-1037 (2001); Roberts et al., Mayo Clin Proc, 76:576-581 (2001)). Most of patients with advanced or relapsed disease are treated with androgen ablation therapy because growth of PRC is initially androgen dependent. Although most of these patients initially respond to androgen ablation therapy, the disease eventually progresses to androgen-independent PRC, at which point the tumor is no longer responsive to androgen ablation therapy.

One of the most serious clinical problems of treatment for PRC is that this androgen-independent PRC is unresponsive to any other therapies, and understanding the mechanism of androgen-independent growth and establishing new therapies other than androgen ablation therapy against PRC are urgent issues for management of PRC.

On the other hand, prostatic intraepithelial neoplasia (PIN) is the specific type of minimal lesion that is believed to be the precursor of PRC (McNeal, J. E. and Bostwick, D. G., Hum Pathol, 17, 64-71 (1986)). PIN is regarded as a continuum between low-grade and high-grade forms, and high-grade PIN is considered to be the immediate precursor of invasive carcinoma. High-grade PIN and PRC frequently coexist and they share the similar chromosomal and genetic alterations (Qian et al., Eur Urol, 35, 479-83 (1999)). However, the mechanism of PIN development and the progression from PIN to PRC remain unclear. Therefore, genome-wide analysis of expression profiles in PINs is an essential step toward understanding the molecular carcinogenesis and progression and the preventive strategies of PRC.

cDNA microarray technologies have enabled to obtain comprehensive profiles of gene expression in normal and malignant cells, and compare the gene expression in malignant and corresponding normal cells (Okabe et al., Cancer Res 61:2129-37 (2001); Kitahara et al., Cancer Res 61: 3544-9 (2001); Lin et al., Oncogene 21:4120-8 (2002); Hasegawa et al., Cancer Res 62:7012-7 (2002)). This approach enables to disclose the complex nature of cancer cells, and helps to understand the mechanism of carcinogenesis. Identification of genes that are deregulated in tumors can lead to more precise and accurate diagnosis of individual cancers, and to develop novel therapeutic targets (Bienz and Clevers, Cell 103:311-20 (2000)). To disclose mechanisms underlying tumors from a genome-wide point of view, and discover target molecules for diagnosis and development of novel therapeutic drugs, the present inventors have been analyzing the expression profiles of tumor cells using a cDNA microarray of 23040 genes (Okabe et al., Cancer Res 61:2129-37 (2001); Kitahara et al., Cancer Res 61:3544-9 (2001); Lin et al., Oncogene 21:4120-8 (2002); Hasegawa et al., Cancer Res 62:7012-7 (2002)).

Studies designed to reveal mechanisms of carcinogenesis have already facilitated identification of molecular targets for anti-tumor agents. For example, inhibitors of farnesyltransferase (FTIs) which were originally developed to inhibit the growth-signaling pathway related to Ras, whose activation depends on posttranslational farnesylation, has been effective in treating Ras-dependent tumors in animal models (He et al., Cell 99:335-45 (1999)). Clinical trials on human using a combination or anti-cancer drugs and anti-HER2 monoclonal antibody, trastuzumab, have been conducted to antagonize the proto-oncogene receptor HER2/neu; and have been achieving improved clinical response and overall survival of breast-cancer patients (Lin et al., Cancer Res 61:6345-9 (2001)). A tyrosine kinase inhibitor, STI-571, which selectively inactivates bcr-abl fusion proteins, has been developed to treat chronic myelogenous leukemias wherein constitutive activation of bcr-abl tyrosine kinase plays a crucial role in the transformation of leukocytes. Agents of these kinds are designed to suppress oncogenic activity of specific gene products (Fujita et al., Cancer Res 61:7722-6 (2001)). Therefore, gene products commonly up-regulated in cancerous cells may serve as potential targets for developing novel anti-cancer agents.

It has been demonstrated that CD8+ cytotoxic T lymphocytes (CTLs) recognize epitope peptides derived from tumor-associated antigens (TAAs) presented on MHC Class I molecule, and lyse tumor cells. Since the discovery of MAGE family as the first example of TAAs, many other TAAs have been discovered using immunological approaches (Boon, Int J Cancer 54: 177-80 (1993); Boon and van der Bruggen, J Exp Med 183: 725-9 (1996); van der Bruggen et al., Science 254: 1643-7 (1991); Brichard et al., J Exp Med 178: 489-95 (1993); Kawakami et al., J Exp Med 180: 347-52 (1994)). Some of the discovered TAAs are now in the stage of clinical development as targets of immunotherapy. TAAs discovered so far include MAGE (van der Bruggen et al., Science 254: 1643-7 (1991)), gp100 (Kawakami et al., J Exp Med 180: 347-52 (1994)), SART (Shichijo et al., J Exp Med 187: 277-88 (1998)), and NY-ESO-1 (Chen et al., Proc Natl Acad Sci USA 94: 1914-8 (1997)). On the other hand, gene products which had been demonstrated to be specifically over-expressed in tumor cells, have been shown to be recognized as targets inducing cellular immune responses. Such gene products include p53 (Umano et al., Brit J Cancer 84: 1052-7 (2001)), HER2/neu (Tanaka et al., Brit J Cancer 84: 94-9 (2001)), CEA (Nukaya et al., Int J Cancer 80: 92-7 (1999)), and so on.

In spite of significant progress in basic and clinical research concerning TAAs (Rosenbeg et al., Nature Med 4: 321-7 (1998); Mukherji et al., Proc Natl Acad Sci USA 92: 8078-82 (1995); Hu et al., Cancer Res 56: 2479-83 (1996)), only limited number of candidate TAAs for the treatment of adenocarcinomas, including cancer, are available. TAAs abundantly expressed in cancer cells, and at the same time which expression is restricted to cancer cells would be promising candidates as immunotherapeutic targets. Further, identification of new TAAs inducing potent and specific antitumor immune responses is expected to encourage clinical use of peptide vaccination strategy in various types of cancer (Boon and can der Bruggen, J Exp Med 183: 725-9 (1996); van der Bruggen et al., Science 254: 1643-7 (1991); Brichard et al., J Exp Med 178: 489-95 (1993); Kawakami et al., J Exp Med 180: 347-52 (1994); Shichijo et al., J Exp Med 187: 277-88 (1998); Chen et al., Proc Natl Acad Sci USA 94: 1914-8 (1997); Harris, J Natl Cancer Inst 88: 1442-5 (1996); Butterfield et al., Cancer Res 59: 3134-42 (1999); Vissers et al., Cancer Res 59: 5554-9 (1999); van der Burg et al., J Immunol 156: 3308-14 (1996); Tanaka et al., Cancer Res 57: 4465-8 (1997); Fujie et al., Int J Cancer 80: 169-72 (1999); Kikuchi et al., Int J Cancer 81: 459-66 (1999); Oiso et al., Int J Cancer 81: 387-94 (1999)).

It has been repeatedly reported that peptide-stimulated peripheral blood mononuclear cells (PBMCs) from certain healthy donors produce significant levels of IFN-γ in response to the peptide, but rarely exert cytotoxicity against tumor cells in an HLA-A24 or -A0201 restricted manner in ⁵¹Cr-release assays (Kawano et al., Cance Res 60: 3550-8 (2000); Nishizaka et al., Cancer Res 60: 4830-7 (2000); Tamura et al., Jpn J Cancer Res 92: 762-7 (2001)). However, both of HLA-A24 and HLA-A0201 are one of the popular HLA alleles in Japanese, as well as Caucasian (Date et al., Tissue Antigens 47: 93-101 (1996); Kondo et al., J Immunol 155: 4307-12 (1995); Kubo et al., J Immunol 152: 3913-24 (1994); Imanishi et al., Proceeding of the eleventh International Hictocompatibility Workshop and Conference Oxford University Press, Oxford, 1065 (1992); Williams et al., Tissue Antigen 49: 129 (1997)). Thus, antigenic peptides of carcinomas presented by these HLAs may be especially useful for the treatment of carcinomas among Japanese and Caucasian. Further, it is known that the induction of low-affinity CTL in vitro usually results from the use of peptide at a high concentration, generating a high level of specific peptide/MHC complexes on antigen presenting cells (APCs), which will effectively activate these CTL (Alexander-Miller et al., Proc Natl Acad Sci USA 93: 4102-7 (1996)).

### BRIEF SUMMARY OF THE INVENTION

The invention is based on the discovery of a pattern of gene expression correlated with PRC or PIN. The genes that are differentially expressed in either or both of PRC and PIN are collectively referred to herein as “PRC nucleic acids” or “PRC polynucleotides” and the corresponding encoded polypeptides are referred to as “PRC polypeptides” or “PRC proteins.”

Accordingly, the invention features a method of diagnosing or determining a predisposition to either or both of PRC and PIN in a subject by determining an expression level of a PRC-associated gene in a patient derived biological sample, such as tissue sample. By PRC associated gene is meant a gene that is characterized by an expression level which differs in a cell obtained from a PRC or PIN cell compared to a normal cell. A normal cell is one obtained from prostate tissue. A PRC-associated gene includes for example PRC 1-692. An alteration, e.g., increase or decrease of the level of expression of the gene compared to a normal control level of the gene indicates that the subject suffers from or is at risk of developing either or both of PRC and PIN.

By normal control level is meant a level of gene expression detected in a normal, healthy individual or in a population of individuals known not to be suffering from PRC and PIN. A control level is a single expression pattern derived from a single reference population or from a plurality of expression patterns. For example, the control level can be a database of expression patterns from previously tested cells. A normal individual is one with no clinical symptoms of PRC and PIN.

An increase in the level of PRC 1-88,296-321,458-537 detected in a test sample compared to a normal control level indicates the subject (from which the sample was obtained) suffers from or is at risk of developing at least either of PRC or PIN. In contrast, a decrease in the level of PRC 89-295,322-457,538-692 detected in a test sample compared to a normal control level indicates said subject suffers from or is at risk of developing either or both of PRC and PIN.

Alternatively, expression of a panel of PRC-associated genes in the sample is compared to a PRC control level of the same panel of genes. By PRC control level is meant the expression profile of the PRC-associated genes found in a population suffering from either or both of PRC and PIN.

Gene expression is increased or decreased 10%, 25%, 50% compared to the control level. Alternately, gene expression is increased or decreased 1, 2, 5 or more fold compared to the control level. Expression is determined by detecting hybridization, e.g., on an array, of a PRC-associated gene probe to a gene transcript of the patient-derived tissue sample.

The patient derived tissue sample is any tissue from a test subject, e.g., a patient known to or suspected of having PRC or PIN. For example, the tissue contains an epithelial cell. For example, the tissue is an epithelial cell from prostate tissue.

The invention also provides a PRC reference expression profile of a gene expression level of two or more of PRC 1-692. Alternatively, the invention provides a PRC reference expression profile of the levels of expression two or more of PRC 1-88, PRC 89-295, PRC 296-321, PRC 322-457, PRC 458-537, or PRC 538-692.

The invention further provides methods of identifying an agent that inhibits or enhances the expression or activity of a PRC-associated gene, e.g PRC 1-692 by contacting a test cell expressing a PRC associated gene with a test agent and determining the expression level of the PRC associated gene. The test cell is an epithelial cell such as an epithelial cell from prostate tissue. A decrease of the level compared to a control level of the gene indicates that the test agent is an inhibitor of the PRC-associated gene and reduces a symptom of either or both of PRC and PIN. Alternatively, an increase of the level or activity compared to a control level or activity of the gene indicates that said test agent is an enhancer of expression or function of the PRC associated gene and reduces a symptom of either or both of PRC and PIN, e.g, PRC 89-295, PRC 322-457, PRC 538-692.

The invention also provides a kit with a detection reagent which binds to two or more PRC nucleic acid sequences or which binds to a gene product encoded by the nucleic acid sequences. Also provided is an array of nucleic acids that binds to two or more PRC nucleic acids.

Therapeutic methods include a method of treating or preventing either or both of PRC and PIN in a subject by administering to the subject an antisense composition. The antisense composition reduces the expression of a specific target gene, e.g., the antisense composition contains a nucleotide, which is complementary to a sequence selected from the group consisting of PRC 1-88, 296-321, 458-537. Another method includes the steps of administering to a subject an small interfering RNA (siRNA) composition. The siRNA composition reduces the expression of a nucleic acid selected from the group consisting of PRC 1-88, 296-321, 458-537. In yet another method, treatment or prevention of either or both of PRC and PIN in a subject is carried out by administering to a subject a ribozyme composition. The nucleic acid-specific ribozyme composition reduces the expression of a nucleic acid selected from the group consisting of PRC 1-88, 296-321, 458-537. Other therapeutic methods include those in which a subject is administered a compound that increases the expression of PRC 89-295, 322-457, 538-692 or activity of a polypeptide encoded by PRC 89-295,322-457,538-692. Furthermore, either or both of PRC and PIN can be treated by administering a protein encoded by PRC 89-295,322-457,538-692. The protein may be directly administered to the patient or, alternatively, may be expressed in vivo subsequent to being introduced into the patient, for example, by administering an expression vector or host cell carrying the down-regulated marker gene of interest. Suitable mechanisms for in vivo expression of a gene of interest are known in the art.

The invention also includes vaccines and vaccination methods. For example, a method of treating or preventing either or both of PRC and PIN in a subject is carried out by administering to the subject a vaccine containing a polypeptide encoded by a nucleic acid selected from the group consisting of PRC 1-88, 296-321, 458-537 or an immunologically active fragment such a polypeptide. An immunologically active fragment is a polypeptide that is shorter in length than the full-length naturally-occurring protein and which induces an immune response. For example, an immunologically active fragment at least 8 residues in length and stimulates an immune cell such as a T cell or a B cell. Immune cell stimulation is measured by detecting cell proliferation, elaboration of cytokines (e.g., IL-2), or production of an antibody.

In the present invention, the present inventors have focused on one EST and identified a novel gene, CCDC4, over-expressed in prostate cancer cells. This gene corresponds to PRC 69 (EST AA743348) in Table 3.

As a result, CCDC4 was identified as specifically over-expressed gene in prostate cancer cells. The present inventors show the knocking-down effect of CCDC4 by siRNA attenuated the growth of prostate cancer cells and this molecule can be potentially targeted for drug design for novel therapies of prostate cancer.

CCDC4 encodes a 530-amino acid protein comprising coiled-coiled domain. According to a Northern blot analysis, the expression of CCDC4 was shown to be restricted to testis and prostate.

Many anticancer drugs are not only toxic to cancer cells but also for normally growing cells. However, agents suppressing the expression of CCDC4 may not adversely affect other organs due to the fact that normal expression of CCDC4 is restricted to testis and prostate, and thus may be conveniently used for treating or preventing prostate cancer.

Thus, the present invention provides isolated gene, CCDC4 which serves as candidates of diagnostic markers for prostate cancer as well as promising potential targets for developing new strategies for diagnosis and effective anti-cancer agents. Furthermore, the present invention provides polypeptide encoded by this gene, as well as the production and the use of the same. More specifically, the present invention provides the following:

The present application provides novel human polypeptide, CCDC4 or a functional equivalent thereof, which expressions are elevated in prostate cancer cells.

In a preferred embodiment, the CCDC4 polypeptide includes a 530 amino acid protein encoded by the open reading frame of SEQ ID NO: 1 or a 437 amino acid protein encoded by the open reading frame of SEQ 1N NO: 3. The CCDC4 polypeptide preferably includes the amino acid sequence set forth in SEQ ID NO: 2 (Gene Bank Accession number: AB 126828) or 4 (Gene Bank Accession number: AB 126829). The present application also provides an isolated protein encoded from at least a portion of the CCDC4 polynucleotide sequence, or polynucleotide sequences at least 15% and more preferably at least 25% homology to the sequence set forth in SEQ ID NO: 1 or 3.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

One advantage of the methods described herein is that the disease is identified prior to detection of overt clinical symptoms. Other features and advantages of the invention will be apparent from the following detailed description, and from the claims.

### BRIEF DESCRIPTION OF THE DRAWINGS

FIG. 1 is a photograph of a DNA agarose gel showing expression of representative 5 genes and β-actin examined by semi-quantitative RT-PCR using cDNA prepared from amplified RNA. Gene symbols are noted. T and N indicate tujors and normal, respectively for each of 8 patients.

FIG. 2(A) depicts photographs showing the results of semi-quantitative PCR. CCDC4 was over-expressed in prostate cancer cells microdissected from human prostate cancer tissues. FIG. 2(B) depicts photographs of Northern blot analysis showing the expression pattern in normal adult tissues of CCDC4. The 8.7 kb transcript, CCDC4, is expressed restrictedly only in adult testis and prostate.

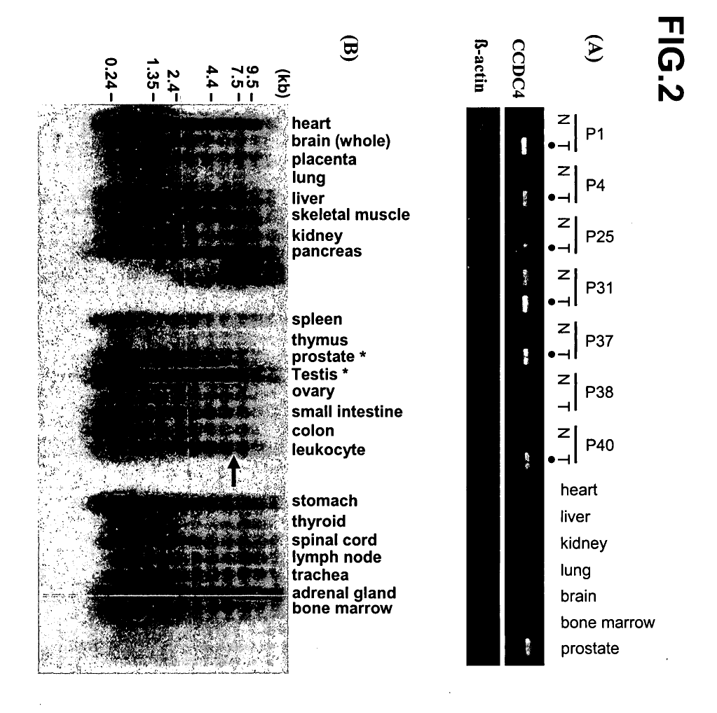

FIG. 3 shows the effects of Knocking-down endogenous CCDC4 in prostate cancer cell line, PRC3, by siRNA. FIG. 3(A) is a photograph showing the results of RT-PCR. This photograph validates the knockdown effect of CCDC4 mRNA by transfection of siRNA expression vectors si#1. The si#1 was designed specifically for CCDC4 mRNA sequence, and siEGFP was for EGFP mRNA sequence. RNA was harvested 48 hours after transfection and analyzed. ACTB was used to normalize input cDNA. FIG. 3(B) is a photograph showing the results of colony formation assay. This photograph shows the drastic decrease of colony numbers in PRC3 cells one week after transfection with si#1 that was validated to knock down CCDC4 effectively by RT-PCR. FIG. 3(C) is a bar chart showing the results of MTT assay. This assay also shows the drastic decreased number of the grown cells transfected with si#1.

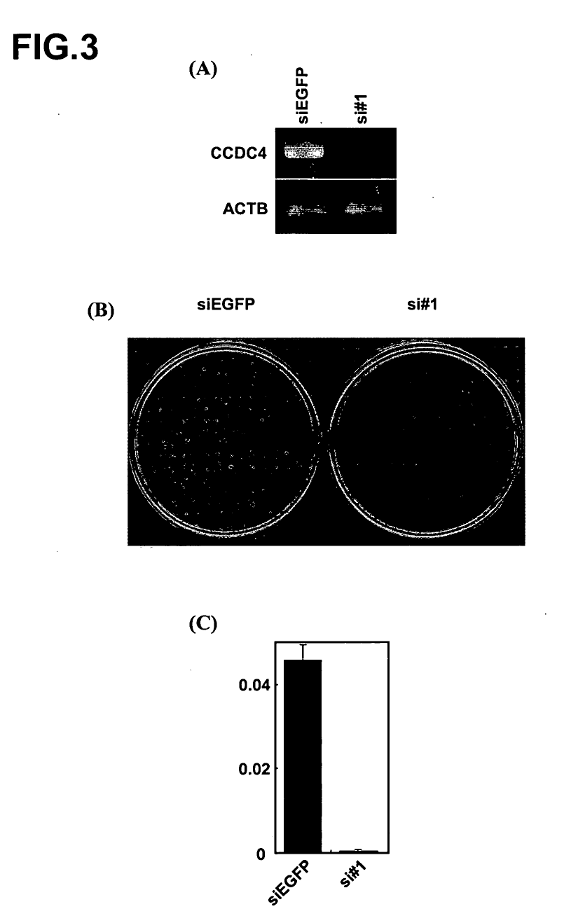

### DETAILED DESCRIPTION

The present invention is based in part on the discovery of changes in expression patterns of multiple nucleic acid sequences in epithelial cells of patients with PRC or PIN. The differences in gene expression were identified by using a comprehensive cDNA microarray system.
cDNA microarray is a powerful tool for identifying genes that may be applicable for development of novel molecular targets for therapeutic purposes (Ishiguro et al., Oncogene, 21, 6387-94 (2002); Yagyu et al., Int J Oncol, 20, 1173-8 (2002)). Now basic research about PRC are rapidly progressed recently by using genome information and new technologies, but most difficulty in studying human PRCs with histological heterogeneity is the inability to isolate pure samples for molecular analysis. Most of the previous studies have used bulk cancer tissues without eliminating contamination by non-cancerous cells including stroma cells, microvasculature cells, fibromuscular cells, inflammatory cells and other epithelial cells from benign lesions including PINs. However, laser microdissection allows us to overcome this hurdle and enables the precise evaluation of pure cell populations (Emmert-Buck et al., Science, 274:998-1001 (1996)) for PRC and PIN cells. Also, we compared gene expression of cancer cells with their corresponding normal epithelial cells as a control in each case. This procedure prevents individuality of gene expression from effecting on data. This study is the first report about precise expression profiles of PRCs and PINs, coupling with LMM. These data would provide important information on prostatic carcinogenesis and would be greatly useful to identify candidate genes whose products can be targeted for drug design for treatment and prevention of PRC.

The gene-expression profiles of cancer cells from 20 PRCs and 10 PINs were analyzed using cDNA microarray representing 23,040 genes coupled with laser microdissection. By comparing expression patterns between cancer cells from diagnostic PRC patients and normal epithelial cells purely selected with Laser Microdisection, 88 genes were identified as commonly up-regulated in PRC and PIN cells, and 207 genes were identified as being commonly down-regulated in PRC and PIN cells. 26 genes were identified as commonly up-regulated in PRC cells, and 136 genes were identified as being commonly down-regulated in PRC cells. 80 genes were identified as commonly up-regulated in PIN cells and 155 genes were identified as being commonly down-regulated in PIN cells. In addition, selection was made of candidate molecular markers with the potential of detecting cancer-related proteins in serum or sputum of patients, and discovered some potential targets for development of signal-suppressing strategies in human PRC or PIN.

The differentially expressed genes identified herein are used for diagnostic purposes as markers of PRC or PIN and as gene targets, the expression of which is altered to treat or alleviate a symptom of PRC or PIN.

The genes whose expression levels are modulated (i.e., increased or decreased) in either or both of PRC and PIN patients are summarized in Tables 3-8 and are collectively referred to herein as “PRC-associated genes”, “PRC nucleic acids” or “PRC polynucleotides” and the corresponding encoded polypeptides are referred to as “PRC polypeptides” or “PRC proteins.” Unless indicated otherwise, “PRC” is meant to refer to any of the sequences disclosed herein. (e.g., PRC 1-692). The genes that have been previously described are presented along with a database accession number.

By measuring expression of the various genes in a sample of cells, PRC and PIN are diagnosed. Similarly, by measuring the expression of these genes in response to various agents, agents for treating either or both of PRC and PIN can be identified.

The invention involves determining (e.g., measuring) the expression of at least one, and up to all the PRC sequences listed in Tables 3-8. Using sequence information provided by the GeneBank™ database entries for the known sequences the PRC associated genes are detected and measured using techniques well known to one of ordinary skill in the art. For example, sequences within the sequence database entries corresponding to PRC sequences, are used to construct probes for detecting PRC RNA sequences in, e.g., Northern blot hybridization analyses. Probes include at least 10, 20, 50, 100, 200 nucleotides of a reference sequence. As another example, the sequences can be used to construct primers for specifically amplifying the PRC nucleic acid in, e.g, amplification-based detection methods such as reverse-transcription based polymerase chain reaction.

Expression level of one or more of the PRC-associated genes in the test cell population, e.g., a patient derived tissues sample is then compared to expression levels of the some genes in a reference population. The reference cell population includes one or more cells for which the compared parameter is known, i.e., PRC cells or non-PRC cells.

Whether or not a pattern of gene expression in the test cell population compared to the reference cell population indicates PRC or PIN, or a predisposition thereto depends upon the composition of the reference cell population. For example, if the reference cell population is composed of non-PRC cells, a similar gene expression pattern in the test cell population and reference cell population indicates the test cell population is non-PRC. Conversely, if the reference cell population is made up of PRC cells, a similar gene expression profile between the test cell population and the reference cell population that the test cell population includes PRC cells.

A level of expression of a PRC marker gene in a test cell population is considered altered in levels of expression if its expression level varies from the reference cell population by more than 1.0, 1.5, 2.0, 5.0, 10.0 or more fold from the expression level of the corresponding PRC marker gene in the reference cell population.

Differential gene expression between a test cell population and a reference cell population is normalized to a control nucleic acid, e.g. a housekeeping gene. For example, a control nucleic acid is one which is known not to differ depending on the PRC or non-PRC state of the cell. Expression levels of the control nucleic acid in the test and reference nucleic acid can be used to normalize signal levels in the compared populations. Control genes include β-actin, glyceraldehyde 3-phosphate dehydrogenase or ribosomal protein P1.

The test cell population is compared to multiple reference cell populations. Each of the multiple reference populations may differ in the known parameter. Thus, a test cell population may be compared to a second reference cell population known to contain, e.g., PRC cells, as well as a second reference population known to contain, e.g., non-PRC cells (normal cells). The test cell is included in a tissue type or cell sample from a subject known to contain, or to be suspected of containing, PRC cells.

The test cell is obtained from a bodily tissue or a bodily fluid, e.g., biological fluid (such as blood, or serum). For example, the test cell is purified from a tissue. Preferably, the test cell population comprises an epithelial cell. The epithelial cell is from tissue known to be or suspected to be cancerous.

Cells in the reference cell population are derived from a tissue type as similar to test cell. Optionally, the refernce cell poulation is a cell line, e.g. a PRC cell line (positive control) or a normal non-PRC cell line (negative control). Alternatively, the control cell population is derived from a database of molecular information derived from cells for which the assayed parameter or condition is known.

The subject is preferably a mammal. The mammal can be, e.g., a human, non-human primate, mouse, rat, dog, cat, horse, or cow.

Expression of the genes disclosed herein is determined at the protein or nucleic acid level using methods known in the art. For example, Northern hybridization analysis using probes which specifically recognize one or more of these nucleic acid sequences can be used to determine gene expression. Alternatively, expression is measured using reverse-transcription-based PCR assays, e.g., using primers specific for the differentially expressed gene sequences. Expression is also determined at the protein level, i.e., by measuring the levels of polypeptides encoded by the gene products described herein, or biological activity thereof. Such methods are well known in the art and include, e.g., immunoassays based on antibodies to proteins encoded by the genes. The biological activities of the proteins encoded by the genes are also well known.

CCDC4

Using the methods described above, two genes with a similar sequence were identified. These genes correspond to PRC 69 (EST AA743348) in Table 3, below. As discussed below, these genes encode variants of CCDC4. The cDNA of the longer variant consists of 8763 nucleotides containing an open reading frame of 1593 nucleotides (SEQ ID NO: 1) and the shorter variant consists of 8692 nucleotides containing an open reading frame of 1314 nucleotides (SEQ ID NO: 3). These open reading frames encode a 530 amino acid-protein and a 437 amino acid-protein, respectively.

Thus, the present invention provides substantially pure polypeptides encoded by these genes including polypeptides comprising the amino acid sequence of SEQ ID NO: 2 or 4, as well as functional equivalents thereof, to the extent that they encode a CCDC4 protein. Examples of polypeptides functionally equivalent to CCDC4 include, for example, homologous proteins of other organisms corresponding to the human CCDC4 protein, as well as mutants of human CCDC4 proteins.

In the present invention, the term “functionally equivalent” means that the subject polypeptide has the activity to promote cell proliferation like the CCDC4 protein and to confer oncogenic activity to cancer cells. Whether the subject polypeptide has a cell proliferation activity or not can be judged by introducing the DNA encoding the subject polypeptide into a cell, expressing the respective polypeptide and detecting promotion of proliferation of the cells or increase in colony forming activity. Such cells include, for example, NIH3T3, COS7 and HEK293.

Methods for preparing polypeptides functionally equivalent to a given protein are well known by a person skilled in the art and include known methods of introducing mutations into the protein. For example, one skilled in the art can prepare polypeptides functionally equivalent to the human CCDC4 protein by introducing an appropriate mutation in the amino acid sequence of these proteins by site-directed mutagenesis (Hashimoto-Gotoh et al., Gene 152:271-5 (1995); Zoller and Smith, Methods Enzymol 100: 468-500 (1983); Kramer et al., Nucleic Acids Res. 12:9441-9456 (1984); Kramer and Fritz, Methods Enzymol 154: 350-67 (1987); Kunkel, Proc Natl Acad Sci USA 82: 488-92 (1985); Kunkel, Methods Enzymol 85: 2763-6 (1988)). Amino acid mutations can occur in nature, too. The polypeptide of the present invention includes those proteins having the amino acid sequences of the human CCDC4 protein in which one or more amino acids are mutated, provided the resulting mutated polypeptides are functionally equivalent to the human CCDC4 protein. The number of amino acids to be mutated in such a mutant is generally 10 amino acids or less, preferably 6 amino acids or less, and more preferably 3 amino acids or less.

Mutated or modified proteins, proteins having amino acid sequences modified by substituting, deleting, inserting and/or adding one or more amino acid residues of a certain amino acid sequence, have been known to retain the original biological activity (Mark et al., Proc Natl Acad Sci USA 81: 5662-6 (1984); Zoller and Smith, Nucleic Acids Res 10:6487-500 (1982); Dalbadie-McFarland et al., Proc Natl Acad Sci USA 79: 6409-13 (1982)).

The amino acid residue to be mutated is preferably mutated into a different amino acid in which the properties of the amino acid side-chain are conserved (a process known as conservative amino acid substitution). Examples of properties of amino acid side chains are hydrophobic amino acids (A, I, L, M, F, P, W, Y, V), hydrophilic amino acids (R, D, N, C, E, Q, G, H, K, S, T), and side chains having the following functional groups or characteristics in common: an aliphatic side-chain (G, A, V, L, I, P); a hydroxyl group containing side-chain (S, T, Y); a sulfur atom containing side-chain (C, M); a carboxylic acid and amide containing side-chain (D, N, E, Q); a base containing side-chain (R, K, H); and an aromatic containing side-chain (H, F, Y, W). Note, the parenthetic letters indicate the one-letter codes of amino acids.

An example of a polypeptide to which one or more amino acids residues are added to the amino acid sequence of human CCDC4 protein is a fusion protein containing the human CCDC4 protein. Fusion proteins, fusions of the human CCDC4 protein and other peptides or proteins, are included in the present invention. Fusion proteins can be made by techniques well known to a person skilled in the art, such as by linking the DNA encoding the human CCDC4 protein of the invention with DNA encoding other peptides or proteins, so that the frames match, inserting the fusion DNA into an expression vector and expressing it in a host. There is no restriction as to the peptides or proteins fused to the protein of the present invention.

Known peptides that can be used as peptides that are fused to the protein of the present invention include, for example, FLAG (Hopp et al., Biotechnology 6: 1204-10 (1988)), 6×His containing six His (histidine) residues, 10×His, Influenza agglutinin (HA), human c-myc fragment, VSP GP fragment, p18HIV fragment, T7-tag, HSV-tag, E-tag, SV40T antigen fragment, lck tag, α-tubulin fragment, B-tag, Protein C fragment and the like. Examples of proteins that may be fused to a protein of the invention include GST (glutathione-5-transferase), Influenza agglutinin (HA), immunoglobulin constant region, β-galactosidase, MBP (maltose-binding protein) and such.

Fusion proteins can be prepared by fusing commercially available DNA, encoding the fusion peptides or proteins discussed above, with the DNA encoding the polypeptide of the present invention and expressing the fused DNA prepared.

An alternative method known in the art to isolate functionally equivalent polypeptides is, for example, the method using a hybridization technique (Sambrook et al., Molecular Cloning 2nd ed. 9.47-9.58, Cold Spring Harbor Lab. Press (1989)). One skilled in the art can readily isolate a DNA having high homology with a whole or part of the DNA sequence encoding the human CCDC4 protein (i.e., SEQ ID NO: 1 or 3), and isolate functionally equivalent polypeptides to the human CCDC4 protein from the isolated DNA. The polypeptides of the present invention include those that are encoded by DNA that hybridize with a whole or part of the DNA sequence encoding the human CCDC4 protein and are functionally equivalent to the human CCDC4 protein. These polypeptides include mammal homologues corresponding to the protein derived from human (for example, a polypeptide encoded by a monkey, rat, rabbit and bovine gene). In isolating a cDNA highly homologous to the DNA encoding the human CCDC4 protein from animals, it is particularly preferable to use tissues from testis or prostate.

The condition of hybridization for isolating a DNA encoding a polypeptide functionally equivalent to the human CCDC4 protein can be routinely selected by a person skilled in the art. For example, hybridization may be performed by conducting prehybridization at 68° C. for 30 min or longer using “Rapid-hyb buffer” (Amersham LIFE SCIENCE), adding a labeled probe, and warming at 68° C. for 1 hour or longer. The following washing step can be conducted, for example, in a low stringent condition. A low stringent condition is, for example, 42° C., 2×SSC, 0.1% SDS, or preferably 50° C., 2×SSC, 0.1% SDS. More preferably, high stringent conditions are used. A high stringent condition is, for example, washing 3 times in 2×SSC, 0.01% SDS at room temperature for 20 min, then washing 3 times in 1×SSC, 0.1% SDS at 37° C. for 20 min, and washing twice in 1×SSC, 0.1% SDS at 50° C. for 20 min. However, several factors, such as temperature and salt concentration, can influence the stringency of hybridization and one skilled in the art can suitably select the factors to achieve the requisite stringency.

In place of hybridization, a gene amplification method, for example, the polymerase chain reaction (PCR) method, can be utilized to isolate a DNA encoding a polypeptide functionally equivalent to the human CCDC4 protein, using a primer synthesized based on the sequence information of the protein encoding DNA (SEQ ID NO: 1 or 3).

Polypeptides that are functionally equivalent to the human CCDC4 protein encoded by the DNA isolated through the above hybridization techniques or gene amplification techniques normally have a high homology to the amino acid sequence of the human CCDC4 protein. “High homology” typically refers to a homology of 40% or higher, preferably 60% or higher, more preferably 80% or higher, even more preferably 85%, 90%, 93%, 95%, 98%, 99% or higher between a polypeptide sequence or a polynucleotide sequence and a reference sequence. Percent homology (also referred to as percent identity) are typically carried out between two optimally aligned sequences. Methods of alignment of sequences for comparison are well-known in the art. Optimal alignment of sequences and comparison can be conducted, e.g., using the algorithm in “Wilbur and Lipman, Proc Natl Acad Sci USA 80: 726-30 (1983)”.

A polypeptide of the present invention have variations in amino acid sequence, molecular weight, isoelectric point, the presence or absence of sugar chains, or form, depending on the cell or host used to produce it or the purification method utilized. Nevertheless, so long as it has a function equivalent to that of the human CCDC4 protein of the present invention, it is within the scope of the present invention.

The polypeptides of the present invention can be prepared as recombinant proteins or natural proteins, by methods well known to those skilled in the art. A recombinant protein can be prepared by inserting a DNA, which encodes the polypeptide of the present invention (for example, the DNA comprising the nucleotide sequence of SEQ ID NO: 1 or 3), into an appropriate expression vector, introducing the vector into an appropriate host cell, obtaining the extract, and purifying the polypeptide by subjecting the extract to chromatography, e.g., ion exchange chromatography, reverse phase chromatography, gel filtration or affinity chromatography utilizing a column to which antibodies against the protein of the present invention is fixed or by combining more than one of aforementioned columns.

Also when the polypeptide of the present invention is expressed within host cells (for example, animal cells and E. coli) as a fusion protein with glutathione-5-transferase protein or as a recombinant protein supplemented with multiple histidines, the expressed recombinant protein can be purified using a glutathione column or nickel column. Alternatively, when the polypeptide of the present invention is expressed as a protein tagged with c-myc, multiple histidines or FLAG, it can be detected and purified using antibodies to c-myc, His or FLAG, respectively.

After purifying the fusion protein, it is also possible to exclude regions other than the objective polypeptide by cutting with thrombin or factor-Xa as required.

A natural protein can be isolated by methods known to a person skilled in the art, for example, by contacting the affinity column, in which antibodies binding to the CCDC4 protein described below are bound, with the extract of tissues or cells expressing the polypeptide of the present invention. The antibodies can be polyclonal antibodies or monoclonal antibodies.

The present invention also encompasses partial peptides of the polypeptide of the present invention. The partial peptide has an amino acid sequence specific to the polypeptide of the present invention and consists of at least 7 amino acids, preferably 8 amino acids or more, and more preferably 9 amino acids or more. The partial peptide can be used, for example, for preparing antibodies against the polypeptide of the present invention, screening for a compound that binds to the polypeptide of the present invention, and screening for inhibitors of the polypeptide of the present invention.

A partial peptide of the invention can be produced by genetic engineering, by known methods of peptide synthesis or by digesting the polypeptide of the invention with an appropriate peptidase. For peptide synthesis, for example, solid phase synthesis or liquid phase synthesis may be used.

The present invention further provides polynucleotides that encode such CCDC4 polypeptides described above. The polynucleotides of the present invention can be used for the in vivo or in vitro production of the polypeptide of the present invention as described above, or can be applied to gene therapy for diseases attributed to genetic abnormality in the gene encoding the protein of the present invention. Any form of the polynucleotide of the present invention can be used so long as it encodes the polypeptide of the present invention, including mRNA, RNA, cDNA, genomic DNA, chemically synthesized polynucleotides. The polynucleotide of the present invention includes a DNA comprising a given nucleotide sequences as well as its degenerate sequences, so long as the resulting DNA encodes a polypeptide of the present invention.

The polynucleotide of the present invention can be prepared by methods known to a person skilled in the art. For example, the polynucleotide of the present invention can be prepared by: preparing a cDNA library from cells which express the polypeptide of the present invention, and conducting hybridization using a partial sequence of the DNA of the present invention (for example, SEQ ID NO: 1 or 3) as a probe. A cDNA library can be prepared, for example, by the method described in Sambrook et al., Molecular Cloning, Cold Spring Harbor Laboratory Press (1989); alternatively, commercially available cDNA libraries may be used. A cDNA library can be also prepared by: extracting RNAs from cells expressing the polypeptide of the present invention, synthesizing oligo DNAs based on the sequence of the DNA of the present invention (for example, SEQ ID NO: 1 or 3), conducting PCR using the oligo DNAs as primers, and amplifying cDNAs encoding the protein of the present invention.

In addition, by sequencing the nucleotides of the obtained cDNA, the translation region encoded by the cDNA can be routinely determined, and the amino acid sequence of the polypeptide of the present invention can be easily obtained. Moreover, by screening the genomic DNA library using the obtained cDNA or parts thereof as a probe, the genomic DNA can be isolated.

More specifically, mRNAs may first be prepared from a cell, tissue or organ (e.g., testis or prostate) in which the object polypeptide of the invention is expressed. Known methods can be used to isolate mRNAs; for instance, total RNA may be prepared by guanidine ultracentrifugation (Chirgwin et al., Biochemistry 18:5294-9 (1979)) or AGPC method (Chomczynski and Sacchi, Anal Biochem 162:156-9 (1987)). In addition, mRNA may be purified from total RNA using mRNA Purification Kit (Pharmacia) and such. Alternatively, mRNA may be directly purified by QuickPrep mRNA Purification Kit (Pharmacia).

The obtained mRNA is used to synthesize cDNA using reverse transcriptase. cDNA may be synthesized using a commercially available kit, such as the AMV Reverse Transcriptase First-strand cDNA Synthesis Kit (Seikagaku Kogyo). Alternatively, cDNA may be synthesized and amplified following the 5′-RACE method (Frohman et al., Proc Natl Acad Sci USA 85: 8998-9002 (1988); Belyavsky et al., Nucleic Acids Res 17: 2919-32 (1989)), which uses a primer and such, described herein, the 5′-Ampli FINDER RACE Kit (Clontech), and polymerase chain reaction (PCR).

A desired DNA fragment is prepared from the PCR products and ligated with a vector DNA. The recombinant vectors are used to transform E. coli and such, and a desired recombinant vector is prepared from a selected colony. The nucleotide sequence of the desired DNA can be verified by conventional methods, such as dideoxynucleotide chain termination.

The nucleotide sequence of a polynucleotide of the invention may be designed to be expressed more efficiently by taking into account the frequency of codon usage in the host to be used for expression (Grantham et al., Nucleic Acids Res 9: 43-74 (1981)). The sequence of the polynucleotide of the present invention may be altered by a commercially available kit or a conventional method. For instance, the sequence may be altered by digestion with restriction enzymes, insertion of a synthetic oligonucleotide or an appropriate polynucleotide fragment, addition of a linker, or insertion of the initiation codon (ATG) and/or the stop codon (TAA, TGA or TAG).

Specifically, the polynucleotide of the present invention encompasses the DNA comprising the nucleotide sequence of SEQ ID NO: 1 or 3.

Furthermore, the present invention provides a polynucleotide that hybridizes under stringent conditions with a polynucleotide having a nucleotide sequence of SEQ ID NO: 1 or 3, and encodes a polypeptide functionally equivalent to the CCDC4 protein of the invention described above. One skilled in the art may appropriately choose stringent conditions. For example, low stringent condition can be used. More preferably, high stringent condition can be used. These conditions are the same as that described above. The hybridizing DNA above is preferably a cDNA or a chromosomal DNA.

The present invention also provides a polynucleotide which is complementary to the polynucleotide encoding human CCDC4 protein (SEQ ID NO: 1 or 3) or the complementary strand thereof, and which comprises at least 15 nucleotides. The polynucleotide of the present invention is preferably a polynucleotide which specifically hybridizes with the DNA encoding the CCDC4 polypeptide of the present invention. The term “specifically hybridize” as used herein, means that cross-hybridization does not occur significantly with DNA encoding other proteins, under the usual hybridizing conditions, preferably under stringent hybridizing conditions. Such polynucleotides include, probes, primers, nucleotides and nucleotide derivatives (for example, antisense oligonucleotides and ribozymes), which specifically hybridize with DNA encoding the polypeptide of the invention or its complementary strand. Moreover, such polynucleotide can be utilized for the preparation of DNA chip.

Vectors and Host Cells

The present invention also provides a vector and host cell into which a polynucleotide of the present invention is introduced. A vector of the present invention is useful to keep a polynucleotide, especially a DNA, of the present invention in host cell, to express the polypeptide of the present invention, or to administer the polynucleotide of the present invention for gene therapy.

When E. coli is a host cell and the vector is amplified and produced in a large amount in E. coli (e.g., JM109, DH5α, HB101 or XL1Blue), the vector should have “ori” to be amplified in E. coli and a marker gene for selecting transformed E. coli (e.g., a drug-resistance gene selected by a drug such as ampicillin, tetracycline, kanamycin, chloramphenicol or the like). For example, M13-series vectors, pUC-series vectors, pBR322, pBluescript, pCR-Script, etc. can be used. In addition, pGEM-T, pDIRECT and pT7 can also be used for subcloning and extracting cDNA as well as the vectors described above. When a vector is used to produce the protein of the present invention, an expression vector is especially useful. For example, an expression vector to be expressed in E. coli should have the above characteristics to be amplified in E. coli. When E. coli, such as JM109, DH5α, HB101 or XL1 Blue, are used as a host cell, the vector should have a promoter, for example, lacZ promoter (Ward et al., Nature 341: 544-6 (1989); FASEB J 6: 2422-7 (1992)), araB promoter (Better et al., Science 240: 1041-3 (1988)), T7 promoter or the like, that can efficiently express the desired gene in E. coli. In that respect, pGEX-5X-1 (Pharmacia), “QIAexpress system” (Qiagen), pEGFP and pET (in this case, the host is preferably BL21 which expresses T7 RNA polymerase), for example, can be used instead of the above vectors. Additionally, the vector may also contain a signal sequence for polypeptide secretion. An exemplary signal sequence that directs the polypeptide to be secreted to the periplasm of the E. coli is the pelB signal sequence (Lei et al., J Bacteriol 169: 4379 (1987)). Means for introducing of the vectors into the target host cells include, for example, the calcium chloride method, and the electroporation method.

In addition to E. coli, for example, expression vectors derived from mammals (for example, pcDNA3 (Invitrogen) and pEGF-BOS (Nucleic Acids Res 18(17): 5322 (1990)), pEF, pCDM8), expression vectors derived from insect cells (for example, “Bac-to-BAC baculovirus expression system” (GIBCO BRL), pBacPAK8), expression vectors derived from plants (e.g., pMH1, pMH2), expression vectors derived from animal viruses (e.g., pHSV, pMV, pAdexLcw), expression vectors derived from retroviruses (e.g., pZIpneo), expression vector derived from yeast (e.g., “Pichia Expression Kit” (Invitrogen), pNV11, SP-Q01) and expression vectors derived from Bacillus subtilis (e.g., pPL608, pKTH50) can be used for producing the polypeptide of the present invention.

In order to express the vector in animal cells, such as CHO, COS or NIH3T3 cells, the vector should have a promoter necessary for expression in such cells, for example, the SV40 promoter (Mulligan et al., Nature 277: 108 (1979)), the MMLV-LTR promoter, the EF1αpromoter (Mizushima et al., Nucleic Acids Res 18: 5322 (1990)), the CMV promoter and the like, and preferably a marker gene for selecting transformants (for example, a drug resistance gene selected by a drug (e.g., neomycin, G418)). Examples of known vectors with these characteristics include, for example, pMAM, pDR2, pBK-RSV, pBK-CMV, pOPRSV and pOP13.

Producing Polypeptides

In addition, the present invention provides methods for producing a polypeptide of the present invention. The polypeptides may be prepared by culturing a host cell which harbors an expression vector comprising a gene encoding the polypeptide. According to needs, methods may be used to express a gene stably and, at the same time, to amplify the copy number of the gene in cells. For example, a vector comprising the complementary DHFR gene (e.g., pCHO I) may be introduced into CHO cells in which the nucleic acid synthesizing pathway is deleted, and then amplified by methotrexate (MTX). Furthermore, in case of transient expression of a gene, the method wherein a vector comprising a replication origin of SV40 (pcD, etc.) is transformed into COS cells comprising the SV40 T antigen expressing gene on the chromosome can be used.

A polypeptide of the present invention obtained as above may be isolated from inside or outside (such as medium) of host cells and purified as a substantially pure homogeneous polypeptide. The term “substantially pure” as used herein in reference to a given polypeptide means that the polypeptide is substantially free from other biological macromolecules. The substantially pure polypeptide is at least 75% (e.g., at least 80, 85, 95, or 99%) pure by dry weight. Purity can be measured by any appropriate standard method, for example by column chromatography, polyacrylamide gel electrophoresis, or HPLC analysis. The method for polypeptide isolation and purification is not limited to any specific method; in fact, any standard method may be used.

For instance, column chromatography, filter, ultrafiltration, salt precipitation, solvent precipitation, solvent extraction, distillation, immunoprecipitation, SDS-polyacrylamide gel electrophoresis, isoelectric point electrophoresis, dialysis, and recrystallization may be appropriately selected and combined to isolate and purify the polypeptide.

Examples of chromatography include, for example, affinity chromatography, ion-exchange chromatography, hydrophobic chromatography, gel filtration, reverse phase chromatography, adsorption chromatography, and such (Strategies for Protein Purification and Characterization: A Laboratory Course Manual. Ed. Daniel R. Marshak et al., Cold Spring Harbor Laboratory Press (1996)). These chromatographies may be performed by liquid chromatography, such as HPLC and FPLC. Thus, the present invention provides for highly purified polypeptides prepared by the above methods.

A polypeptide of the present invention may be optionally modified or partially deleted by treating it with an appropriate protein modification enzyme before or after purification. Useful protein modification enzymes include, but are not limited to, trypsin, chymotrypsin, lysylendopeptidase, protein kinase, glucosidase and so on.

Antibodies

The present invention provides an antibody that binds to the polypeptide of the invention. The antibody of the invention can be used in any form, such as monoclonal or polyclonal antibodies, and includes antiserum obtained by immunizing an animal such as a rabbit with the polypeptide of the invention, all classes of polyclonal and monoclonal antibodies, human antibodies and humanized antibodies produced by genetic recombination.

A polypeptide of the invention used as an antigen to obtain an antibody may be derived from any animal species, but preferably is derived from a mammal such as a human, mouse, or rat, more preferably from a human. A human-derived polypeptide may be obtained from the nucleotide or amino acid sequences disclosed herein.

According to the present invention, the polypeptide to be used as an immunization antigen may be a complete protein or a partial peptide of the protein. A partial peptide may comprise, for example, the amino (N)-terminal or carboxy (C)-terminal fragment of a polypeptide of the present invention.

Herein, an antibody is defined as a protein that reacts with either the full length or a fragment of a polypeptide of the present invention.

A gene encoding a polypeptide of the invention or its fragment may be inserted into a known expression vector, which is then used to transform a host cell as described herein. The desired polypeptide or its fragment may be recovered from the outside or inside of host cells by any standard method, and may subsequently be used as an antigen. Alternatively, whole cells expressing the polypeptide or their lysates or a chemically synthesized polypeptide may be used as the antigen.

Any mammalian animal may be immunized with the antigen, but preferably the compatibility with parental cells used for cell fusion is taken into account. In general, animals of Rodentia, Lagomorpha or Primates are used. Animals of Rodentia include, for example, mouse, rat and hamster. Animals of Lagomorpha include, for example, rabbit. Animals of Primates include, for example, a monkey of Catarrhini (old world monkey) such as Macaca fascicularis, rhesus monkey, sacred baboon and chimpanzees.

Methods for immunizing animals with antigens are known in the art. Intraperitoneal injection or subcutaneous injection of antigens is a standard method for immunization of mammals. More specifically, antigens may be diluted and suspended in an appropriate amount of phosphate buffered saline (PBS), physiological saline, etc. If desired, the antigen suspension may be mixed with an appropriate amount of a standard adjuvant, such as Freund's complete adjuvant, made into emulsion and then administered to mammalian animals. Preferably, it is followed by several administrations of antigen mixed with an appropriately amount of Freund's incomplete adjuvant every 4 to 21 days. An appropriate carrier may also be used for immunization. After immunization as above, serum is examined by a standard method for an increase in the amount of desired antibodies.

Polyclonal antibodies against the polypeptides of the present invention may be prepared by collecting blood from the immunized mammal examined for the increase of desired antibodies in the serum, and by separating serum from the blood by any conventional method. Polyclonal antibodies include serum containing the polyclonal antibodies, as well as the fraction containing the polyclonal antibodies may be isolated from the serum. Immunoglobulin G or M can be prepared from a fraction which recognizes only the polypeptide of the present invention using, for example, an affinity column coupled with the polypeptide of the present invention, and further purifying this fraction using protein A or protein G column.

To prepare monoclonal antibodies, immune cells are collected from the mammal immunized with the antigen and checked for the increased level of desired antibodies in the serum as described above, and are subjected to cell fusion. The immune cells used for cell fusion are preferably obtained from spleen. Other preferred parental cells to be fused with the above immunocyte include, for example, myeloma cells of mammalians, and more preferably myeloma cells having an acquired property for the selection of fused cells by drugs.

The above immunocyte and myeloma cells can be fused according to known methods, for example, the method of Milstein et al. (Galfre and Milstein, Methods Enzymol 73: 3-46 (1981)).

Resulting hybridomas obtained by the cell fusion may be selected by cultivating them in a standard selection medium, such as HAT medium (hypoxanthine, aminopterin and thymidine containing medium). The cell culture is typically continued in the HAT medium for several days to several weeks, the time being sufficient to allow all the other cells, with the exception of the desired hybridoma (non-fused cells), to die. Then, the standard limiting dilution is performed to screen and clone a hybridoma cell producing the desired antibody.

In addition to the above method, in which a non-human animal is immunized with an antigen for preparing hybridoma, human lymphocytes such as those infected by EB virus may be immunized with a polypeptide, polypeptide expressing cells or their lysates in vitro. Then, the immunized lymphocytes are fused with human-derived myeloma cells that are capable of indefinitely dividing, such as U266, to yield a hybridoma producing a desired human antibody that is able to bind to the polypeptide can be obtained (Unexamined Published Japanese Patent Application No. (JP-A) Sho 63-17688).

The obtained hybridomas are subsequently transplanted into the abdominal cavity of a mouse and the ascites are extracted. The obtained monoclonal antibodies can be purified by, for example, ammonium sulfate precipitation, a protein A or protein G column, DEAE ion exchange chromatography or an affinity column to which the polypeptide of the present invention is coupled. The antibody of the present invention can be used not only for purification and detection of the polypeptide of the present invention, but also as a candidate for agonists and antagonists of the polypeptide of the present invention. In addition, this antibody can be applied to the antibody treatment for diseases related to the polypeptide of the present invention. When the obtained antibody is to be administered to the human body (antibody treatment), a human antibody or a humanized antibody is preferable for reducing immunogenicity.

For example, transgenic animals having a repertory of human antibody genes may be immunized with an antigen selected from a polypeptide, polypeptide expressing cells or their lysates. Antibody producing cells are then collected from the animals and fused with myeloma cells to obtain hybridoma, from which human antibodies against the polypeptide can be prepared (see WO92-03918, WO93-2227, WO94-02602, WO94-25585, WO96-33735 and WO96-34096).

Alternatively, an immune cell, such as an immunized lymphocyte, producing antibodies may be immortalized by an oncogene and used for preparing monoclonal antibodies.

Monoclonal antibodies thus obtained can be also recombinantly prepared using genetic engineering techniques (see, for example, Borrebaeck and Larrick, Therapeutic Monoclonal Antibodies, published in the United Kingdom by MacMillan Publishers LTD (1990)). For example, a DNA encoding an antibody may be cloned from an immune cell, such as a hybridoma or an immunized lymphocyte producing the antibody, inserted into an appropriate vector, and introduced into host cells to prepare a recombinant antibody. The present invention also provides recombinant antibodies prepared as described above.

Furthermore, an antibody of the present invention may be a fragment of an antibody or modified antibody, so long as it binds to one or more of the polypeptides of the invention. For instance, the antibody fragment may be Fab, F(ab′)2, Fv or single chain Fv (scFv), in which Fv fragments from H and L chains are ligated by an appropriate linker (Huston et al., Proc Natl Acad Sci USA 85: 5879-83 (1988)). More specifically, an antibody fragment may be generated by treating an antibody with an enzyme, such as papain or pepsin. Alternatively, a gene encoding the antibody fragment may be constructed, inserted into an expression vector and expressed in an appropriate host cell (see, for example, Co et al., J Immunol 152: 2968-76 (1994); Better and Horwitz, Methods Enzymol 178: 476-96 (1989); Pluckthun and Skerra, Methods Enzymol 178: 497-515 (1989); Lamoyi, Methods Enzymol 121: 652-63 (1986); Rousseaux et al., Methods Enzymol 121: 663-9 (1986); Bird and Walker, Trends Biotechnol 9: 132-7 (1991)).

An antibody may be modified by conjugation with a variety of molecules, such as polyethylene glycol (PEG). The present invention provides for such modified antibodies. The modified antibody can be obtained by chemically modifying an antibody. These modification methods are conventional in the field.

Alternatively, an antibody of the present invention may be obtained as a chimeric antibody, between a variable region derived from nonhuman antibody and the constant region derived from human antibody, or as a humanized antibody, comprising the complementarity determining region (CDR) derived from nonhuman antibody, the frame work region (FR) and the constant region derived from human antibody. Such antibodies can be prepared according to known technology. Humanization can be performed by substituting rodent CDRs or CDR sequences for the corresponding sequences of a human antibody (see e.g., Verhoeyen et al., Science 239:1534-1536 (1988)). Accordingly, such humanized antibodies are chimeric antibodies, wherein substantially less than an intact human variable domain has been substituted by the corresponding sequence from a non-human species.

Fully human antibodies comprising human variable regions in addition to human framework and constant regions can also be used. Such antibodies can be produced using various techniques known in the art. For example in vitro methods involve use of recombinant libraries of human antibody fragments displayed on bacteriophage (e.g., Hoogenboom & Winter, J. Mol. Biol. 227:381 (1991), Similarly, human antibodies can be made by introducing of human immunoglobulin loci into transgenic animals, e.g., mice in which the endogenous immunoglobulin genes have been partially or completely inactivated. This approach is described, e.g., in U.S. Pat. Nos. 6,150,584, 5,545,807; 5,545,806; 5,569,825; 5,625,126; 5,633,425; 5,661,016.

Antibodies obtained as above may be purified to homogeneity. For example, the separation and purification of the antibody can be performed according to separation and purification methods used for general proteins. For example, the antibody may be separated and isolated by the appropriately selected and combined use of column chromatographies, such as affinity chromatography, filter, ultrafiltration, salting-out, dialysis, SDS polyacrylamide gel electrophoresis and isoelectric focusing (Antibodies: A Laboratory Manual. Ed Harlow and David Lane, Cold Spring Harbor Laboratory (1988)), but are not limited thereto. A protein A column and protein G column can be used as the affinity column. Exemplary protein A columns to be used include, for example, Hyper D, POROS and Sepharose F.F. (Pharmacia).

Exemplary chromatography, with the exception of affinity includes, for example, ion-exchange chromatography, hydrophobic chromatography, gel filtration, reverse-phase chromatography, adsorption chromatography and the like (Strategies for Protein Purification and Characterization: A Laboratory Course Manual. Ed Daniel R. Marshak et al., Cold Spring Harbor Laboratory Press (1996)). The chromatographic procedures can be carried out by liquid-phase chromatography, such as HPLC and FPLC.

For example, measurement of absorbance, enzyme-linked immunosorbent assay (ELISA), enzyme immunoassay (EIA), radioimmunoassay (RIA) and/or immunofluorescence may be used to measure the antigen binding activity of the antibody of the invention. In ELISA, the antibody of the present invention is immobilized on a plate, a polypeptide of the invention is applied to the plate, and then a sample containing a desired antibody, such as culture supernatant of antibody producing cells or purified antibodies, is applied. Then, a secondary antibody that recognizes the primary antibody and is labeled with an enzyme, such as alkaline phosphatase, is applied, and the plate is incubated. Next, after washing, an enzyme substrate, such as p-nitrophenyl phosphate, is added to the plate, and the absorbance is measured to evaluate the antigen binding activity of the sample. A fragment of the polypeptide, such as a C-terminal or N-terminal fragment, may be used as the antigen to evaluate the binding activity of the antibody. BIAcore (Pharmacia) may be used to evaluate the activity of the antibody according to the present invention.

The above methods allow for the detection or measurement of the polypeptide of the invention, by exposing the antibody of the invention to a sample assumed to contain the polypeptide of the invention, and detecting or measuring the immune complex formed by the antibody and the polypeptide.

Because the method of detection or measurement of the polypeptide according to the invention can specifically detect or measure a polypeptide, the method may be useful in a variety of experiments in which the polypeptide is used.

Diagnosing PRC or PIN

PRC or PIN is diagnosed by measuring the expression level of one or more PRC nucleic acid sequences from a test population of cells, (i.e., a patient derived biological sample). Preferably, the test cell population comprises an epithelial cell, e.g., a cell obtained from prostate tissue. Gene expression is also measured from blood or other bodily fluids such as urine. Other biological samples can be used for measuring the protein level. For example, the protein level in the blood, or serum derived from subject to be diagnosed can be measured by immunoassay or biological assay.

Expression of one or more of a PRC-associated gene, e.g., PRC 1-692 is determined in the test cell or biological sample and compared to the expression of the normal control level. A normal control level is an expression profile of a PRC-associated gene typically found in a population known not to be suffering from PRC. An increase or a decrease of the 110 level of expression in the patient derived tissue sample of the PRC associated genes indicates that the subject is suffering from or is at risk of developing PRC or PIN. For example, an increase in expression of PRC 1-88, PRC 296-321, PRC 458-537 in the test population compared to the normal control level indicates that the subject is suffering from or is at risk of developing PRC or PIN. Conversely, a decrease in expression of PRC 89-295, PRC 322-457, PRC 538-692 in the test population compared to the normal control level indicates that the subject is suffering from or is at risk of developing PRC or PIN.

When one or more of the PRC-associated genes are altered in the test population compared to the normal control level indicates that the subject suffers from or is at risk of developing PRC or PIN. For example, at least 1%, 5%, 25%, 50%, 60%, 80%, 90% or more of the panel of PRC-associated genes (PRC 1-88, PRC 296-321, PRC 458-537, PRC 89-295, PRC 322-457, or PRC 538-692) are altered.

The expression levels of the PRC 1-692 in a particular specimen can be estimated by quantifying mRNA corresponding to or protein encoded by PRC 1-692. Quantification methods for mRNA are known to those skilled in the art. For example, the levels of mRNAs corresponding to the PRC 1-692 can be estimated by Northern blotting or RT-PCR. Since the nucleotide sequence of the PRC 1-692 have already been reported. Anyone skilled in the art can design the nucleotide sequences for probes or primers to quantify the PRC 1-692.

Also the expression level of the PRC 1-692 can be analyzed based on the activity or quantity of protein encoded by the gene. A method for determining the quantity of the PRC 1-692 protein is shown in bellow. For example, immunoassay method is useful for the determination of the proteins in biological materials. Any biological materials can be used for the determination of the protein or it's activity. For example, blood sample is analyzed for estimation of the protein encoded by a serum marker. On the other hand, a suitable method can be selected for the determination of the activity of a protein encoded by the PRC 1-692 according to the activity of a protein to be analyzed.

In the present invention, a diagnostic agent for diagnosing PRC or PIN, is also provided. The diagnostic agent of the present invention comprises a compound that binds to a polynucleotide or a polypeptide of the present invention. Preferably, an oligonucleotide that hybridizes to the polynucleotide of the PRC 1-692, or an antibody that binds to the polypeptide of the PRC 1-692 may be used as such a compound.

In the present invention, PRC 1-692 are useful for diagnosing either or both of PRC and PIN. PRC 1-295 are useful for diagnosing both of PRC and PIN. PRC 296-457 are also useful for diagnosing PRC as PRC specific markers. Furthermore, PRC 458-692 are useful for diagnosing PIN as PIN specific markers.

Identifying Agents that Inhibit or Enhance PRC-Associated Gene Expression

An agent that inhibits the expression or activity of an PRC-associated gene is identified by contacting a test cell population expressing an PRC associated up-regulated gene with a test agent and determining the expression level of the PRC associated gene. A decrease in expression in the presence of the agent compared to the control level (or compared to the level in the absence of the test agent) indicates the agent is an inhibitor of an PRC associated up-regulated gene and useful to inhibit PRC or PIN.

Alternatively, an agent that enhances the expression or activity of an PRC down-regulated associated gene is identified by contacting a test cell population expressing an PRC associated gene with a test agent and determining the expression level or activity of the PRC associated down-regulated gene. An increase of expression or activity compared to a control expression level or activity (or compared to the level in the absence of the test agent) of the PRC-associated gene indicates that the test agent augments expression or activity of the down-regulated PRC associated gene.

The test cell population is any cell expressing the PRC-associated genes. For example, the test cell population contains an epithelial cell, such as a cell is or derived from prostate. For example, the test cell is immortalized cell line derived from a PRC cell. Alternatively, the test cell is a cell, which has been transfected with a PRC-associated gene or which has been transfected with a regulatory sequence (e.g. promoter sequence) from a PRC-associated gene operably linked to a reporter gene.

Assessing Efficacy of Treatment of PRC or PIN in a Subject

The differentially expressed PRC-associated gene identified herein also allow for the course of treatment of either or both of PRC and PIN to be monitored. In this method, a test cell population is provided from a subject undergoing treatment for PRC or PIN. If desired, test cell populations are obtained from the subject at various time points before, during, or after treatment. Expression of one or more of the PRC-associated gene, in the cell population is then determined and compared to a reference cell population which includes cells whose PRC state is known. The reference cells have not been exposed to the treatment.

If the reference cell population contains no PRC cells, a similarity in expression between PRC-associated gene in the test cell population and the reference cell population indicates that the treatment is efficacious. However, a difference in expression between PRC-associated gene in the test population and a normal control reference cell population indicates a less favorable clinical outcome or prognosis.

By “efficacious” is meant that the treatment leads to a reduction in expression of a pathologically up-regulated gene, increase in expression of a pathologically down-regulated gene or a decrease in size, prevalence, or metastatic potential of PRC in a subject. When treatment is applied prophylactically, “efficacious” means that the treatment retards or prevents a PRC or PIN from forming or retards, prevents, or alleviates a symptom of clinical PRC or PIN. Assesment of prostate tumors are made using standard clinical protocols.

Efficaciousness is determined in association with any known method for diagnosing or treating either or both of PRC and PIN. PRC is diagnosed for example, by identifying symptomatic anomalies, e.g., urinary symptoms such as difficulty in starting or stopping the stream, dysuria, frequency, or hematuria.

Selecting a Therapeutic Agent for Treating PRC or PIN that is Appropriate for a Particular Individual

Differences in the genetic makeup of individuals can result in differences in their relative abilities to metabolize various drugs. An agent that is metabolized in a subject to act as an inhibitor of PRC or PIN can manifest itself by inducing a change in gene expression pattern in the subject's cells from that characteristic of an PRC state to a gene expression pattern characteristic of a non-PRC state. Accordingly, the differentially expressed PRC-associated gene disclosed herein allow for a putative therapeutic or prophylactic inhibitor of PRC or PIN to be tested in a test cell population from a selected subject in order to determine if the agent is a suitable PRC or PIN inhibitor in the subject.

To identify a inhibitor of PRC or PIN, that is appropriate for a specific subject, a test cell population from the subject is exposed to a therapeutic agent, and the expression of one or more of PRC 1-692 genes is determined.

The test cell population contains a PRC or PIN cell expressing a PRC associated gene. Preferably, the test cell is an epithelial cell. For example a test cell population is incubated in the presence of a candidate agent and the pattern of gene expression of the test sample is measured and compared to one or more reference profiles, e.g., an PRC reference expression profile or an non-PRC reference expression profile.

A decrease in expression of one or more of PRC 1-88, PRC 296-321, PRC 458-537 or an increase in expression of one or more of PRC 89-295, PRC 322-457, PRC 538-692 in a test cell population relative to a reference cell population containing PRC is indicative that the agent is therapeutic.

The test agent can be any compound or composition. For example, the test agents are immunomodulatory agents.

Screening Assays for Identifying Therapeutic Agents

The differentially expressed genes disclosed herein can also be used to identify candidate therapeutic agents for treating PRC or PIN. The method is based on screening a candidate therapeutic agent to determine if it converts an expression profile of PRC 1-692 characteristic of an PRC state to a pattern indicative of a non-PRC state.

In the present invention, PRC 1-692 are useful for screening of therapeutic agent for treating or preventing either or both of PRC and PIN. PRC 1-295 are used for screening of therapeutic agent for treating or preventing both of PRC and PIN. PRC 296-457 are also used as PRC specific markers for screening of therapeutic agent for treating or preventing PRC. Furthermore, PRC 458-692 are used as PIN specific markers for screening of therapeutic agent for treating or preventing PIN or preventing PRC.

In the method, a cell is exposed to a test agent or a combination of test agents (sequentially or consequentially) and the expression of one or more PRC 1-692 in the cell is measured. The expression profile of the PRC-associated gene in the test population is compared to expression level of the PRC-associated gene in a reference cell population that is not exposed to the test agent.

An agent effective in stimulating expression of under-expressed genes, or in suppressing expression of over-expressed genes is deemed to lead to a clinical benefit such compounds are further tested for the ability to prevent PRC in animals or test subjects.

In a further embodiment, the present invention provides methods for screening candidate agents which are potential targets in the treatment or prevention of either or both of PRC and PIN. As discussed in detail above, by controlling the expression levels or activities of marker genes, one can control the onset and progression of either or both of PRC and PIN. Thus, candidate agents, which are potential targets in the treatment or prevention of either or both of PRC and PIN, can be identified through screenings that use the expression levels and activities of marker genes as indices. In the context of the present invention, such screening may comprise, for example, the following steps:
a) contacting a test compound with a polypeptide encoded by a nucleic acid selected from the group consisting of PRC 1-692;
b) detecting the binding activity between the polypeptide and the test compound; and
c) selecting a compound that binds to the polypeptide.

Alternatively, the screening method of the present invention may comprise the following steps:
a) contacting a candidate compound with a cell expressing one or more marker genes, wherein the one or more marker genes is selected from the group consisting of PRC 1-692; and
b) selecting a compound that reduces the expression level of one or more marker genes selected from the group consisting of PRC 1-88, 296-321, 458-537, or elevates the expression level of one or more marker genes selected from the group consisting of PRC 89-295,322-457,538-692.

Cells expressing a marker gene include, for example, cell lines established from PRC; such cells can be used for the above screening of the present invention.

Alternatively, the screening method of the present invention may comprise the following steps:
a) contacting a test compound with a polypeptide encoded by a nucleic acid selected from the group consisting of PRC 1-692;
b) detecting the biological activity of the polypeptide of step (a); and
c) selecting a compound that suppresses the biological activity of the polypeptide encoded by a nucleic acid selected from the group consisting of PRC 1-88, 296-321, 458-537 in comparison with the biological activity detected in the absence of the test compound, or enhances the the biological activity of the polypeptide encoded by a nucleic acid selected from the group consisting of PRC 89-295,322-457,538-692 in comparison with the biological activity detected in the absence of the test compound.

A protein required for the screening can be obtained as a recombinant protein using the nucleotide sequence of the marker gene. Based on the information of the marker gene, one skilled in the art can select any biological activity of the protein as an index for screening and a measurement method based on the selected biological activity.

Alternatively, the screening method of the present invention may comprise the following steps:
a) contacting a candidate compound with a cell into which a vector comprising the transcriptional regulatory region of one or more marker genes and a reporter gene that is expressed under the control of the transcriptional regulatory region has been introduced, wherein the one or more marker genes are selected from the group consisting of PRC 1-692
b) measuring expression level or the activity of said reporter gene; and
c) selecting a compound that reduces the expression level or activity of said reporter gene when said marker gene is an up-regulated marker gene selected from the group consisting of PRC 1-88, 296-321, 458-537 as compared to a control, or that enhances the expression level of said reporter gene when said marker gene is a down-regulated marker gene selected from the group consisting of PRC 89-295,322-457,538-692, as compared to a control.

Suitable reporter genes and host cells are well known in the art. The reporter construct required for the screening can be prepared by using the transcriptional regulatory region of a marker gene. When the transcriptional regulatory region of a marker gene has been known to those skilled in the art, a reporter construct can be prepared by using the previous sequence information. When the transcriptional regulatory region of a marker gene remains unidentified, a nucleotide segment containing the transcriptional regulatory region can be isolated from a genome library based on the nucleotide sequence information of the marker gene.

As a method of screening for proteins, for example, that bind to the polypeptides of the present invention using the polypeptide of the present invention, many methods well known by a person skilled in the art can be used. Such a screening can be conducted by, for example, immunoprecipitation method, specifically, in the following manner. The gene encoding the polypeptide of the present invention is expressed in host (e.g., animal) cells and so on by inserting the gene to an expression vector for foreign genes, such as pSV2neo, pcDNA I, pcDNA3.1, pCAGGS and pCD8. The promoter to be used for the expression may be any promoter that can be used commonly and include, for example, the SV40 early promoter (Rigby in Williamson (ed.), Genetic Engineering, vol. 3. Academic Press, London, 83-141 (1982)), the EF α promoter (Kim et al., Gene 91: 217-23 (1990)), the CAG promoter (Niwa et al., Gene 108: 193-200 (1991)), the RSV LTR promoter (Cullen, Methods in Enzymology 152: 684-704 (1987)) the SRα promoter (Takebe et al., Mol Cell Biol 8: 466 (1988)), the CMV immediate early promoter (Seed and Aruffo, Proc Natl Acad Sci USA 84: 3365-9 (1987)), the SV40 late promoter (Gheysen and Fiers, J Mol Appl Genet 1: 385-94 (1982)), the Adenovirus late promoter (Kaufman et al., Mol Cell Biol 9: 946 (1989)), the HSV TK promoter and so on. The introduction of the gene into host cells to express a foreign gene can be performed according to any methods, for example, the electroporation method (Chu et al., Nucleic Acids Res 15: 1311-26 (1987)), the calcium phosphate method (Chen and Okayama, Mol Cell Biol 7: 2745-52 (1987)), the DEAE dextran method (Lopata et al., Nucleic Acids Res 12: 5707-17 (1984); Sussman and Milman, Mol Cell Biol 4: 1642-3 (1985)), the Lipofectin method (Derijard, B Cell 7: 1025-37 (1994); Lamb et al., Nature Genetics 5: 22-30 (1993): Rabindran et al., Science 259: 230-4 (1993)) and so on. The polypeptide of the present invention can be expressed as a fusion protein comprising a recognition site (epitope) of a monoclonal antibody by introducing the epitope of the monoclonal antibody, whose specificity has been revealed, to the N- or C-terminus of the polypeptide of the present invention. A commercially available epitope-antibody system can be used (Experimental Medicine 13: 85-90 (1995)). Vectors which can express a fusion protein with, for example, β-galactosidase, maltose binding protein, glutathione S-transferase, green florescence protein (GFP) and so on by the use of its multiple cloning sites are commercially available.

A fusion protein prepared by introducing only small epitopes consisting of several to a dozen amino acids so as not to change the property of the polypeptide of the present invention by the fusion is also reported. Epitopes, such as polyhistidine (His-tag), influenza aggregate HA, human c-myc, FLAG, Vesicular stomatitis virus glycoprotein (VSV-GP), T7 gene 10 protein (T7-tag), human simple herpes virus glycoprotein (HSV-tag), E-tag (an epitope on monoclonal phage) and such, and monoclonal antibodies recognizing them can be used as the epitope-antibody system for screening proteins binding to the polypeptide of the present invention (Experimental Medicine 13: 85-90 (1995)).

In immunoprecipitation, an immune complex is formed by adding these antibodies to cell lysate prepared using an appropriate detergent. The immune complex consists of the polypeptide of the present invention, a polypeptide comprising the binding ability with the polypeptide, and an antibody. Immunoprecipitation can be also conducted using antibodies against the polypeptide of the present invention, besides using antibodies against the above epitopes, which antibodies can be prepared as described above.

An immune complex can be precipitated, for example by Protein A sepharose or Protein G sepharose when the antibody is a mouse IgG antibody. If the polypeptide of the present invention is prepared as a fusion protein with an epitope, such as GST, an immune complex can be formed in the same manner as in the use of the antibody against the polypeptide of the present invention, using a substance specifically binding to these epitopes, such as glutathione-Sepharose 4B.

Immunoprecipitation can be performed by following or according to, for example, the methods in the literature (Harlow and Lane, Antibodies, 511-52, Cold Spring Harbor Laboratory publications, New York (1988)).

SDS-PAGE is commonly used for analysis of immunoprecipitated proteins and the bound protein can be analyzed by the molecular weight of the protein using gels with an appropriate concentration. Since the protein bound to the polypeptide of the present invention is difficult to detect by a common staining method, such as Coomassie staining or silver staining, the detection sensitivity for the protein can be improved by culturing cells in culture medium containing radioactive isotope, ³⁵S-methionine or ³⁵S-cystein, labeling proteins in the cells, and detecting the proteins. The target protein can be purified directly from the SDS-polyacrylamide gel and its sequence can be determined, when the molecular weight of a protein has been revealed.

As a method for screening proteins binding to the polypeptide of the present invention using the polypeptide, for example, West-Western blotting analysis (Skolnik et al., Cell 65: 83-90 (1991)) can be used. Specifically, a protein binding to the polypeptide of the present invention can be obtained by preparing a cDNA library from cells, tissues, organs (for example, tissues such as testis or prostate), or cultured cells (e.g., PC3, DU145) expected to express a protein binding to the polypeptide of the present invention using a phage vector (e.g., ZAP), expressing the protein on LB-agarose, fixing the protein expressed on a filter, reacting the purified and labeled polypeptide of the present invention with the above filter, and detecting the plaques expressing proteins bound to the polypeptide of the present invention according to the label. The polypeptide of the invention may be labeled by utilizing the binding between biotin and avidin, or by utilizing an antibody that specifically binds to the polypeptide of the present invention, or a peptide or polypeptide (for example, GST) that is fused to the polypeptide of the present invention. Methods using radioisotope or fluorescence and such may be also used.

Alternatively, in another embodiment of the screening method of the present invention, a two-hybrid system utilizing cells may be used (“MATCHMAKER Two-Hybrid system”, “Mammalian MATCHMAKER Two-Hybrid Assay Kit”, “MATCHMAKER one-Hybrid system” (Clontech); “HybriZAP Two-Hybrid Vector System” (Stratagene); the references “Dalton and Treisman, Cell 68: 597-612 (1992)”, “Fields and Sternglanz, Trends Genet 10: 286-92 (1994)”).

In the two-hybrid system, the polypeptide of the invention is fused to the SRF-binding region or GAL4-binding region and expressed in yeast cells. A cDNA library is prepared from cells expected to express a protein binding to the polypeptide of the invention, such that the library, when expressed, is fused to the VP16 or GAL4 transcriptional activation region. The cDNA library is then introduced into the above yeast cells and the cDNA derived from the library is isolated from the positive clones detected (when a protein binding to the polypeptide of the invention is expressed in yeast cells, the binding of the two activates a reporter gene, making positive clones detectable). A protein encoded by the cDNA can be prepared by introducing the cDNA isolated above to E. coli and expressing the protein.

As a reporter gene, for example, Ade2 gene, lacZ gene, CAT gene, luciferase gene and such can be used in addition to the HIS3 gene.

The compound isolated by the screening is a candidate for drugs that inhibit the activity of the protein encoded by marker genes and can be applied to the treatment or prevention of PRC or PIN.

Moreover, compound in which a part of the structure of the compound inhibiting the activity of proteins encoded by marker genes is converted by addition, deletion and/or replacement are also included in the compounds obtainable by the screening method of the present invention.

When administrating the compound isolated by the method of the invention as a pharmaceutical for humans and other mammals, such as mice, rats, guinea-pigs, rabbits, cats, dogs, sheep, pigs, cattle, monkeys, baboons, and chimpanzees, the isolated compound can be directly administered or can be formulated into a dosage form using known pharmaceutical preparation methods. For example, according to the need, the drugs can be taken orally, as sugar-coated tablets, capsules, elixirs and microcapsules, or non-orally, in the form of injections of sterile solutions or suspensions with water or any other pharmaceutically acceptable liquid. For example, the compounds can be mixed with pharmaceutically acceptable carriers or media, specifically, sterilized water, physiological saline, plant-oils, emulsifiers, suspending agents, surfactants, stabilizers, flavoring agents, excipients, vehicles, preservatives, binders, and such, in a unit dose form required for generally accepted drug implementation. The amount of active ingredients in these preparations makes a suitable dosage within the indicated range acquirable.

Examples of additives that can be mixed to tablets and capsules are, binders such as gelatin, corn starch, tragacanth gum and arabic gum; excipients such as crystalline cellulose; swelling agents such as corn starch, gelatin and alginic acid; lubricants such as magnesium stearate; sweeteners such as sucrose, lactose or saccharin; and flavoring agents such as peppermint, Gaultheria adenothrix oil and cherry. When the unit-dose form is a capsule, a liquid carrier, such as an oil, can also be further included in the above ingredients. Sterile composites for injections can be formulated following normal drug implementations using vehicles such as distilled water used for injections.

Physiological saline, glucose, and other isotonic liquids including adjuvants, such as D-sorbitol, D-mannnose, D-mannitol, and sodium chloride, can be used as aqueous solutions for injections. These can be used in conjunction with suitable solubilizers, such as alcohol, specifically ethanol, polyalcohols such as propylene glycol and polyethylene glycol, non-ionic surfactants, such as Polysorbate 80™ and HCO-50.

Sesame oil or Soy-bean oil can be used as a oleaginous liquid and may be used in conjunction with benzyl benzoate or benzyl alcohol as a solubilizer and may be formulated with a buffer, such as phosphate buffer and sodium acetate buffer; a pain-killer, such as procaine hydrochloride; a stabilizer, such as benzyl alcohol and phenol; and an anti-oxidant. The prepared injection may be filled into a suitable ampule.

Methods well known to one skilled in the art may be used to administer the pharmaceutical composition of the present inevntion to patients, for example as intraarterial, intravenous, or percutaneous injections and also as intranasal, transbronchial, intramuscular or oral administrations. The dosage and method of administration vary according to the body-weight and age of a patient and the administration method; however, one skilled in the art can routinely select a suitable metod of administration. If said compound is encodable by a DNA, the DNA can be inserted into a vector for gene therapy and the vector administered to a patient to perform the therapy. The dosage and method of administration vary according to the body-weight, age, and symptoms of the patient but one skilled in the art can suitably select them.

For example, although the dose of a compound that binds to the protein of the present invention and regulates its activity depends on the symptoms, the dose is about 0.1 mg to about 100 mg per day, preferably about 1.0 mg to about 50 mg per day and more preferably about 1.0 mg to about 20 mg per day, when administered orally to a normal adult (weight 60 kg).

When administering parenterally, in the form of an injection to a normal adult (weight 60 kg), although there are some differences according to the patient, target organ, symptoms and method of administration, it is convenient to intravenously inject a dose of about 0.01 mg to about 30 mg per day, preferably about 0.1 to about 20 mg per day and more preferably about 0.1 to about 10 mg per day. Also, in the case of other animals too, it is possible to administer an amount converted to 60 kgs of body-weight.

Assessing the Prognosis of a Subject with PRC or PIN

Also provided is a method of assessing the prognosis of a subject with PRC or PIN by comparing the expression of one or more PRC-associated genes in a test cell population to the expression of the genes in a reference cell population derived from patients over a spectrum of disease stages. By comparing gene expression of one or more PRC-associated gene in the test cell population and the reference cell population(s), or by comparing the pattern of gene expression over time in test cell populations derived from the subject, the prognosis of the subject can be assessed.

A decrease in expression of one or more of PRC 89-295, PRC 322-457, PRC 538-692 compared to a normal control or an increase of expression of one or more of PRC 1-88, PRC 296-321, PRC 458-537 compared to a normal control indicates less favorable prognosis. An increase in expression of one or more of PRC 89-295, PRC 322-457, PRC 538-692 indicates a more favorable prognosis, and a decrease in expression of PRC 1-88, PRC 296-321, PRC 458-537 indicates a more favorable prognosis for the subject.

Kits

The invention also includes an PRC-detection reagent, e.g., a nucleic acid that specifically binds to or identifies one or more PRC nucleic acids such as oligonucleotide sequences, which are complementary to a portion of an PRC nucleic acid or antibodies which bind to proteins encoded by an PRC nucleic acid. The reagents are packaged together in the form of a kit. The reagents are packaged in separate containers, e.g., a nucleic acid or antibody (either bound to a solid matrix or packaged separately with reagents for binding them to the matrix), a control reagent (positive and/or negative), and/or a detectable label. Instructions (e.g., written, tape, VCR, CD-ROM, etc.) for carrying out the assay are included in the kit. The assay format of the kit is a Northern hybridization or a sandwich ELISA known in the art.

For example, PRC detection reagent, is immobilized on a solid matrix such as a porous strip to form at least one PRC detection site. The measurement or detection region of the porous strip may include a plurality of sites containing a nucleic acid. A test strip may also contain sites for negative and/or positive controls. Alternatively, control sites are located on a separate strip from the test strip. Optionally, the different detection sites may contain different amounts of immobilized nucleic acids, i.e., a higher amount in the first detection site and lesser amounts in subsequent sites. Upon the addition of test sample, the number of sites displaying a detectable signal provides a quantitative indication of the amount of PRC present in the sample. The detection sites may be configured in any suitably detectable shape and are typically in the shape of a bar or dot spanning the width of a teststrip.

Alternatively, the kit contains a nucleic acid substrate array comprising one or more nucleic acid sequences. The nucleic acids on the array specifically identify one or more nucleic acids represented by PRC 1-692. The expression of 2, 3, 4, 5, 6, 7, 8, 9, 10, 15, 20, 25, 40 or 50 or more of the nucleic acids represented by PRC 1-692 are identified by virtue if the level of binding to an array test strip or chip. The substrate array can be on, e.g., a solid substrate, e.g., a “chip” as described in U.S. Pat. No. 5,744,305.

Arrays and Pluralities

The invention also includes a nucleic acid substrate array comprising one or more nucleic acid. The nucleic acids on the array specifically corresponds to one or more nucleic acid sequences represented by PRC 1-692. The expression level of 2, 3, 4, 5, 6, 7, 8, 9, 10, 15, 20, 25, 40 or 50 or more of the nucleic acids represented by PRC 1-692 are identified by detecting nucleic acid binding to the array.

The invention also includes an isolated plurality (i.e., a mixture if two or more nucleic acids) of nucleic acids. The nucleic acids are in a liquid phase or a solid phase, e.g., immobilized on a solid support such as a nitrocellulose membrane. The plurality includes one or more of the nucleic acids represented by PRC 1-692. In various embodiments, the plurality includes 2, 3, 4, 5, 6, 7, 8, 9, 10, 15, 20, 25, 40 or 50 or more of the nucleic acids represented by PRC 1-692.

Methods of Inhibiting PRC or PIN

The invention provides a method for treating or alleviating a symptom of PRC or PIN in a subject by decreasing expression or activity of PRC 1-88, PRC 296-321, PRC 458-537 or increasing expression or activity of PRC 89-295, PRC 322-457, PRC 538-692. Therapeutic compounds are administered prophylactically or therapeutically to subject suffering from at risk of (or susceptible to) developing PRC or PIN. Such subjects are identified using standard clinical methods or by detecting an aberrant level of expression or activity of (e.g., PRC 1-692). Therapeutic agents include inhibitors of cell cycle regulation, cell proliferation, and protein kinase activity.

In the present invention, PRC 1-692 are useful for treating or preventing either or both of PRC and PIN as molecular target. PRC 1-295 are useful for treating or preventing both of PRC and PIN. PRC 296-457 are also useful for treating or preventing PRC as molecular target. Furthermore, PRC 458-692 are useful for treating or preventing PIN and ultimately preventing PRC.

The therapeutic method includes increasing the expression, or function, or both of one or more gene products of genes whose expression is decreased (“under-expressed genes”) in PRC or PIN cell relative to normal cells of the same tissue type from which the PRC or PIN cells are derived. In these methods, the subject is treated with an effective amount of a compound, which increases the amount of one of more of the under-expressed genes in the subject. Administration can be systemic or local. Therapeutic compounds include a polypeptide product of an under-expressed gene, or a biologically active fragment thereof a nucleic acid encoding an under-expressed gene and having expression control elements permitting expression in the PRC or PIN cells; for example an agent which increases the level of expression of such gene endogenous to the PRC or PIN cells (i.e., which up-regulates expression of the under-expressed gene or genes). Administration of such compounds counter the effects of aberrantly-under expressed of the gene or genes in the subject's prostate cells and improves the clinical condition of the subject.

The method also includes decreasing the expression, or function, or both, of one or more gene products of genes whose expression is aberrantly increased (“over-expressed gene”) in. Expression is inhibited in any of several ways known in the art. For example, expression is inhibited by administering to the subject a nucleic acid that inhibits, or antagonizes, the expression of the over-expressed gene or genes, e.g., an antisense oligonucleotide or small interfering RNA which disrupts expression of the over-expressed gene or genes.

Alternatively, function of one or more gene products of the over-expressed genes is inhibited by administering a compound that binds to or otherwise inhibits the function of the gene products. For example, the compound is an antibody which binds to the over-expressed gene product or gene products.

As noted above, antisense nucleic acids corresponding to the nucleotide sequence of PRC 1-88, 296-321, 458-537 can be used to reduce the expression level of the PRC 1-88, 296-321, 458-537. Antisense nucleic acids corresponding to PRC 1-88, 296-321, 458-537 that are up-regulated in either or both of PRC and PIN are useful for the treatment of either or both of PRC and PIN. Specifically, the antisense nucleic acids of the present invention may act by binding to the PRC 1-88, 296-321, 458-537 or mRNAs corresponding thereto, thereby inhibiting the transcription or translation of the genes, promoting the degradation of the mRNAs, and/or inhibiting the expression of proteins encoded by a nucleic acid selected from the group consisting of the PRC 1-88, 296-321, 458-537, finally inhibiting the function of the proteins. The term “antisense nucleic acids” as used herein encompasses both nucleotides that are entirely complementary to the target sequence and those having a mismatch of one or more nucleotides, so long as the antisense nucleic acids can specifically hybridize to the target sequences. For example, the antisense nucleic acids of the present invention include polynucleotides that have a homology of at least 70% or higher, preferably at 80% or higher, more preferably 90% or higher, even more preferably 95% or higher over a span of at least 15 continuous nucleotides. Algorithms known in the art can be used to determine the homology.

For example, the present invention includes antisense oligonucleotides that hybridize with any site within the nucleotide sequence of SEQ ID NO: 1 or 3. This antisense oligonucleotide is preferably against at least about 15 continuous nucleotides of the nucleotide sequence of SEQ ID NO: 1 or 3. The above-mentioned antisense oligonucleotide, which contains an initiation codon in the above-mentioned at least 15 continuous nucleotides, is even more preferred.

Derivatives or modified products of antisense oligonucleotides can also be used as antisense oligonucleotides. Examples of such modified products include lower alkyl phosphonate modifications such as methyl-phosphonate-type or ethyl-phosphonate-type, phosphorothioate modifications and phosphoroamidate modifications.

The term “antisense oligonucleotides” as used herein means, not only those in which the nucleotides corresponding to those constituting a specified region of a DNA or mRNA are entirely complementary, but also those having a mismatch of one or more nucleotides, as long as the DNA or mRNA and the antisense oligonucleotide can specifically hybridize with the nucleotide sequence of PRC 1-88, 296-321, 458-537, in particular, for CCDC4 as shown in SEQ ID NO: 1 or 3.

Such polynucleotides are contained as those having, in the “at least about 15 continuous nucleotide sequence region”, a homology of at least 70% or higher, preferably at 80% or higher, more preferably about 90% or higher, even more preferably about 95% or higher. The algorithm stated herein can be used to determine the homology. Algorithms known in the art can be used to determine the homology. Furthermore, derivatives or modified products of the antisense-oligonucleotides can also be used as antisense-oligonucleotides in the present invention. Examples of such modified products include lower alkyl phosphonate modifications such as methyl-phosphonate-type or ethyl-phosphonate-type, phosphorothioate modifications and phosphoroamidate modifications.

Such antisense polynucleotides are useful as probes for the isolation or detection of DNA encoding the polypeptide of the invention or as a primer used for amplifications.

The antisense oligonucleotide derivatives of the present invention act upon cells producing the polypeptide of the invention by binding to the DNA or mRNA encoding the polypeptide, inhibiting its transcription or translation, promoting the degradation of the mRNA and inhibiting the expression of the polypeptide of the invention, thereby resulting in the inhibition of the polypeptide's function.

The present invention also includes small interfering RNAs (siRNA) comprising a combination of a sense strand nucleic acid and an antisense strand nucleic acid of the nucleotide sequence of PRC 1-88, 296-321, 458-537. In some embodiments, CCDC4, as shown in SEQ ID NO: 1 or 3 is targeted. In some embodiments, such siRNA for suppressing the expression of CCDC4 include those that target the nucleotide sequence of SEQ ID NO: 8.

The term “siRNA” refers to a double stranded RNA molecule which prevents translation of a target mRNA. Standard techniques are used for introducing siRNA into cells, including those wherein DNA is used as the template to transcribe RNA. The siRNA comprises a sense nucleic acid sequence and an antisense nucleic acid sequence of the polynucleotide encoding the protein of interest, for example, human CCDC4 protein (SEQ ID NO: 1 or 3). The siRNA is constructed such that a single transcript (double stranded RNA) has both the sense and complementary antisense sequences from the target gene, e.g., a hairpin.

Binding of the siRNA to a transcript of interest in the target cell results in a reduction in the protein production by the cell. The length of the oligonucleotide is at least 10 nucleotides and may be as long as the naturally-occurring the transcript. Preferably, the oligonucleotide is about 19 to about 25 nucleotides in length. Most preferably, the oligonucleotide is less than about 75, about 50, about 25 nucleotides in length. Examples of CCDC4 siRNA oligonucleotide which inhibit the growth of the cancer cell include the target sequence containing SEQ ID NO: 8. Furthermore, in order to enhance the inhibition activity of the siRNA, nucleotide “u” can be added to 3′end of the antisense strand of the target sequence. The number of “u”s to be added is at least about 2, generally about 2 to about 10, preferably about 2 to about 5. The added “u”s form single strand at the 3′end of the antisense strand of the siRNA.

A siRNA of the invention is directly introduced into the cells in a form that is capable of binding to the mRNA transcripts. In these embodiments, the siRNA molecules of the invention are typically modified as described above for antisense molecules. Other modifications are also possible, for example, cholesterol-conjugated siRNAs have shown improved pharmacological properties (Song et al. Nature Med. 9:347-351 (2003)). Alternatively, the DNA encoding the siRNA of interest is in a vector.

Vectors are produced for example by cloning a target sequence into an expression vector operatively-linked regulatory sequences flanking the desired sequence in a manner that allows for expression (by transcription of the DNA molecule) of both strands (Lee et al., Nature Biotechnology 20:500-505 (2002)). An RNA molecule that is antisense to the target mRNA is transcribed by a first promoter (e.g., a promoter sequence 3′ of the cloned DNA) and an RNA molecule that is the sense strand for the target mRNA is transcribed by a second promoter (e.g., a promoter sequence 5′ of the cloned DNA). The sense and antisense strands hybridize in vivo to generate siRNA constructs for silencing of the target gene. Alternatively, two constructs are utilized to create the sense and antisense strands of a siRNA construct. Cloned sequences of interest can encode a construct having secondary structure, e.g., hairpins, wherein a single transcript has both the sense and complementary antisense sequences from the target gene.

Furthermore, a loop sequence consisting of an arbitrary nucleotide sequence can be located between the sense and antisense sequence in order to form the hairpin loop structure. Thus, the present invention also provides siRNA having the general formula 5′-[A]-[B]-[A′]-3′, wherein [A] is a ribonucleotide sequence corresponding to a sequence that specifically hybridizes to an mRNA or a cDNA from a target gene, for example the CCDC4 gene. In those embodiments in which the CCDC4 gene is targeted, [A] is a ribonucleotide sequence corresponding a sequence of nucleotides 1666-1684 (SEQ ID NO: 8) of SEQ ID NO: 1 or 3. [B] is a ribonucleotide loop sequence consisting of about 3 to about 23 nucleotides, and [A′] is a ribonucleotide sequence consisting of the complementary sequence of [A].

The loop sequence may consist of arbitrary sequence having preferably 3 to 23 nucleotide in length. The loop sequence, for example, can be selected from group consisting of following sequences (http://www.ambion.com/techlib/tb/tb_{—}506.html). In the siRNA of the present invention, nucleotide “u” can be added to the 3′end of [A′], in order to enhance the inhibiting activity of the siRNA. The number of “u”s to be added is at least about 2, generally about 2 to about 10, preferably about 2 to about 5. Furthermore, a loop sequence consisting of 23 nucleotides also provides active siRNA (Jacque et al., Nature 418 : 435-438 (2002)). Other loop sequences useful in the invention include:

CCC, CCACC or CCACACC (Jacque et al., Nature, Vol. 418: 435-438 (2002)); UUCG (Lee et al., Nature Biotechnology 20:500-505 (2002); Fruscoloni et al., Proc. Natl. Acad. Sci. USA 100(4): 1639-1644 (2003)); and UUCAAGAGA (Dykxhoom et al., Cell Biology 4: 457-467 (2002)).

For example, preferable siRNAs having hairpin structure of the present invention are shown below. In the following structure, the loop sequence can be selected from group consisting of CCC, UUCG, CCACC, CCACACC, and UUCAAGAGA. A preferable loop sequence is UUCAAGAGA (“ttcaagaga” in DNA).
gaugguucugcagcaccac-[B]-guggugcugcagaaccauc (for target sequence of SEQ ID NO: 8)

The regulatory sequences flanking the target sequence are identical or are different, such that their expression can be modulated independently, or in a temporal or spatial manner. siRNAs are transcribed intracellularly by cloning the desired gene templates into a vector containing, e.g., a RNA polymerase III transcription unit from the small nuclear RNA (snRNA) U6 or the human HI RNA promoter. For introducing the vector into the cell, transfection-enhancing agent can be used. FuGENE (Rochediagnostices), Lipofectamine 2000 (Invitrogen), Oligofectamine (Invitrogen), and Nucleofector (Wako pure Chemical) are useful as the transfection-enhancing agent.

The nucleotide sequence of siRNAs may be designed using an siRNA design computer program available from the Ambion website (http://www.ambion.com/techlib/misc/siRNA_finder.html). Nucleotide sequences for the siRNA are selected by the computer program based on the following protocol:

Selection of siRNA Target Sites:

1. Beginning with the AUG start codon of the object transcript, scan downstream for AA dinucleotide sequences. Record the occurrence of each AA and the 3′ adjacent 19 nucleotides as potential siRNA target sites. Tuschl et al., Targeted mRNA degradation by double-stranded RNA in vitro, Genes Dev 13(24): 3191-7 (1999), don't recommend against designing siRNA to the 5′ and 3′ untranslated regions (UTRs) and regions near the start codon (within 75 bases) as these may be richer in regulatory protein binding sites. UTR-binding proteins and/or translation initiation complexes may interfere with the binding of the siRNA endonuclease complex.

2. Compare the potential target sites to the human genome database and eliminate from consideration any target sequences with significant homology to other coding sequences. The homology search can be performed using BLAST, which can be found on the NCBI server at: www.ncbi.nlm.nih.gov/BLAST/.

3. Select qualifying target sequences for synthesis. At Ambion, preferably several target sequences can be selected along the length of the gene for evaluation.

Oligonucleotides and oligonucleotides complementary to various portions of CCDC4 mRNA were tested in vitro for their ability to decrease production of CCDC4 in tumor cells (e.g., using the PC3, or DU145 prostate cancer cell line) according to standard methods. A reduction in CCDC4 gene product in cells contacted with the candidate siRNA composition compared to cells cultured in the absence of the candidate composition is detected using CCDC4-specific antibodies or other detection strategies. Sequences which decrease production of CCDC4 in in vitro cell-based or cell-free assays are then tested for there inhibitory effects on cell growth. Sequences which inhibit cell growth in in vitro cell-based assay are test in in vivo in rats or mice to confirm decreased CCDC4 production and decreased tumor cell growth in animals with malignant neoplasms.

Also included in the invention are double-stranded molecules that include the nucleic acid sequence of target sequences, for example, nucleotides 1666-1684 (SEQ ID NO: 8) of SEQ ID NO: 1 or 3. In the present invention, the double-stranded molecule comprising a sense strand and an antisense strand, wherein the sense strand comprises a ribonucleotide sequence corresponding to SEQ ID NO: 8, and wherein the antisense strand comprises a ribonucleotide sequence which is complementary to said sense strand, wherein said sense strand and said antisense strand hybridize to each other to form said double-stranded molecule, and wherein said double-stranded molecule, when introduced into a cell expressing the CCDC4 gene, inhibits expression of said gene. In the present invention, when the isolated nucleic acid is RNA or derivatives thereof, base “t” should be replaced with “u” in the nucleotide sequences. As used herein, the term “complementary” refers to Watson Crick or Hoogsteen base pairing between nucleotides units of a nucleic acid molecule, and the term “binding” means the physical or chemical interaction between two nucleic acids or compounds or associated nucleic acids or compounds or combinations thereof.

Complementary nucleic acid sequences hybridize under appropriate conditions to form stable duplexes containing few or no mismatches. Furthermore, the sense strand and antisense strand of the isolated nucleotide of the present invention, can form double stranded nucleotide or hairpin loop structure by the hybridization. In a preferred embodiment, such duplexes contain no more than 1 mismatch for every 10 matches. In an especially preferred embodiment, where the strands of the duplex are fully complementary, such duplexes contain no mismatches. In the case of CCDC4, the target nucleic acid molecule is less than 8763 nucleotides (for SEQ ID NO: 1) or 8692 nucleotides (for SEQ ID NO: 3) in length. For example, the nucleic acid molecule is less than 500, 200, or 75 nucleotides in length. Also included in the invention is a vector containing one or more of the nucleic acids described herein, and a cell containing the vectors. The isolated nucleic acids of the present invention are useful for siRNA against any of PRC 1-88, 296-321, 458-537 or DNA encoding the siRNA. When the nucleic acids are used for siRNA or coding DNA thereof, the sense strand is preferably longer than about 19 nucleotides, and more preferably longer than about 21 nucleotides.

The antisense oligonucleotide or siRNA of the invention inhibit the expression of the polypeptide of the invention and is thereby useful for suppressing the biological activity of the polypeptide of the invention. Also, expression-inhibitors, comprising the antisense oligonucleotide or siRNA of the invention, are useful in the point that they can inhibit the biological activity of the polypeptide of the invention. Therefore, a composition comprising antisense oligonucleotide or siRNA of the present invention are useful in treating a prostate cancer. Examples of siRNA oligonucleotides which inhibit the expression in mammalian cells include the target sequence containing SEQ ID NO: 8. Furthermore, in order to enhance the inhibition activity of the siRNA, nucleotide “u” can be added to 3′end of the antisense strand of the target sequence. The number of “u”s to be added is at least about 2, generally about 2 to about 10, preferably about 2 to about 5. The added “u”s form single strand at the 3′end of the antisense strand of the siRNA.

Also, expression-inhibitors, comprising the antisense oligonucleotide or siRNA of the invention, are useful in the point that they can inhibit the biological activity of the polypeptide of the invention. Therefore, a composition comprising the antisense oligonucleotide or siRNA of the present invention is useful in treating a cell proliferative disease such as prostate cancer.

Furthermore, the present invention provides ribozymes that inhibit the expression of a target polypeptide of the present invention.

Generally, ribozymes are classified into large ribozymes and small ribozymes. A large ribozyme is known as an enzyme that cleaves the phosphate ester bond of nucleic acids. After the reaction with the large ribozyme, the reacted site consists of a 5′-phosphate and 3′-hydroxyl group. The large ribozyme is further classified into (1) group I intron RNA catalyzing transesterification at the 5′-splice site by guanosine; (2) group II intron RNA catalyzing self-splicing through a two step reaction via lariat structure; and (3) RNA component of the ribonuclease P that cleaves the tRNA precursor at the 5′ site through hydrolysis. On the other hand, small ribozymes have a smaller size (about 40 bp) compared to the large ribozymes and cleave RNAs to generate a 5′-hydroxyl group and a 2′-3′ cyclic phosphate. Hammerhead type ribozymes (Koizumi et al., FEBS Lett. 228:225 (1988)) and hairpin type ribozymes (Buzayan, Nature 323: 349 (1986); Kikuchi and Sasaki, Nucleic Acids Res 19: 6751 (1992)) are included in the small ribozymes. Methods for designing and constructing ribozymes are known in the art (see Koizumi et al., FEBS Lett 228: 225 (1988); Koizumi et al., Nucleic Acids Res 17: 7059 (1989); Kikuchi and Sasaki, Nucleic Acids Res 19: 6751 (1992)). Thus, ribozymes inhibiting the expression of the polypeptides of the present invention can also be constructed based on their sequence information (SEQ ID NO: 1 or 3) and these conventional methods.

Ribozymes against the over expressed genes noted above (e.g., PRC 1-88, 296-321, 458-537 and in particular the CCDC4 gene) inhibit the expression of over-expressed protein and is thus useful for suppressing the biological activity of the protein. Therefore, the ribozymes are useful in treating or preventing prostate cancer.

Alternatively, function of one or more gene products of the over-expressed genes is inhibited by administering a compound that binds to or otherwise inhibits the function of the gene products. For example, the compound is an antibody which binds to the over-expressed gene product or gene products.

Cancer therapies directed at specific molecular alterations that occur in cancer cells have been validated through clinical development and regulatory approval of anti-cancer drugs such as trastuzumab (Herceptin) for the treatment of advanced breast cancer, imatinib methylate (Gleevec) for chronic myeloid leukemia, gefitinib (Iressa) for non-small cell lung cancer (NSCLC), and rituximab (anti-CD20 mAb) for B-cell lymphoma and mantle cell lymphoma (Ciardiello F, Tortora G., Clin Cancer Res.; 7(10):2958-70 (2001). Review; Slamon et al., N Engl J Med., 344(11):783-92 (2001); Rehwald et al., Blood. 2003 Jan. 15; 101(2):420-424.; Fang et al., Blood, 96, 2246-2253 (2000)). These drugs are clinically effective and better tolerated than traditional anti-cancer agents because they target only transformed cells. Hence, such drugs not only improve survival and quality of life for cancer patients, but also validate the concept of molecularly targeted cancer therapy. Furthermore, targeted drugs can enhance the efficacy of standard chemotherapy when used in combination with it (Gianni, L., Oncology, 63 Suppl 1, 47-56 (2002); Klejman, A., Oncogene, 21, 5868-5876 (2002)). Therefore, future cancer treatments will probably involve combining conventional drugs with target-specific agents aimed at different characteristics of tumor cells such as angiogenesis and invasiveness.

These modulatory methods are performed ex vivo or in vitro (e.g., by culturing the cell with the agent) or, alternatively, in vivo (e.g., by administering the agent to a subject). The method involves administering a protein or combination of proteins or a nucleic acid molecule or combination of nucleic acid, molecules as therapy to counteract aberrant expression or activity of the differentially expressed genes.

Diseases and disorders that are characterized by increased (relative to a subject not suffering from the disease or disorder) levels or biological activity of the genes may be treated with therapeutics that antagonize (i.e., reduce or inhibit) activity of the over-expressed gene or genes. Therapeutics that antagonize activity are administered therapeutically or prophylactically.

Therapeutics that may be utilized include, e.g., (i) a polypeptide, or analogs, derivatives, fragments or homologs thereof of the under-expressed gene or genes; (ii) antibodies to the over-expressed gene or genes; (iii) nucleic acids encoding the under-expressed gene or genes; (iv) antisense nucleic acids or nucleic acids that are “dysfunctional” (i.e., due to a heterologous insertion within the coding sequences of one or more over-expressed genes); (v) small interfering RNA (siRNA); or (vi) modulators (i.e., inhibitors, agonists and antagonists that alter the interaction between an over/under-expressed polypeptide and its binding partner. The dysfunctional antisense molecules are utilized to “knockout” endogenous function of a polypeptide by homologous recombination (see, e.g., Capecchi, Science 244: 1288-1292 (1989))

Diseases and disorders that are characterized by decreased (relative to a subject not suffering from the disease or disorder) levels or biological activity may be treated with therapeutics that increase (i.e., are agonists to) activity. Therapeutics that up-regulate activity may be administered in a therapeutic or prophylactic manner. Therapeutics that may be utilized include, but are not limited to, a polypeptide (or analogs, derivatives, fragments or homologs thereof) or an agonist that increases bioavailability.

Increased or decreased levels can be readily detected by quantifying peptide and/or RNA, by obtaining a patient tissue sample (e.g., from biopsy tissue) and assaying it in vitro for RNA or peptide levels, structure and/or activity of the expressed peptides (or mRNAs of a gene whose expression is altered). Methods that are well-known within the art include, but are not limited to, immunoassays (e.g., by Western blot analysis, immunoprecipitation followed by sodium dodecyl sulfate (SDS) polyacrylamide gel electrophoresis, immunocytochemistry, etc.) and/or hybridization assays to detect expression of mRNAs (e.g., Northern assays, dot blots, in situ hybridization, etc.).

Prophylactic administration occurs prior to the manifestation of overt clinical symptoms of disease, such that a disease or disorder is prevented or, alternatively, delayed in its progression.

Therapeutic methods include contacting a cell with an agent that modulates one or more of the activities of the gene products of the differentially expressed genes. An agent that modulates protein activity includes a nucleic acid or a protein, a naturally-occurring cognate ligand of these proteins, a peptide, a peptidomimetic, or other small molecule. For example, the agent stimulates one or more protein activities of one or more of a differentially under-expressed gene.

The present invention also relates to a method of treating or preventing either or both of PRC and PIN in a subject comprising administering to said subject a vaccine comprising a polypeptide encoded by a nucleic acid selected from the group consisting of PRC 1-88, 296-321, 458-537 or an immunologically active fragment of said polypeptide, or a polynucleotide encoding the polypeptide or the fragment thereof. An administration of the polypeptide induces an anti-tumor immunity in a subject. To inducing anti-tumor immunity, a polypeptide encoded by a nucleic acid selected from the group consisting of PRC 1-88, 296-321, 458-537 or an immunologically active fragment of said polypeptide, or a polynucleotide encoding the polypeptide is administered. The polypeptide or the immunologically active fragments thereof are useful as vaccines against either or both of PRC and PIN. In some cases the proteins or fragments thereof may be administered in a form bound to the T cell recepor (TCR) or presented by an antigen presenting cell (APC), such as macrophage, dendritic cell (DC), or B-cells. Due to the strong antigen presenting ability of DC, the use of DC is most preferable among the APCs.

In the present invention, vaccine against either or both of PRC and PIN refers to a substance that has the function to induce anti-tumor immunity upon inoculation into animals. According to the present invention, polypeptides encoded by a nucleic acid selected from the group consisting of PRC 1-88, 296-321, 458-537 or fragments thereof were suggested to be HLA-A24 or HLA-A*0201 restricted epitopes peptides that may induce potent and specific immune response against either or both of PRC and PIN cells expressing PRC 1-88, 296-321, 458-537. Thus, the present invention also encompasses method of inducing anti-tumor immunity using the polypeptides. In general, anti-tumor immunity includes immune responses such as follows:
induction of cytotoxic lymphocytes against tumors,
induction of antibodies that recognize tumors, and
induction of anti-tumor cytokine production.

Therefore, when a certain protein induces any one of these immune responses upon inoculation into an animal, the protein is decided to have anti-tumor immunity inducing effect. The induction of the anti-tumor immunity by a protein can be detected by observing in vivo or in vitro the response of the immune system in the host against the protein.

For example, a method for detecting the induction of cytotoxic T lymphocytes is well known. A foreign substance that enters the living body is presented to T cells and B cells by the action of antigen presenting cells (APCs). T cells that respond to the antigen presented by APC in antigen specific manner differentiate into cytotoxic T cells (or cytotoxic T lymphocytes; CTLs) due to stimulation by the antigen, and then proliferate (this is referred to as activation of T cells). Therefore, CTL induction by a certain peptide can be evaluated by presenting the peptide to T cell by APC, and detecting the induction of CTL. Furthermore, APC has the effect of activating CD4+ T cells, CD8+ T cells, macrophages, eosinophils, and NK cells. Since CD4+ T cells and CD8+ T cells are also important in anti-tumor immunity, the anti-tumor immunity inducing action of the peptide can be evaluated using the activation effect of these cells as indicators.

A method for evaluating the inducing action of CTL using dendritic cells (DCs) as APC is well known in the art. DC is a representative APC having the strongest CTL inducing action among APCs. In this method, the test polypeptide is initially contacted with DC, and then this DC is contacted with T cells. Detection of T cells having cytotoxic effects against the cells of interest after the contact with DC shows that the test polypeptide has an activity of inducing the cytotoxic T cells. Activity of CTL against tumors can be detected, for example, using the lysis of ⁵¹Cr-labeled tumor cells as the indicator. Alternatively, the method of evaluating the degree of tumor cell damage using ³H-thymidine uptake activity or LDH (lactose dehydrogenase)-release as the indicator is also well known.

Apart from DC, peripheral blood mononuclear cells (PBMCs) may also be used as the APC. The induction of CTL is reported that it can be enhanced by culturing PBMC in the presence of GM-CSF and IL-4. Similarly, CTL has been shown to be induced by culturing PBMC in the presence of keyhole limpet hemocyanin (KLH) and IL-7.

The test polypeptides confirmed to possess CTL inducing activity by these methods are polypeptides having DC activation effect and subsequent CTL inducing activity. Therefore, polypeptides that induce CTL against tumor cells are useful as vaccines against tumors. Furthermore, APC that acquired the ability to induce CTL against tumors by contacting with the polypeptides are useful as vaccines against tumors. Furthermore, CTL that acquired cytotoxicity due to presentation of the polypeptide antigens by APC can be also used as vaccines against tumors. Such therapeutic methods for tumors using anti-tumor immunity due to APC and CTL are referred to as cellular immunotherapy.

Generally, when using a polypeptide for cellular immunotherapy, efficiency of the CTL-induction is known to increase by combining a plurality of polypeptides having different structures and contacting them with DC. Therefore, when stimulating DC with protein fragments, it is advantageous to use a mixture of multiple types of fragments.

Alternatively, the induction of anti-tumor immunity by a polypeptide can be confirmed by observing the induction of antibody production against tumors. For example, when antibodies against a polypeptide are induced in a laboratory animal immunized with the polypeptide, and when growth of tumor cells is suppressed by those antibodies, the polypeptide can be determined to have an ability to induce anti-tumor immunity.

Anti-tumor immunity is induced by administering the vaccine of this invention, and the induction of anti-tumor immunity enables treatment and prevention of either or both of PRC and PIN. Therapy against cancer or prevention of the onset of cancer includes any of the steps, such as inhibition of the growth of cancerous cells, involution of cancer, and suppression of occurrence of cancer. Decrease in mortality of individuals having cancer, decrease of tumor markers in the blood, alleviation of detectable symptoms accompanying cancer, and such are also included in the therapy or prevention of cancer. Such therapeutic and preventive effects are preferably statistically significant. For example, in observation, at a significance level of 5% or less, wherein the therapeutic or preventive effect of a vaccine against cell proliferative diseases is compared to a control without vaccine administration. For example, Student's t-test, the Mann-Whitney U-test, or ANOVA may be used for statistical analyses.

The above-mentioned protein having immunological activity or a vector encoding the protein may be combined with an adjuvant. An adjuvant refers to a compound that enhances the immune response against the protein when administered together (or successively) with the protein having immunological activity. Examples of adjuvants include cholera toxin, salmonella toxin, alum, and such, but are not limited thereto. Furthermore, the vaccine of this invention may be combined appropriately with a pharmaceutically acceptable carrier. Examples of such carriers are sterilized water, physiological saline, phosphate buffer, culture fluid, and such. Furthermore, the vaccine may contain as necessary, stabilizers, suspensions, preservatives, surfactants, and such. The vaccine is administered systemically or locally. Vaccine administration may be performed by single administration, or boosted by multiple administrations.

When using APC or CTL as the vaccine of this invention, tumors can be treated or prevented, for example, by the ex vivo method. More specifically, PBMCs of the subject receiving treatment or prevention are collected, the cells are contacted with the polypeptide ex vivo, and following the induction of APC or CTL, the cells may be administered to the subject. APC can be also induced by introducing a vector encoding the polypeptide into PBMCs ex vivo. APC or CTL induced in vitro can be cloned prior to administration. By cloning and growing cells having high activity of damaging target cells, cellular immunotherapy can be performed more effectively. Furthermore, APC and CTL isolated in this manner may be used for cellular immunotherapy not only against individuals from whom the cells are derived, but also against similar types of tumors from other individuals.

Furthermore, a pharmaceutical composition for treating or preventing a cell proliferative disease, such as cancer, comprising a pharmaceutically effective amount of the polypeptide of the present invention is provided. The pharmaceutical composition may be used for raising anti tumor immunity.

Pharmaceutical Compositions for Inhibiting PRC or PIN

Pharmaceutical formulations include those suitable for oral, rectal, nasal, topical (including buccal and sub-lingual), vaginal or parenteral (including intramuscular, sub-cutaneous and intravenous) administration, or for administration by inhalation or insufflation. Preferably, administration is intravenous. The formulations are optionally packaged in discrete dosage units

Pharmaceutical formulations suitable for oral administration include capsules, cachets or tablets, each containing a predetermined amount of the active ingredient. Formulations also include powders, granules or solutions, suspensions or emulsions. The active ingredient os optionally administered as a bolus electuary or paste. Tablets and capsules for oral administration may contain conventional excipients such as binding agents, fillers, lubricants, disintegrant or wetting agents. A tablet may be made by compression or molding, optionally with one or more formulational ingredients. Compressed tablets may be prepared by compressing in a suitable machine the active ingredients in a free-flowing form such as a powder or granules, optionally mixed with a binder, lubricant, inert diluent, lubricating, surface active or dispersing agent. Molded tablets may be made by molding in a suitable machine a mixture of the powdered compound moistened with an inert liquid diluent. The tablets may be coated according to methods well known in the art. Oral fluid preparations may be in the form of, for example, aqueous or oily suspensions, solutions, emulsions, syrups or elixirs, or may be presented as a dry product for constitution with water or other suitable vehicle before use. Such liquid preparations may contain conventional additives such as suspending agents, emulsifying agents, non-aqueous vehicles (which may include edible oils), or preservatives. The tablets may optionally be formulated so as to provide slow or controlled release of the active ingredient therein. A package of tablets may contain one tablet to be taken on each day of the month.

Formulations for parenteral administration include aqueous and non-aqueous sterile injection solutions which may contain anti-oxidants, buffers, bacteriostats and solutes which render the formulation isotonic with the blood of the intended recipient; and aqueous and non-aqueous sterile suspensions which may include suspending agents and thickening agents. The formulations may be presented in unit dose or multi-dose containers, for example sealed ampoules and vials, and may be stored in a freeze-dried (lyophilized) condition requiring only the addition of the sterile liquid carrier, for example, saline, water-for-injection, immediately prior to use. Alternatively, the formulations may be presented for continuous infusion. Extemporaneous injection solutions and suspensions may be prepared from sterile powders, granules and tablets of the kind previously described.

Formulations for rectal administration include suppositories with standard carriers such as cocoa butter or polyethylene glycol. Formulations for topical administration in the mouth, for example buccally or sublingually, include lozenges, which contain the active ingredient in a flavored base such as sucrose and acacia or tragacanth, and pastilles comprising the active ingredient in a base such as gelatin and glycerin or sucrose and acacia. For intra-nasal administration the compounds of the invention may be used as a liquid spray or dispersible powder or in the form of drops. Drops may be formulated with an aqueous or non-aqueous base also comprising one or more dispersing agents, solubilizing agents or suspending agents.

For administration by inhalation the compounds are conveniently delivered from an insufflator, nebulizer, pressurized packs or other convenient means of delivering an aerosol spray. Pressurized packs may comprise a suitable propellant such as dichlorodifluoromethane, trichlorofluoromethane, dichlorotetrafluoroethane, carbon dioxide or other suitable gas. In the case of a pressurized aerosol, the dosage unit may be determined by providing a valve to deliver a metered amount.

Alternatively, for administration by inhalation or insufflation, the compounds may take the form of a dry powder composition, for example a powder mix of the compound and a suitable powder base such as lactose or starch. The powder composition may be presented in unit dosage form, in for example, capsules, cartridges, gelatin or blister packs from which the powder may be administered with the aid of an inhalator or insufflators.

Other formulations include implantable devices and adhesive patches; which release a therapeutic agent.

When desired, the above described formulations, adapted to give sustained release of the active ingredient, may be employed. The pharmaceutical compositions may also contain other active ingredients such as antimicrobial agents, immunosuppressants or preservatives.

It should be understood that in addition to the ingredients particularly mentioned above, the formulations of this invention may include other agents conventional in the art having regard to the type of formulation in question, for example, those suitable for oral administration may include flavoring agents.

Preferred unit dosage formulations are those containing an effective dose, as recited below, or an appropriate fraction thereof, of the active ingredient.

For each of the aforementioned conditions, the compositions, e.g., polypeptides and organic compounds are administered orally or via injection at a dose of from about 0.1 to about 250 mg/kg per day. The dose range for adult humans is generally from about 5 mg to about 17.5 g/day, preferably about 5 mg to about 10 g/day, and most preferably about 100 mg to about 3 g/day. Tablets or other unit dosage forms of presentation provided in discrete units may conveniently contain an amount which is effective at such dosage or as a multiple of the same, for instance, units containing about 5 mg to about 500 mg, usually from about 100 mg to about 500 mg.

The dose employed will depend upon a number of factors, including the age and sex of the subject, the precise disorder being treated, and its severity. Also the route of administration may vary depending upon the condition and its severity.

The invention will be further described in the following examples, which do not limit the scope of the invention described in the claims. The following examples illustrate the identification and characterization of genes differentially expressed in PRC or PIN cells.

### EXAMPLES

The following examples are offered to illustrate, but not to limit the claimed invention.

### Example 1

### Preparation of Test Samples

Tissue obtained from diseased tissues (e.g., epithelial cells from PRCs) and normal tissues were evaluated to identify genes which are differently expressed or a disease state, e.g., PRC. The assays were carried out as follows.

Patients Tissue Samples and Laser-Capture Microdissection (LCM)

PRC samples including non-cancerous prostate tissues were obtained from 26 patients who underwent radical prostatectomy without preoperative treatment. Prostate adenocarcinomas or high-grade PINs were histopathologically diagnosed by a single pathologist (M.F.). Among 26 PRC tissues, 20 cancers and 10 high-grade PINs cells that have sufficient amount and quality of RNA to analyze were used for microarray study. Clinical and pathological information on the tumor is detailed in Table 1. Samples were embedded in TissueTek OCT medium (Sakura) and then stored at −80° C. until use. Frozen specimens were serially sectioned in 8-μm slices with a cryostat and stained with hematoxylin and eosin to define the analyzed regions. To avoid cross-contamination of cancer and noncancerous cells, the two populations were prepared by EZ Cut LCM System (SL Microtest GmbH) following the manufacture's protocol with several modifications.

TABLE 1
Clinicopathological features

| | | PSA | Pathological | Microdissected |
|---|---|---|---|---|
| Case | Age | (ng/ml) | Stage | Lesions |
| 1 | 76 | 17.0 | pT2aN0M0 | T^{(a)} |
| 2 | 73 | 14.0 | pT2aN0M0 | T |
| 3 | 73 | 59.2 | pT3aN0M0 | T |
| 4 | 56 | 8.6 | pT2bN0M0 | T |
| 5 | 73 | 1.8 | pT2aN0M0 | PIN |
| 6 | 61 | 8.9 | pT2bN0M0 | T |
| 7 | 71 | 11.4 | pT2bN0M0 | T |
| 8 | 69 | 9.5 | pT2aN0M0 | PIN |
| 9 | 66 | 9.6 | pT3aN0M0 | T |
| 10 | 62 | 6.7 | pT2aN0M0 | PIN |
| 11 | 56 | 35.0 | pT3bN0M0 | PIN |
| 12 | 66 | 12.0 | pT2bN0M0 | T |
| 13 | 65 | 4.1 | pT2bN0M0 | T |
| 14 | 77 | 12.3 | pT2bN0M0 | T, PIN |
| 15 | 69 | 10.4 | pT2bN0M0 | T |
| 16 | 68 | 14.1 | pT3aN0M0 | T, PIN |
| 17 | NA^{(b)} | 10.5 | pT2bN0M0 | T |
| 18 | NA | NA | NA | T |
| 19 | 63 | 4.5 | pT2bN0M0 | T |
| 20 | 67 | 9.8 | pT3aN0M0 | T |
| 21 | 63 | 12.4 | pT3N0M0 | T |
| 22 | 73 | 13.0 | pT3bN1M0 | T |
| 23 | 75 | 10.0 | pT2aN1M0 | T, PIN |
| 24 | 67 | 3.3 | pT3aN0M0 | T, PIN |
| 25 | 64 | 5.7 | pT2bN0M0 | PIN |
| 26 | 69 | 38.0 | pT3aN0M0 | PIN |

^{(a)}T indicates prostate cancer.
^{(b)}NA: not available

Extraction of RNA and T7-Based RNA Amplification

Total RNA was extracted from each population of laser captured cells into 350 μl RLT lysis buffer (QIAGEN). The extracted RNA was treated for 30 minutes at room temperature with 30 units of DNase I (QIAGEN) in the presence of 1 unit of RNase inhibitor (TOYOBO, Osaka, Japan) to eliminate any contaminating genomic DNA. After inactivation at 70° C. for 10 min, the RNAs were purified with an RNeasy Mini Kit (QIAGEN) according to the manufacturer's recommendations and DNase-treated RNAs were subjected to T7-based RNA amplification. Two rounds of amplification yielded 50-100 μg of amplified RNA (aRNA) for each sample. 2.5 μg aliquots of aRNA from each cancerous cell and noncancerous cell were reverse-transcribed in the presence of Cy5-dCTP and Cy3-dCTP, respectively.

Preparation of the cDNA Microarray

A “genome-wide” cDNA microarray system was prepared containing 23,040 cDNAs selected from the UniGene database (build #131) of the National Center for Biotechnology Information (NCBI). Briefly, the cDNAs were amplified by reverse transcription-PCR using poly(A)+ RNA isolated from various human organs as templates; lengths of the amplicons ranged from 200 to 1100 bp without repetitive or poly(A) sequences. The PCR products were spotted in duplicate on type-7 glass slides (Amersham Bioscience) using an Array Spotter Generation III (Amersham Bioscience). Each slide contained 52 housekeeping genes, to normalize the signal intensities of the different fluorescent dyes.

Hybridization and Acquisition of Data

Hybridization and washing were performed according to protocols described previously except that all processes were carried out with an Automated Slide Processor (Amersham Biosciences) (Ono et al., Cancer Res, 60:5007-5011 (2000)). The intensity of each hybridization signal was calculated photometrically by the ArrayVision computer program (Amersham Biosciences) and background intensity was subtracted. Normalization of each Cy3 and Cy5 signal intensity was performed using averaged signals from the 52 housekeeping genes. A cut-off value for each expression level was automatically calculated according to background fluctuation. When both Cy3 and Cy5 signal intensities were lower than the cut-off values, expression of the corresponding gene in that sample was assessed as absent. The Cy5/Cy3 ratio was calculated as the relative expression ratio. For other genes we calculated the Cy5/Cy3 ratio using raw data of each sample.

### Example 2

### Identification of PRC-Associated Genes

When up- or down-regulated genes common to PRC and PINs were identified, the genes were analyzed by the following criteria. Initially, genes whose relative expression ratio was able to be calculated for more than 50% cases and whose expression were up- or down-regulated in more than 50% of cases were selected. The relative expression ratio of each gene (Cy5/Cy3 intensity ratio) was classified into one of four categories: (1) up-regulated (expression ratio more than 3.0 in more than 50% of the informative; (2) down-regulated (expression ratio less than 0.33 in more than 50% of the informative cases; (3) unchanged expression (expression ratio between 0.33 and 3.0 in more than 50% of the informative cases); and (4) not expressed (or slight expression but under the cut-off level for detection). These categories were defined to detect a set of genes whose changes in expression ratios were common among samples as well as specific to a certain subgroup. To detect candidate genes that were commonly up- or down-regulated in either or both of PRC and PIN cell, the overall expression patterns of 23,040 genes were screened to select genes with expression ratios of more than 3.0 or less than 0.33 that were present in more than 50% of the PRC cases categorized as (1), (2), or (3).

Furthermore when up- or down-regulated genes common to PRC or PINs were identified, the genes were analyzed by the following criteria. Initially, genes whose relative expression ratio was able to be calculated for more than 50% cases and whose expression were up- or down-regulated in more than 50% of cases were selected. The relative expression ratio of each gene (Cy5/Cy3 intensity ratio) was classified into one of four categories: (5) up-regulated (expression ratio more than 5.0 in more than 50% of the informative; (6) down-regulated (expression ratio less than 0.2 in more than 50% of the informative cases; (7) unchanged expression (expression ratio between 0.2 and 5.0 in more than 50% of the informative cases); and (8) not expressed (or slight expression but under the cut-off level for detection). These categories were defined to detect a set of genes whose changes in expression ratios were common among samples as well as specific to a certain subgroup. To detect candidate genes that were commonly up- or down-regulated in either or both of PRC and PIN cell, the overall expression patterns of 23,040 genes were screened to select genes with expression ratios of more than 5.0 or less than 0.2 that were present in more than 50% of the PRC cases categorized as (5), (6), or (7).

Identification of Genes with Clinically Relevant Expression Patterns in PRC Cells

The expression patterns of approximately 23,000 genes were investigated in PRC cells using cDNA microarray. Individual data was excluded when both Cy5 and Cy3 signals were under cut-off values. 88 up-regulated genes were identified whose expression ratio was more than 3.0 in PRC and PINs (see Table 3), whereas 207 down-regulated genes whose expression ratio was less than 0.33 were identified (see Table 4). 26 up-regulated genes were identified whose expression ratio was more than 5.0 in PRC (see Table 5), whereas 136 down-regulated genes whose expression ratio was less than 0.2 were identified (see Table 6).

Among the up-regulated genes, α-methylacyl coenzyme A racemase (AMACR) has been already reported to be overexpressed in PRC (Rubin et al., Jama, 287:1662-1670 (2002)). Furthermore, these up-regulated elements included significant genes involved in metabolism and signal transduction pathway, transcriptional factors, cell cycle, oncogene, and cell adhesion and cytoskeleton. Of them, olfactory receptor, family 51, subfamily E, member 2 (OR51E2) that is prostate specific G-protein coupled receptor (PSGR), and PRC overexpressed gene 1 (POV1) had already been reported as over-expressed in PRCs (Luo et al., Cancer Res, 62, 2220-6 (2002); Cole et al., Genomics, 51, 282-7 (1998); Xu et al., Cancer Res. 60, 6568-72 (2000)) (see Table 5).

80 up-regulated genes were identified whose expression ratio was more than 5.0 in PINs (see Table 7), whereas 155 down-regulated genes whose expression ratio was less than 0.2 were identified (see Table 8).

To confirm the reliability of the expression indicated by microarray analysis, semi-quantitative RT-PCR experiments were performed. Four up-regulated genes were selected and their expression levels measured by semi-quantitative RT-PCR. A 3-μg aliquot of aRNA from each sample was reverse-transcribed for single-stranded cDNAs using random primer (Roche) and Superscript II (Life Technologies, Inc.). Each cDNA mixture was diluted for subsequent PCR amplification with the primer sets that were shown in Table 2. Expression of β-actin (ACTB) served as an internal control. PCR reactions were optimized for the number of cycles to ensure product intensity within the linear phase of amplification.

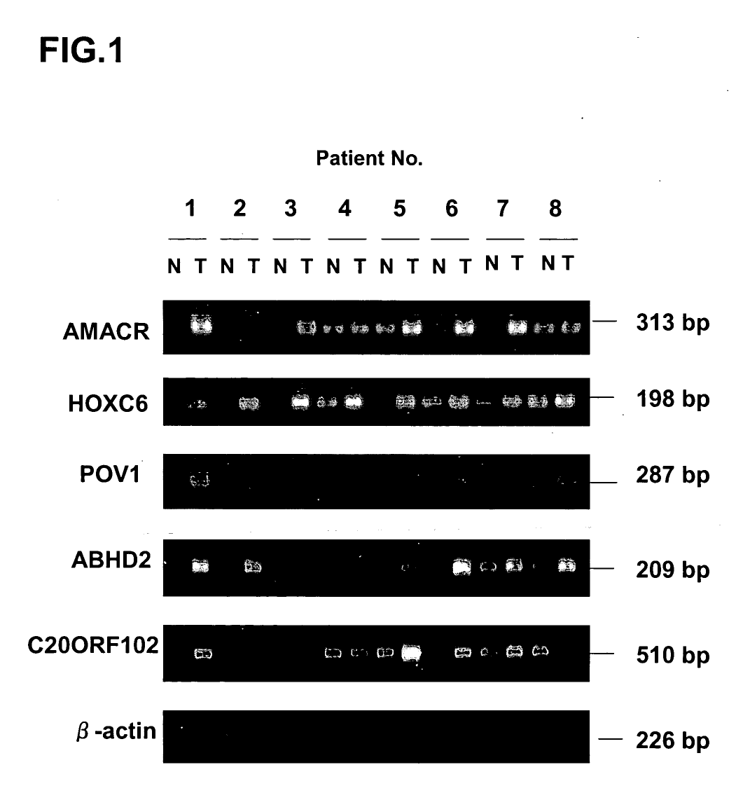

Comparing the ratios of the expression levels of the 4 up-regulated genes (AMACR, HOXC6, POV1, ABHD2 and C20ORF102) whose expression were over-expressed in almost of all informative cases the results were highly similar to those of the microarray analysis in the great majority of the tested cases (FIG. 1). These data verified the reliability of our strategy to identify commonly up-regulated genes in PRC cells.

TABLE 3
Commonly up-regulated genes in prostate cancers and PINs

| | | | | |
|---|---|---|---|---|
| PRC Assignment | Accession No. | Hs. | Symbol | Title |

function known

| | | | | |
|---|---|---|---|---|
| 1 | M93107 | 76893 | BDH | 3-hydroxybutyrate |
| | | | | dehydrogenase (heart, |
| | | | | mitochondrial) |
| 2 | U89281 | 11958 | RODH | 3-hydroxysteroid epimerase |
| 3 | L41559 | 3192 | PCBD | 6-pyruvoyl-tetrahydropterin |
| | | | | synthase/dimerization cofactor of |
| | | | | hepatocyte nuclear factor 1 alpha |
| | | | | (TCF1) |
| 4 | AJ130733 | 128749 | AMACR | alpha-methylacyl-CoA racemase |
| 5 | S77410 | 89472 | AGTR1 | angiotensin II receptor, type 1 |
| 6 | AI080640 | 413945 | AGR2 | anterior gradient 2 homolog |
| | | | | (Xenepus laevis) |
| 7 | NM_000487 | 88251 | ARSA | arylsulfatase A |
| 8 | AF071202 | 139336 | ABCC4 | ATP-binding cassette, sub- |
| | | | | family C (CFTR/MRP), member 4 |
| 9 | NM_000060 | 78885 | BTD | biotinidase |
| 10 | D90276 | 12 | CEACAM4 | carcinoembryonic antigen- |
| | | | | related cell adhesion molecule 4 |
| 11 | AB030905 | 406384 | CBX3 | chromobox homolog 3 (HP1 |
| | | | | gamma homolog, Drosophila) |
| 12 | BF106962 | 20415 | FAM3B | chromosome 21 open reading |
| | | | | frame 11 |
| 13 | AI817172 | 29423 | COLEC12 | collectin sub-family member 12 |
| 14 | NM_005436 | 288862 | D10S170 | DNA segment on chromosome |
| | | | | 10 (unique) 170 |
| 15 | U31556 | 2331 | E2F5 | E2F transcription factor 5, p130- |
| | | | | binding |
| 16 | AF039918 | 80975 | ENTPD5 | ectonucleoside triphosphate |
| | | | | diphosphohydrolase 5 |
| 17 | L10340 | 2642 | EEF1A2 | eukaryotic translation elongation |
| | | | | factor 1 alpha 2 |
| 18 | AI984005 | 380785 | XPOT | exportin, tRNA (nuclear export |
| | | | | receptor for tRNAs) |
| 19 | NM_000166 | 333303 | GJBI | gap junction protein, beta 1, |
| | | | | 32 kDa (connexin 32, Charcot- |
| | | | | Marie-Tooth neuropathy, X- |
| | | | | linked) |
| 20 | AF040260 | 105435 | GMDS | GDP-mannose 4,6-dehydratase |
| 21 | AF236056 | 182793 | GOLPH2 | golgi phosphoprotein 2 |
| 22 | AF055013 | 203862 | GNAI1 | guanine nucleotide binding |
| | | | | protein (G protein), alpha |
| | | | | inhibiting activity polypeptide 1 |
| 23 | NM_000856 | 75295 | GUCY1A3 | guanylate cyclase 1, soluble, |
| | | | | alpha 3 |
| 24 | S82986 | 820 | HOXC6 | homeo box C6 |
| 25 | U42408 | 18141 | LAD1 | ladinin 1 |
| 26 | M88468 | 130607 | MVK | mevalonate kinase (mevalonic |
| | | | | aciduria) |
| 27 | D56064 | 167 | MAP2 | microtubule-associated protein 2 |
| 28 | AI302799 | 68583 | MIPEP | mitochondrial intermediate |
| | | | | peptidase |
| 29 | AB002387 | 118483 | MYO6 | myosin VI |
| 30 | R22536 | 220324 | FLJ13052 | NAD kinase |
| 31 | AI246554 | 31547 | NDUFA8 | NADH dehydrogenase |
| | | | | (ubiquinone) 1 alpha |
| | | | | subcomplex, 8, 19 kDa |
| 32 | AA858162 | 124673 | NCAG1 | NCAG1 |
| 33 | AI805082 | 303171 | OR51E2 | olfactory receptor, family 51, |
| | | | | subfamily E, member 2 |
| 34 | U79240 | 79337 | PASK | PAS domain containing |
| | | | | serine/threonine kinase |
| 35 | BF690393 | 83383 | PRDX4 | peroxiredoxin 4 |
| 36 | AK025460 | 286049 | PSA | phosphoserine aminotransferase |
| 37 | NM_021200 | 380812 | PLEKHB1 | pleckstrin homology domain |
| | | | | containing, family B (evectins) |
| | | | | member 1 |
| 38 | L14778 | 272458 | PPP3CA | protein phosphatase 3 (formerly |
| | | | | 2B), catalytic subunit, alpha |
| | | | | isoform (calcineurin A alpha) |
| 39 | AF044588 | 344037 | PRC1 | protein regulator of cytokinesis 1 |
| 40 | NM_006765 | 71119 | N33 | Putative prostate cancer tumor |
| | | | | suppressor |
| 41 | NM_012342 | 78776 | NMA | putative transmembrane protein |
| 42 | M77836 | 79217 | PYCR1 | pyrroline-5-carboxylate |
| | | | | reductase 1 |
| 43 | D42063 | 199179 | RANBP2 | RAN binding protein 2 |
| 44 | AF064824 | 103755 | RIPK2 | receptor-interacting serine- |
| | | | | threonine kinase 2 |
| 45 | N78357 | 302136 | RIMS1 | regulating synaptic membrane |
| | | | | exocytosis 1 |
| 46 | L10333 | 99947 | RTN1 | reticulon 1 |
| 47 | Y18418 | 272822 | RUVBL1 | RuvB-like 1 (E. coli) |
| 48 | U80456 | 27311 | SIM2 | single-minded homolog 2 |
| | | | | (Drosophila) |
| 49 | AF269150 | 8203 | SMBP | SM-11044 binding protein |
| 50 | U17566 | 84190 | SLC19A1 | solute carrier family 19 (folate |
| | | | | transporter), member 1 |
| 51 | D88308 | 11729 | SLC27A2 | solute carrier family 27 (fatty |
| | | | | acid transporter), member 2 |
| 52 | AF007216 | 5462 | SLC4A4 | solute carrier family 4, sodium |
| | | | | bicarbonate cotransporter, |
| | | | | member 4 |
| 53 | AD001528 | 89718 | SMS | spermine synthase |
| 54 | M32313 | 552 | SRD5A1 | steroid-5-alpha-reductase, alpha |
| | | | | polypeptide 1 (3-oxo-5 alpha- |
| | | | | steroid delta 4-dehydrogenase |
| | | | | alpha 1) |
| 55 | L15203 | 82961 | TFF3 | trefoil factor 3 (intestinal) |
| 56 | M91670 | 174070 | E2-EPF | ubiquitin carrier protein |
| 57 | AW135763 | 6375 | HT010 | uncharacterized hypothalamus |
| | | | | protein HT010 |

function unknown

| | | | | |
|---|---|---|---|---|
| 58 | AA206763 | 7991 | C20orf102 | chromosome 20 open reading |
| | | | | frame 102 |
| 59 | AI989530 | 240845 | DKFZP434D146 | DKFZP434D146 protein |
| 60 | AI192351 | 76285 | DKFZP564B167 | DKFZP564B167 protein |
| 61 | AI133467 | 95612 | | ESTs |
| 62 | H17800 | 438858 | | ESTs |
| 63 | AI732103 | | | ESTs |
| 64 | AI671006 | 5794 | | ESTs, Moderately similar to |
| | | | | hypothetical protein FLJ20234 |
| | | | | [Homo sapiens] [H. sapiens] |
| 65 | AA420675 | 188826 | | ESTs, Moderately similar to |
| | | | | RL39_HUMAN 60S ribosomal |
| | | | | protein L39 [H. sapiens] |
| 66 | AI700341 | 110406 | | ESTs, Weakly similar to |
| | | | | hypothetical protein FLJ20489 |
| | | | | [Homo sapiens] [H. sapiens] |
| 67 | BF057183 | 355809 | | ESTs, Weakly similar to male- |
| | | | | specific lethal 3-like 1 isoform |
| 68 | H05758 | 355684 | | ESTs, Weakly similar to |
| | | | | neuronal thread protein [Homo |
| | | | | sapiens] |
| 69 | AA743348 | 120591 | | Homo sapiens cDNA FLJ35632 |
| | | | | fis, clone SPLEN2011678. |
| 70 | AA679304 | 5740 | | Homo sapiens cDNA FLJ40165 |
| | | | | fis, clone TESTI2015962. |
| 71 | AK027019 | 381105 | | Homo sapiens cDNA: FLJ23366 |
| | | | | fis, clone HEP15665. |
| 72 | AA994004 | 128790 | | Homo sapiens mRNA full length |
| | | | | insert cDNA clone |
| | | | | EUROIMAGE 1628928 |
| 73 | H09779 | 283851 | | Homo sapiens mRNA; cDNA |
| | | | | DKFZp547G036 (from clone |
| | | | | DKFZp547G036) |
| 74 | BE254330 | 14846 | | Homo sapiens mRNA; cDNA |
| | | | | DKFZp564D016 (from clone |
| | | | | DKFZp564D016) |
| 75 | AL157505 | 21380 | | Homo sapiens mRNA; cDNA |
| | | | | DKFZp586P1124 (from clone |
| | | | | DKFZp586P1124) |
| 76 | AI217963 | 434541 | | Homo sapiens, clone |
| | | | | IMAGE: 4429946, mRNA |
| 77 | BF724600 | 22247 | | Homo sapiens, clone |
| | | | | IMAGE: 5302158, mRNA |
| 78 | NM_012066 | 128702 | 20D7-FC4 | hypothetical protein 20D7-FC4 |
| 79 | AB029008 | 84045 | FLJ20288 | FLJ20288 protein |
| 80 | AK026325 | 235873 | FLJ22672 | hypothetical protein FLJ22672 |
| 81 | R55332 | 379386 | LOC115286 | hypothetical protein LOC115286 |
| 82 | H12084 | 31110 | MGC34827 | hypothetical protein MGC34827 |
| 83 | D29954 | 13421 | KIAA0056 | KIAA0056 protein |
| 84 | AB020637 | 167115 | KIAA0830 | KIAA0830 protein |
| 85 | AB023157 | 131945 | KIAA0940 | KIAA0940 protein |
| 86 | AB032981 | 102657 | KIAA1155 | KIAA1155 protein |
| 87 | AB032983 | 21894 | KIAA1157 | KIAA1157 protein |
| 88 | AB033091 | 446390 | KIAA1265 | KIAA1265 protein |

TABLE 4
Commonly down-regulated genes in prostate cancers and PINs

| | | | | |
|---|---|---|---|---|
| PRC Assignment | Accession No. | Hs. | Symbol | Title |

function known

| | | | | |
|---|---|---|---|---|
| 89 | NM_002526 | 153952 | NT5E | 5′-nucleotidase, ecto (CD73) |
| 90 | NM_005159 | 118127 | ACTC | actin, alpha, cardiac muscle |
| 91 | NM_001615 | 378774 | ACTG2 | actin, gamma 2, smooth |
| | | | | muscle, enteric |
| 92 | AL117643 | 99954 | ACVR1B | activin A receptor, type IB |
| 93 | BG105547 | 324470 | ADD3 | adducin 3 (gamma) |
| 94 | AF245505 | 72157 | DKFZp564I1922 | adlican |
| 95 | N74230 | 193228 | AGXT2 | alanine-glyoxylate |
| | | | | aminotransferase 2 |
| 96 | K03000 | 76392 | ALDH1A1 | aldehyde dehydrogenase 1 |
| | | | | family, member A1 |
| 97 | M28443 | 300280 | AMY2A | amylase, alpha 2A; pancreatic |
| 98 | AF286598 | 9271 | AMOT | angiomotin |
| 99 | NM_000700 | 78225 | ANXA1 | annexin A1 |
| 100 | D00017 | 217493 | ANXA2 | annexin A2 |
| 101 | NM_001155 | 118796 | ANXA6 | annexin A6 |
| 102 | AK027126 | 160786 | ASS | argininosuccinate synthetase |
| 103 | AA054346 | 32168 | AUTS2 | autism susceptibility candidate 2 |
| 104 | AL117565 | 6607 | AXUD1 | AXIN1 up-regulated 1 |
| 105 | AB004066 | 171825 | BHLHB2 | basic helix-loop-helix domain |
| | | | | containing, class B, 2 |
| 106 | M14745 | 79241 | BCL2 | B-cell CLL/lymphoma 2 |
| 107 | S67310 | 69771 | BF | B-factor, properdin |
| 108 | M69225 | 198689 | BPAG1 | bullous pemphigoid antigen 1, |
| | | | | 230/240 kDa |
| 109 | X63629 | 2877 | CDH3 | cadherin 3, type 1, P-cadherin |
| | | | | (placental) |
| 110 | R45979 | 252387 | CELSR1 | cadherin, EGF LAG seven- |
| | | | | pass G-type receptor 1 |
| | | | | (flamingo homolog, |
| | | | | Drosophila) |
| 111 | AF134640 | 7235 | CACNG3 | calcium channel, voltage- |
| | | | | dependent, gamma subunit 3 |
| 112 | D17408 | 21223 | CNN1 | calponin 1, basic, smooth |
| | | | | muscle |
| 113 | K01144 | 84298 | CD74 | CD74 antigen (invariant |
| | | | | polypeptide of major |
| | | | | histocompatibility complex, |
| | | | | class II antigen-associated) |
| 114 | NM_001878 | 183650 | CRABP2 | cellular retinoic acid binding |
| | | | | protein 2 |
| 115 | NM_002996 | 80420 | CX3CL1 | chemokine (C-X3-C motif) |
| | | | | ligand 1 |
| 116 | U16306 | 81800 | CSPG2 | chondroitin sulfate |
| | | | | proteoglycan 2 (versican) |
| 117 | AV648364 | 356416 | CBX7 | chromobox homolog 7 |
| 118 | AF000959 | 110903 | CLDN5 | claudin 5 (transmembrane |
| | | | | protein deleted in |
| | | | | velocardiofacial syndrome) |
| 119 | NM_001831 | 75106 | CLU | clusterin (SP-40, 40, sulfated |
| | | | | glycoprotein 2, testosterone- |
| | | | | repressed prostate message 2) |
| 120 | L02870 | 1640 | COL7A1 | collagen, type VII, alpha 1 |
| | | | | (epidermolysis bullosa, |
| | | | | dystrophic, dominant and |
| | | | | recessive) |
| 121 | AF018081 | 78409 | COL18A1 | collagen, type XVIII, alpha 1 |
| 122 | NM_001733 | 1279 | C1R | complement component 1, r |
| | | | | subcomponent |
| 123 | J04080 | 434029 | C1S | complement component 1, s |
| | | | | subcomponent |
| 124 | K02765 | 284394 | C3 | complement component 3 |
| 125 | AF007162 | 408767 | CRYAB | crystallin, alpha B |
| 126 | L12579 | 147049 | CUTL1 | cut-like 1, CCAAT |
| | | | | displacement protein |
| | | | | (Drosophila) |
| 127 | NM_000076 | 106070 | CDKN1C | cyclin-dependent kinase |
| | | | | inhibitor 1C (p57, Kip2) |
| 128 | BF183952 | 412999 | CSTA | cystatin A (stefin A) |
| 129 | NM_004078 | 108080 | CSRP1 | cysteine and glycine-rich |
| | | | | protein 1 |
| 130 | J04813 | 104117 | CYP3A5 | cytochrome P450, family 3, |
| | | | | subfamily A, polypeptide 5 |
| 131 | AF070590 | 90869 | LOC90957 | DEAH-box RNA/DNA |
| | | | | helicase AAM73547 |
| 132 | NM_004394 | 75189 | DAP | death-associated protein |
| 133 | D83407 | 156007 | DSCR1L1 | Down syndrome critical |
| | | | | region gene 1-like 1 |
| 134 | L11329 | 1183 | DUSP2 | dual specificity phosphatase 2 |
| 135 | AW002941 | 339283 | ERAP140 | endoplasmic reticulum |
| | | | | associated protein 140 kDa |
| 136 | J04162 | 176663 | FCGR3A | Fc fragment of IgG, low |
| | | | | affinity IIIa, receptor for |
| | | | | (CD16) |
| 137 | M87770 | 278581 | FGFR2 | fibroblast growth factor |
| | | | | receptor 2 |
| 138 | X02761 | 287820 | FN1 | fibronectin 1 |
| 139 | NM_001456 | 195464 | FLNA | filamin A, alpha (actin binding |
| | | | | protein 280) |
| 140 | U60115 | 239069 | FHL1 | four and a half LIM domains 1 |
| 141 | L42176 | 8302 | FHL2 | four and a half LIM domains 2 |
| 142 | U28963 | 380901 | GPS2 | G protein pathway suppressor 2 |
| 143 | AW949747 | 169946 | GATA3 | GATA binding protein 3 |
| 144 | AK021685 | 234896 | GMNN | geminin, DNA replication |
| | | | | inhibitor |
| 145 | BF115308 | 132760 | G6PT1 | glucose-6-phosphatase, |
| | | | | transport (glucose-6- |
| | | | | phosphate) protein 1 |
| 146 | NM_002083 | 2704 | GPX2 | glutathione peroxidase 2 |
| | | | | (gastrointestinal) |
| 147 | NM_002084 | 386793 | GPX3 | glutathione peroxidase 3 |
| | | | | (plasma) |
| 148 | AA290738 | 301961 | GSTM1 | glutathione S-transferase M1 |
| 149 | NM_002081 | 2699 | GPC1 | glypican 1 |
| 150 | M55543 | 171862 | GBP2 | guanylate binding protein 2, |
| | | | | interferon-inducible |
| 151 | NM_000186 | 250651 | HF1 | H factor 1 (complement) |
| 152 | AK000415 | 250666 | HES1 | hairy and enhancer of split 1, |
| | | | | (Drosophila) |
| 153 | AA522530 | 111244 | RTP801 | HIF-1 responsive RTP801 |
| 154 | AA490691 | 421136 | HOXD11 | homeo box D11 |
| 155 | J02770 | 36602 | IF | I factor (complement) |
| 156 | S81914 | 76095 | IER3 | immediate early response 3 |
| 157 | M87790 | 102950 | IGLJ3 | immunoglobulin lambda |
| | | | | joining 3 |
| 158 | L08488 | 32309 | INPP1 | inositol polyphosphate-1- |
| | | | | phosphatase |
| 159 | M31159 | 77326 | IGFBP3 | insulin-like growth factor |
| | | | | binding protein 3 |
| 160 | M59911 | 265829 | ITGA3 | integrin, alpha 3 (antigen |
| | | | | CD49C, alpha 3 subunit of |
| | | | | VLA-3 receptor) |
| 161 | X52186 | 85266 | ITGB4 | integrin, beta 4 |
| 162 | NM_006435 | 174195 | IFITM2 | interferon induced |
| | | | | transmembrane protein 2 (1- |
| | | | | 8D) |
| 163 | NM_002198 | 80645 | IRF1 | interferon regulatory factor 1 |
| 164 | AF020201 | 166154 | JAG2 | jagged 2 |
| 165 | M25629 | 123107 | KLK1 | kallikrein 1, |
| | | | | renal/pancreas/salivary |
| 166 | X14640 | 74070 | KRT13 | keratin 13 |
| 167 | X07696 | 80342 | KRT15 | keratin 15 |
| 168 | NM_000422 | 2785 | KRT17 | keratin 17 |
| 169 | Y00503 | 182265 | KRT19 | keratin 19 |
| 170 | M21389 | 433845 | KRT5 | keratin 5 (epidermolysis |
| | | | | bullosa simplex, Dowling- |
| | | | | Meara/Kobner/Weber- |
| | | | | Cockayne types) |
| 171 | X03212 | 23881 | KRT7 | keratin 7 |
| 172 | NM_000226 | 2783 | KRT9 | keratin 9 (epidermolytic |
| | | | | palmoplantar keratoderma) |
| 173 | D14520 | 84728 | KLF5 | Kruppel-like factor 5 |
| | | | | (intestinal) |
| 174 | U07643 | 105938 | LTF | lactotransferrin |
| 175 | D37766 | 75517 | LAMB3 | laminin, beta 3 |
| 176 | AW139663 | 166254 | VMP1 | likely ortholog of rat vacuole |
| | | | | membrane protein 1 |
| 177 | AF002672 | 152944 | LOH11CR2A | loss of heterozygosity, 11, |
| | | | | chromosomal region 2, gene A |
| 178 | AI814306 | 42438 | LSM6 | LSM6 homolog, U6 small |
| | | | | nuclear RNA associated (S. cerevisiae) |
| 179 | Z68179 | 77667 | LY6E | lymphocyte antigen 6 |
| | | | | complex, locus E |
| 180 | BE621666 | 296398 | LAPTM4B | lysosomal associated protein |
| | | | | transmembrane 4 beta |
| 181 | M33906 | 198253 | HLA-DQA1 | major histocompatibility |
| | | | | complex, class II, DQ alpha 1 |
| 182 | K01171 | 409805 | HLA-DRA | major histocompatibility |
| | | | | complex, class II, DR alpha |
| 183 | M15178 | 318720 | HLA-DRB4 | major histocompatibility |
| | | | | complex, class II, DR beta 4 |
| 184 | BF697545 | 365706 | MGP | matrix Gla protein |
| 185 | AW298180 | 2256 | MMP7 | matrix metalloproteinase 7 |
| | | | | (matrilysin, uterine) |
| 186 | AF017418 | 104105 | MEIS2 | Meis1, myeloid ecotropic viral |
| | | | | integration site 1 homolog 2 |
| | | | | (mouse) |
| 187 | BF971884 | 118786 | MT2A | metallothionein 2A |
| 188 | NM_005928 | 3745 | MFGE8 | milk fat globule-EGF factor 8 |
| | | | | protein |
| 189 | J05581 | 89603 | MUC1 | mucin 1, transmembrane |
| 190 | AA628530 | 405873 | ISYNA1 | myo-inositol 1-phosphate |
| | | | | synthase A1 |
| 191 | J02854 | 9615 | MYL9 | myosin, light polypeptide 9, |
| | | | | regulatory |
| 192 | AF005888 | 173162 | NOC4 | neighbor of COX4 |
| 193 | AA886412 | 69285 | NRP1 | neuropilin 1 |
| 194 | L31881 | 35841 | NFIX | nuclear factor I/X (CCAAT- |
| | | | | binding transcription factor) |
| 195 | X75918 | 82120 | NR4A2 | nuclear receptor subfamily 4, |
| | | | | group A, member 2 |
| 196 | M13692 | 572 | ORM1 | orosomucoid 1 |
| 197 | U90878 | 75807 | PDLIM1 | PDZ and LIM domain 1 |
| | | | | (elfin) |
| 198 | NM_005036 | 998 | PPARA | peroxisome proliferative |
| | | | | activated receptor, alpha |
| 199 | AF035959 | 24879 | PPAP2C | phosphatidic acid phosphatase |
| | | | | type 2C |
| 200 | AB003723 | 18079 | PIGQ | phosphatidylinositol glycan, |
| | | | | class Q |
| 201 | D00244 | 77274 | PLAU | plasminogen activator, |
| | | | | urokinase |
| 202 | AF091434 | 43080 | PDGFC | platelet derived growth factor C |
| 203 | AF027208 | 112360 | PROML1 | prominin-like 1 (mouse) |
| 204 | AL045876 | 430637 | PTGDS | prostaglandin D2 synthase |
| | | | | 21 kDa (brain) |
| 205 | BF510741 | 5648 | PSMD9 | proteasome (prosome, |
| | | | | macropain) 26S subunit, non- |
| | | | | ATPase, 9 |
| 206 | M65066 | 1519 | PRKAR1B | protein kinase, cAMP- |
| | | | | dependent, regulatory, type I, |
| | | | | beta |
| 207 | AW249758 | 96593 | ARHF | ras homolog gene family, |
| | | | | member F (in filopodia) |
| 208 | X73427 | 75256 | RGS1 | regulator of G-protein |
| | | | | signalling 1 |
| 209 | U72066 | 29287 | RBBP8 | retinoblastoma binding protein 8 |
| 210 | NM_003979 | 194691 | RAI3 | retinoic acid induced 3 |
| 211 | L20688 | 83656 | ARHGDIB | Rho GDP dissociation |
| | | | | inhibitor (GDI) beta |
| 212 | X64652 | 241567 | RBMS1 | RNA binding motif single |
| | | | | stranded interacting protein 1 |
| 213 | AA173755 | 301198 | ROBO1 | roundabout, axon guidance |
| | | | | receptor, homolog 1 |
| | | | | (Drosophila) |
| 214 | AF132734 | 107394 | SEC8 | secretory protein SEC8 |
| 215 | NM_004636 | 82222 | SEMA3B | sema domain, |
| | | | | immunoglobulin domain (Ig), |
| | | | | short basic domain, secreted, |
| | | | | (semaphorin) 3B |
| 216 | M93056 | 183583 | SERPINB1 | serine (or cysteine) proteinase |
| | | | | inhibitor, clade B |
| | | | | (ovalbumin), member 1 |
| 217 | M13690 | 151242 | SERPING1 | serine (or cysteine) proteinase |
| | | | | inhibitor, clade G (C1 |
| | | | | inhibitor), member 1 |
| 218 | NM_006456 | 288215 | STHM | sialyltransferase |
| 219 | AF070609 | 75379 | SLC1A3 | solute carrier family 1 (glial |
| | | | | high affinity glutamate |
| | | | | transporter), member 3 |
| 220 | AF215636 | 5944 | SLC11A3 | solute carrier family 11 |
| | | | | (proton-coupled divalent |
| | | | | metal ion transporters), |
| | | | | member 3 |
| 221 | U59299 | 90911 | SLC16A5 | solute carrier family 16 |
| | | | | (monocarboxylic acid |
| | | | | transporters), member 5 |
| 222 | Y08110 | 101657 | SORL1 | sortilin-related receptor, |
| | | | | L(DLR class) A repeats- |
| | | | | containing |
| 223 | M81635 | 160483 | STOM | stomatin |
| 224 | U15131 | 79265 | ST5 | suppression of tumorigenicity 5 |
| 225 | BF514189 | 345728 | SOCS3 | suppressor of cytokine |
| | | | | signaling 3 |
| 226 | AI423028 | 71622 | SMARCD3 | SWI/SNF related, matrix |
| | | | | associated, actin dependent |
| | | | | regulator of chromatin, |
| | | | | subfamily d, member 3 |
| 227 | U21847 | 82173 | TIEG | TGFB inducible early growth |
| | | | | response |
| 228 | U54831 | 75248 | TOP2B | topoisomerase (DNA) II beta |
| | | | | 180 kDa |
| 229 | S95936 | 396489 | TF | transferring |
| 230 | M77349 | 118787 | TGFBI | transforming growth factor, |
| | | | | beta-induced, 68 kDa |
| 231 | NM_003186 | 433399 | TAGLN | transgelin |
| 232 | M98479 | 75307 | TGM2 | transglutaminase 2 (C |
| | | | | polypeptide, protein- |
| | | | | glutamine-gamma- |
| | | | | glutamyltransferase) |
| 233 | L24203 | 82237 | TRIM29 | tripartite motif-containing 29 |
| 234 | AF208860 | 159651 | TNFRSF21 | tumor necrosis factor receptor |
| | | | | superfamily, member 21 |
| 235 | U44839 | 171501 | USP11 | ubiquitin specific protease 11 |
| 236 | L13852 | 16695 | UBE1L | ubiquitin-activating enzyme |
| | | | | E1-like |
| 237 | X63187 | 2719 | WFDC2 | WAP four-disulfide core |
| | | | | domain 2 |
| 238 | AF122922 | 284122 | WIF1 | WNT inhibitory factor 1 |
| 239 | AA909999 | 50216 | ZFD25 | zinc finger protein (ZFD25) |
| 240 | AA916688 | 85155 | ZFP36L1 | zinc finger protein 36, C3H |
| | | | | type-like 1 |

function unknown

| | | | | |
|---|---|---|---|---|
| 241 | AB002384 | 101359 | C6orf32 | chromosome 6 open reading |
| | | | | frame 32 |
| 242 | AA620628 | 186486 | | ESTs |
| 243 | AA632025 | 444752 | | ESTs |
| 244 | AA904658 | 117299 | | ESTs |
| 245 | AI022658 | 292171 | | ESTs |
| 246 | AI027791 | 132296 | | ESTs |
| 247 | AI338011 | 132147 | | ESTs |
| 248 | AI732637 | 277901 | | ESTs |
| 249 | BE868254 | 380149 | | ESTs |
| 250 | H53099 | 420009 | | ESTs |
| 251 | N95414 | 55168 | | ESTs, Weakly similar to |
| | | | | neuronal thread protein |
| | | | | [Homo sapiens] [H. sapiens] |
| 252 | BG163478 | 405950 | | ESTs, Weakly similar to |
| | | | | BAI1_HUMAN Brain- |
| | | | | specific angiogenesis inhibitor |
| | | | | 1 precursor [H. sapiens] |
| 253 | AI342255 | 24192 | | Homo sapiens cDNA |
| | | | | FLJ20767 fis, clone |
| | | | | COL06986. |
| 254 | AI651212 | 4283 | | Homo sapiens cDNA |
| | | | | FLJ31125 fis, clone |
| | | | | IMR322000819. |
| 255 | AW967916 | 31944 | | Homo sapiens cDNA |
| | | | | FLJ33236 fis, clone |
| | | | | ASTRO2002571. |
| 256 | AI566720 | 380045 | | Homo sapiens cDNA |
| | | | | FLJ34528 fis, clone |
| | | | | HLUNG2008066 |
| 257 | W93000 | 59389 | | Homo sapiens cDNA |
| | | | | FLJ38601 fis, clone |
| | | | | HEART2003781. |
| 258 | BE885999 | 397414 | | Homo sapiens cDNA: |
| | | | | FLJ20860 fis, clone |
| | | | | ADKA01632. |
| 259 | AK025909 | 288741 | | Homo sapiens cDNA: |
| | | | | FLJ22256 fis, clone |
| | | | | HRC02860. |
| 260 | AK025953 | 380437 | | Homo sapiens cDNA: |
| | | | | FLJ22300 fis, clone |
| | | | | HRC04759. |
| 261 | BF311166 | 110783 | | Homo sapiens cDNA: |
| | | | | FLJ22365 fis, clone |
| | | | | HRC06613. |
| 262 | AI097529 | 8136 | | Homo sapiens clone 23698 |
| | | | | mRNA sequence |
| 263 | AI269367 | 101307 | | Homo sapiens HUT11 protein |
| | | | | mRNA, partial 3′ UTR |
| 264 | N58556 | 323053 | | Homo sapiens mRNA full |
| | | | | length insert cDNA clone |
| | | | | EUROIMAGE 26539. |
| 265 | AL110236 | 321022 | | Homo sapiens mRNA; cDNA |
| | | | | DKFZp566P1124 (from clone |
| | | | | DKFZp566P1124) |
| 266 | BF791544 | 351680 | | Homo sapiens, clone |
| | | | | IMAGE: 4103364, mRNA |
| 267 | AV733210 | 367688 | | Homo sapiens, clone |
| | | | | IMAGE: 4794726, mRNA |
| 268 | AA456955 | 78026 | | Homo sapiens, Similar to |
| | | | | hypothetical protein |
| | | | | C130031J23, clone |
| | | | | IMAGE: 3445545, mRNA, |
| | | | | partial cds |
| 269 | AL120399 | 343567 | LOC151568 | hypothetical protein |
| | | | | BC009491 |
| 270 | BE539165 | 355793 | DKFZp313M0720 | hypothetical protein |
| | | | | DKFZp313M0720 |
| 271 | AA709155 | 104800 | FLJ10134 | hypothetical protein FLJ10134 |
| 272 | AK001061 | 30925 | FLJ10199 | hypothetical protein FLJ10199 |
| 273 | AK001431 | 5105 | FLJ10569 | hypothetical protein FLJ10569 |
| 274 | AI709055 | 115412 | FLJ13881 | hypothetical protein FLJ13881 |
| 275 | AK026058 | 27556 | FLJ22405 | hypothetical protein FLJ22405 |
| 276 | AW271223 | 5890 | FLJ23306 | hypothetical protein FLJ23306 |
| 277 | N31935 | 220745 | FLJ25604 | hypothetical protein FLJ25604 |
| 278 | AK001839 | 206501 | LOC57228 | hypothetical protein from |
| | | | | clone 643 |
| 279 | AK022547 | 8694 | LOC56965 | hypothetical protein from |
| | | | | EUROIMAGE 1977056 |
| 280 | AA180145 | 351270 | LOC152485 | hypothetical protein |
| | | | | LOC152485 |
| 281 | AK024828 | 69388 | LOC221749 | hypothetical protein |
| | | | | LOC221749 |
| 282 | AV758898 | 366 | MGC27165 | hypothetical protein |
| | | | | MGC27165 |
| 283 | AW888223 | 59384 | MGC3047 | hypothetical protein |
| | | | | MGC3047 |
| 284 | AA133590 | 377830 | MGC44669 | hypothetical protein |
| | | | | MGC44669 |
| 285 | L13720 | 207251 | MGC5560 | hypothetical protein |
| | | | | MGC5560 |
| 286 | AI206046 | 50535 | MGC7036 | hypothetical protein |
| | | | | MGC7036 |
| 287 | AB002319 | 8663 | KIAA0321 | KIAA0321 protein |
| 288 | AB011125 | 105749 | KIAA0553 | KIAA0553 protein |
| 289 | AB037797 | 24684 | KIAA1376 | KIAA1376 protein |
| 290 | AI741882 | 278436 | KIAA1474 | KIAA1474 protein |
| 291 | AA521149 | 17767 | KIAA1554 | KIAA1554 protein |
| 292 | N62352 | 24790 | KIAA1573 | KIAA1573 protein |
| 293 | AW976121 | 301444 | KIAA1673 | KIAA1673 |
| 294 | AI890497 | 28501 | KIAA1754 | KIAA1754 protein |
| 295 | T78873 | 9587 | KIAA2002 | KIAA2002 protein |

TABLE 5
Commonly up-regulated genes in 20 prostate cancers

| | | | | |
|---|---|---|---|---|
| PRC Assignment | Accession No. | Hs. | Symbol | Title |

function known

| | | | | |
|---|---|---|---|---|
| 296 | X12433 | 99364 | ABHD2 | abhydrolase domain containing 2 |
| 297 | AF039018 | 135281 | ALP | alpha-actinin-2-associated LIM protein |
| 298 | AJ130733 | 128749 | AMACR | alpha-methylacyl-CoA racemase |
| 299 | J02611 | 75736 | APOD | apolipoprotein D |
| 300 | AF071202 | 139336 | ABCC4 | ATP-binding cassette, sub-family C |
| | | | | (CFTR/MRP), member 4 |
| 301 | AA633487 | 108708 | CAMKK2 | calcium/calmodulin-dependent protein kinase |
| | | | | kinase 2, beta |
| 302 | AF001436 | 12289 | CDC42EP2 | CDC42 effector protein (Rho GTPase binding) 2 |
| 303 | BF981201 | 408061 | FABP5 | fatty acid binding protein 5 (psoriasis-associated) |
| 304 | D14446 | 107 | FGL1 | fibrinogen-like 1 |
| 305 | S82986 | 820 | HOXC6 | homeo box C6 |
| 306 | AF064493 | 4980 | LDB2 | LIM domain binding 2 |
| 307 | AI767296 | 123655 | NPR3 | natriuretic peptide receptor C/guanylate cyclase C |
| | | | | (atrionatriuretic peptide receptor C) |
| 308 | AA858162 | 124673 | NCAG1 | NCAG1 |
| 309 | AI805082 | 303171 | OR51E2 | olfactory receptor, family 51, subfamily E, |
| | | | | member 2 (prostate-specific G protein-coupled |
| | | | | receptor) |
| 310 | AF045584 | 18910 | POV1 | prostate cancer overexpressed gene 1 |
| 311 | AI298501 | 21192 | SDK1 | sidekick homolog 1 (chicken) |
| 312 | U80456 | 27311 | SIM2 | single-minded homolog 2 (Drosophila) |
| 313 | AD001528 | 89718 | SMS | spermine synthase |
| 314 | N21096 | 99291 | STXBP6 | syntaxin binding protein 6 (amisyn) |
| 315 | L15203 | 82961 | TFF3 | trefoil factor 3 (intestinal) |

function unknown

| | | | | |
|---|---|---|---|---|
| 316 | D14657 | 81892 | KIAA0101 | KIAA0101 gene product |
| 317 | AI989530 | 240845 | DKFZP434D146 | DKFZP434D146 protein |
| 318 | NM_012066 | 128702 | 20D7-FC4 | hypothetical protein 20D7-FC4 |
| 319 | AA206763 | 7991 | C20orf102 | chromosome 20 open reading frame 102 |
| 320 | AI700341 | 110406 | | ESTs, Weakly similar to hypothetical protein |
| | | | | FLJ20489 [Homo sapiens] |
| 321 | AI003798 | 23799 | | Homo sapiens, clone IMAGE: 4791783, mRNA |

TABLE 6
Commonly down-regulated genes in 20 prostate cancers

| | | | | |
|---|---|---|---|---|
| PRC Assignment | Accession No. | Hs. | Symbol | Title |

function known

| | | | | |
|---|---|---|---|---|
| 322 | AI827230 | 374481 | APCDD1 | adenomatosis polyposis coli down-regulated 1 |
| 323 | BF965257 | 74120 | APM2 | adipose specific 2 |
| 324 | AF245505 | 72157 | DKFZp564I1922 | adlican |
| 325 | D00017 | 217493 | ANXA2 | annexin A2 |
| 326 | NM_001155 | 118796 | ANXA6 | annexin A6 |
| 327 | AK027126 | 160786 | ASS | argininosuccinate synthetase |
| 328 | W91908 | 6079 | GALNAC4S- | B cell RAG associated protein |
| | | | 6ST | |
| 329 | AB004066 | 171825 | BHLHB2 | basic helix-loop-helix domain containing, class B, 2 |
| 330 | M14745 | 79241 | BCL2 | B-cell CLL/lymphoma 2 |
| 331 | S67310 | 69771 | BF | B-factor, properdin |
| 332 | M69225 | 198689 | BPAG1 | bullous pemphigoid antigen 1, 230/240 kDa |
| 333 | X63629 | 2877 | CDH3 | cadherin 3, type 1, P-cadherin (placental) |
| 334 | AF134640 | 7235 | CACNG3 | calcium channel, voltage-dependent, gamma |
| | | | | subunit 3 |
| 335 | M94345 | 82422 | CAPG | capping protein (actin filament), gelsolin-like |
| 336 | AF035752 | 139851 | CAV2 | caveolin 2 |
| 337 | K01144 | 84298 | CD74 | CD74 antigen |
| 338 | AI750036 | 22116 | CDC14B | CDC14 cell division cycle 14 homolog B (S. cerevisiae) |
| 339 | NM_002996 | 80420 | CX3CL1 | chemokine (C-X3-C motif) ligand 1 |
| 340 | AF000959 | 110903 | CLDN5 | claudin 5 (transmembrane protein deleted in |
| | | | | velocardiofacial syndrome) |
| 341 | NM_001831 | 75106 | CLU | clusterin (SP-40, 40, sulfated glycoprotein 2, |
| | | | | testosterone-repressed prostate message 2) |
| 342 | NM_001733 | 1279 | C1R | complement component 1, r subcomponent |
| 343 | K02765 | 284394 | C3 | complement component 3 |
| 344 | D13639 | 75586 | CCND2 | cyclin D2 |
| 345 | BF183952 | 412999 | CSTA | cystatin A (stefin A) |
| 346 | M62401 | 82568 | CYP27A1 | cytochrome P450, family 27, subfamily A, |
| | | | | polypeptide 1 |
| 347 | J04813 | 104117 | CYP3A5 | cytochrome P450, family 3, subfamily A, |
| | | | | polypeptide 5 |
| 348 | X90579 | 166079 | CYP3A5P2 | cytochrome P450, family 3, subfamily A, |
| | | | | polypeptide 5 pseudogene 2 |
| 349 | AW956111 | 79404 | D4S234E | DNA segment on chromosome 4 (unique) 234 |
| | | | | expressed sequence |
| 350 | AB012955 | 129867 | KIP2 | DNA-dependent protein kinase catalytic subunit- |
| | | | | interacting protein 2 |
| 351 | D83407 | 156007 | DSCR1L1 | Down syndrome critical region gene 1-like 1 |
| 352 | L11329 | 1183 | DUSP2 | dual specificity phosphatase 2 |
| 353 | NM_001421 | 151139 | ELF4 | E74-like factor 4 (ets domain transcription factor) |
| 354 | AW300770 | 61265 | FAM3D | family with sequence similarity 3, member D |
| 355 | D84239 | 111732 | FCGBP | Fc fragment of IgG binding protein |
| 356 | AF182316 | 234680 | FER1L3 | fer-1-like 3, myoferlin (C. elegans) |
| 357 | M87770 | 278581 | FGFR2 | fibroblast growth factor receptor 2 |
| 358 | NM_001456 | 195464 | FLNA | filamin A, alpha (actin binding protein 280) |
| 359 | L42176 | 8302 | FHL2 | four and a half LIM domains 2 |
| 360 | NM_000165 | 74471 | GJA1 | gap junction protein, alpha 1, 43 kDa (connexin |
| | | | | 43) |
| 361 | AW949747 | 169946 | GATA3 | GATA binding protein 3 |
| 362 | NM_002083 | 2704 | GPX2 | glutathione peroxidase 2 (gastrointestinal) |
| 363 | NM_002084 | 386793 | GPX3 | glutathione peroxidase 3 (plasma) |
| 364 | AA290738 | 301961 | GSTM1 | glutathione S-transferase M1 |
| 365 | NM_002081 | 2699 | GPC1 | glypican 1 |
| 366 | M55543 | 171862 | GBP2 | guanylate binding protein 2, interferon-inducible |
| 367 | AA666119 | 92287 | GBP3 | guanylate binding protein 3 |
| 368 | NM_000186 | 250651 | HF1 | H factor 1 (complement) |
| 369 | AA490691 | 421136 | HOXD11 | homeo box D11 |
| 370 | J02770 | 36602 | IF | I factor (complement) |
| 371 | S81914 | 76095 | IER3 | immediate early response 3 |
| 372 | AV646610 | 34853 | ID4 | inhibitor of DNA binding 4, dominant negative |
| | | | | helix-loop-helix protein |
| 373 | L08488 | 32309 | INPP1 | inositol polyphosphate-1-phosphatase |
| 374 | M31159 | 77326 | IGFBP3 | insulin-like growth factor binding protein 3 |
| 375 | M59911 | 265829 | ITGA3 | integrin, alpha 3 (antigen CD49C, alpha 3 subunit |
| | | | | of VLA-3 receptor) |
| 376 | X52186 | 85266 | ITGB4 | integrin, beta 4 |
| 377 | AF020201 | 166154 | JAG2 | jagged 2 |
| 378 | X14640 | 74070 | KRT13 | keratin 13 |
| 379 | X07696 | 80342 | KRT15 | keratin 15 |
| 380 | M21389 | 433845 | KRT5 | keratin 5 (epidermolysis bullosa simplex, |
| | | | | Dowling-Meara/Kobner/Weber-Cockayne types) |
| 381 | X03212 | 23881 | KRT7 | keratin 7 |
| 382 | AF287272 | 84728 | KLF5 | Kruppel-like factor 5 (intestinal) |
| 383 | Y00711 | 234489 | LDHB | lactate dehydrogenase B |
| 384 | U07643 | 105938 | LTF | lactotransferrin |
| 385 | M13452 | 377973 | LMNA | lamin A/C |
| 386 | D37766 | 75517 | LAMB3 | laminin, beta 3 |
| 387 | L13210 | 79339 | LGALS3BP | lectin, galactoside-binding, soluble, 3 binding |
| | | | | protein |
| 388 | AF002672 | 152944 | LOH11CR2A | loss of heterozygosity, 11, chromosomal region 2, |
| | | | | gene A |
| 389 | BE621666 | 296398 | LAPTM4B | lysosomal associated protein transmembrane 4 |
| | | | | beta |
| 390 | L08895 | 78995 | MEF2C | MADS box transcription enhancer factor 2, |
| | | | | polypeptide C (myocyte enhancer factor 2C) |
| 391 | AA779709 | 7457 | MAGE-E1 | MAGE-E1 protein |
| 392 | M33906 | 198253 | HLA-DQA1 | major histocompatibility complex, class II, DQ |
| | | | | alpha 1 |
| 393 | AW298180 | 2256 | MMP7 | matrix metalloproteinase 7 (matrilysin, uterine) |
| 394 | AF017418 | 104105 | MEIS2 | Meis1, myeloid ecotropic viral integration site 1 |
| | | | | homolog 2 (mouse) |
| 395 | J02854 | 9615 | MYL9 | myosin, light polypeptide 9, regulatory |
| 396 | AF203032 | 198760 | NEFH | neurofilament, heavy polypeptide 200 kDa |
| 397 | M12267 | 75485 | OAT | ornithine aminotransferase (gyrate atrophy) |
| 398 | U90878 | 75807 | PDLIM1 | PDZ and LIM domain 1 (elfin) |
| 399 | M22430 | 76422 | PLA2G2A | phospholipase A2, group IIA (platelets, synovial |
| | | | | fluid) |
| 400 | D00244 | 77274 | PLAU | plasminogen activator, urokinase |
| 401 | AL045876 | 430637 | PTGDS | prostaglandin D2 synthase 21 kDa (brain) |
| 402 | AF043498 | 423634 | PSCA | prostate stem cell antigen |
| 403 | NM_006394 | 278503 | RIG | regulated in glioma |
| 404 | NM_003979 | 194691 | RAI3 | retinoic acid induced 3 |
| 405 | AA173755 | 301198 | ROBO1 | roundabout, axon guidance receptor, homolog 1 |
| | | | | (Drosophila) |
| 406 | AW965789 | 66450 | SENP1 | sentrin/SUMO-specific protease |
| 407 | M93056 | 183583 | SERPINB1 | serine (or cysteine) proteinase inhibitor, clade B |
| | | | | (ovalbumin), member 1 |
| 408 | M13690 | 151242 | SERPING1 | serine (or cysteine) proteinase inhibitor, clade G |
| | | | | (C1 inhibitor), member 1 |
| 409 | W73992 | 132792 | SDCCAG43 | serologically defined colon cancer antigen 43 |
| 410 | X51441 | 332053 | SAA1 | serum amyloid A1 |
| 411 | NM_006456 | 288215 | STHM | sialyltransferase |
| 412 | AF215636 | 5944 | SLC11A3 | solute carrier family 11 (proton-coupled divalent |
| | | | | metal ion transporters), member 3 |
| 413 | U59299 | 90911 | SLC16A5 | solute carrier family 16 (monocarboxylic acid |
| | | | | transporters), member 5 |
| 414 | M55531 | 33084 | SLC2A5 | solute carrier family 2 (facilitated |
| | | | | glucose/fructose transporter), member 5 |
| 415 | M81635 | 160483 | STOM | stomatin |
| 416 | BF514189 | 345728 | SOCS3 | suppressor of cytokine signaling 3 |
| 417 | AI423028 | 71622 | SMARCD3 | SWI/SNF related, matrix associated, actin |
| | | | | dependent regulator of chromatin, subfamily d, |
| | | | | member 3 |
| 418 | AK001617 | 24948 | SNCAIP | synuclein, alpha interacting protein (synphilin) |
| 419 | U21847 | 82173 | TIEG | TGFB inducible early growth response |
| 420 | M12670 | 5831 | TIMP1 | tissue inhibitor of metalloproteinase 1 (erythroid |
| | | | | potentiating activity, collagenase inhibitor) |
| 421 | U54831 | 75248 | TOP2B | topoisomerase (DNA) II beta 180 kDa |
| 422 | NM_003241 | 2387 | TGM4 | transglutaminase 4 (prostate) |
| 423 | W72411 | 137569 | TP73L | tumor protein p73-like |
| 424 | D88154 | 103665 | VILL | villin-like |
| 425 | X63187 | 2719 | WFDC2 | WAP four-disulfide core domain 2 |
| 426 | AF122922 | 284122 | WIF1 | WNT inhibitory factor 1 |
| 427 | AA916688 | 85155 | ZFP36L1 | zinc finger protein 36, C3H type-like 1 |
| 428 | BF055342 | 326801 | ZNF6 | zinc finger protein 6 (CMPX1) |

function unknown

| | | | | |
|---|---|---|---|---|
| 429 | AA706316 | 32343 | ZD52F10 | hypothetical gene ZD52F10 |
| 430 | U57961 | 181304 | 13CDNA73 | hypothetical protein CG003 |
| 431 | AA709155 | 104800 | FLJ10134 | hypothetical protein FLJ10134 |
| 432 | AK001021 | 22505 | FLJ10159 | hypothetical protein FLJ10159 |
| 433 | AA180145 | 351270 | LOC152485 | hypothetical protein LOC152485 |
| 434 | AA133590 | 377830 | MGC44669 | hypothetical protein MGC44669 |
| 435 | NM_014766 | 75137 | KIAA0193 | KIAA0193 gene product |
| 436 | AI741882 | 278436 | KIAA1474 | KIAA1474 protein |
| 437 | BF431643 | 15420 | KIAA1500 | KIAA1500 protein |
| 438 | N62352 | 24790 | KIAA1573 | KIAA1573 protein |
| 439 | T78873 | 9587 | KIAA2002 | KIAA2002 protein |
| 440 | AK022877 | 49476 | | Homo sapiens cDNA FLJ12815 fis, clone |
| | | | | NT2RP2002546. |
| 441 | AI566720 | 380045 | | Homo sapiens cDNA FLJ34528 fis, clone |
| | | | | HLUNG2008066. |
| 442 | BE885999 | 397414 | | Homo sapiens cDNA: FLJ20860 fis, clone |
| | | | | ADKA01632. |
| 443 | AK025909 | 288741 | | Homo sapiens cDNA: FLJ22256 fis, clone |
| | | | | HRC02860. |
| 444 | AI269367 | 101307 | | Homo sapiens HUT11 protein mRNA, partial 3′ |
| | | | | UTR |
| 445 | AL050204 | 28540 | | Homo sapiens mRNA; cDNA DKFZp586F1223 |
| | | | | (from clone DKFZp586F1223) |
| 446 | AV733210 | 367688 | | Homo sapiens, clone IMAGE: 4794726, mRNA |
| 447 | AI027791 | 132296 | | ESTs |
| 448 | BF111819 | 21470 | | ESTs |
| 449 | AA632025 | 444752 | | ESTs |
| 450 | BE868254 | 380149 | | ESTs |
| 451 | AW510657 | 156044 | | ESTs |
| 452 | AA620628 | 186486 | | ESTs |
| 453 | AI769569 | 112472 | | ESTs |
| 454 | T79422 | 119237 | | ESTs |
| 455 | AI052358 | 131741 | | ESTs |
| 456 | N95414 | 55168 | | ESTs, Weakly similar to neuronal thread protein |
| | | | | [Homo sapiens] [H. sapiens] |
| 457 | BG163478 | 405950 | | ESTs, Weakly similar to BAI1_HUMAN Brain- |
| | | | | specific angiogenesis inhibitor 1 precursor |
| | | | | [H. sapiens] |

TABLE 7
Up-regulated genes in 10 PINs

| | | | | |
|---|---|---|---|---|
| PRC Assignment | Accession No | Hs. | Symbol | Title |

function known

| | | | | |
|---|---|---|---|---|
| 458 | BE466450 | 50628 | AP4S1 | adaptor-related protein complex 4, sigma 1 |
| | | | | subunit |
| 459 | AW612403 | 293970 | ALDH6A1 | aldehyde dehydrogenase 6 family, member A1 |
| 460 | AJ130733 | 128749 | AMACR | alpha-methylacyl-CoA racemase |
| 461 | NM_001642 | 279518 | APLP2 | amyloid beta (A4) precursor-like protein 2 |
| 462 | X59066 | 405985 | ATP5A1 | ATP synthase, H+ transporting, mitochondrial F1 |
| | | | | complex, alpha subunit, isoform 1 |
| 463 | AF071202 | 139336 | ABCC4 | ATP-binding cassette, sub-family C |
| | | | | (CFTR/MRP), member 4 |
| 464 | AB019038 | 44592 | HMT-1 | beta-1,4 mannosyltransferase |
| 465 | AF231023 | 55173 | CELSR3 | cadherin, EGF LAG seven-pass G-type receptor 3 |
| | | | | (flamingo homolog, Drosophila) |
| 466 | AI817172 | 29423 | COLEC12 | collectin sub-family member 12 |
| 467 | Z21488 | 143434 | CNTN1 | contactin 1 |
| 468 | AF255443 | 268281 | CRNKL1 | Crn, crooked neck-like 1 (Drosophila) |
| 469 | NM_005436 | 288862 | D10S170 | DNA segment on chromosome 10 (unique) 170 |
| 470 | AI697792 | 21189 | DNAJA2 | DnaJ (Hsp40) homolog, subfamily A, member 2 |
| 471 | AF039918 | 80975 | ENTPD5 | ectonucleoside triphosphate diphosphohydrolase 5 |
| 472 | AF176699 | 49526 | FBXL4 | F-box and leucine-rich repeat protein 4 |
| 473 | M99487 | 1915 | FOLH1 | folate hydrolase (prostate-specific membrane |
| | | | | antigen) 1 |
| 474 | NM_000159 | 184141 | GCDH | glutaryl-Coenzyme A dehydrogenase |
| 475 | AW967035 | 159572 | HS3ST3B1 | heparan sulfate (glucosamine) 3-O- |
| | | | | sulfotransferase 3B1 |
| 476 | NM_005333 | 211571 | HCCS | holocytochrome c synthase (cytochrome c hemelyase) |
| 477 | U26726 | 1376 | HSD11B2 | hydroxysteroid (11-beta) dehydrogenase 2 |
| 478 | U89281 | 11958 | RODH | 3-hydroxysteroid epimerase |
| 479 | U42408 | 18141 | LAD1 | ladinin 1 |
| 480 | L25931 | 152931 | LBR | lamin B receptor |
| 481 | Z30137 | 49998 | LDB3 | LIM domain binding 3 |
| 482 | AF001174 | 57732 | MAPK11 | mitogen-activated protein kinase 11 |
| 483 | M92449 | 264330 | ASAHL | N-acylsphingosine amidohydrolase (acid |
| | | | | ceramidase)-like |
| 484 | W23499 | 118654 | ASAH2 | N-acylsphingosine amidohydrolase (non- |
| | | | | lysosomal ceramidase) 2 |
| 485 | R22536 | 220324 | FLJ13052 | NAD kinase |
| 486 | AA704060 | 8248 | NDUFS1 | NADH dehydrogenase (ubiquinone) Fe—S protein |
| | | | | 1, 75 kDa (NADH-coenzyme Q reductase) |
| 487 | AI805082 | 303171 | OR51E2 | olfactory receptor, family 51, subfamily E, |
| | | | | member 2 |
| 488 | AK025460 | 286049 | PSA | phosphoserine aminotransferase |
| 489 | NM_021200 | 380812 | PLEKHB1 | pleckstrin homology domain containing, family B |
| | | | | (evectins) member 1 |
| 490 | AI346354 | 75871 | PRKCBP1 | protein kinase C binding protein 1 |
| 491 | AF044588 | 344037 | PRC1 | protein regulator of cytokinesis 1 |
| 492 | NM_012342 | 78776 | NMA | putative transmembrane protein |
| 493 | AL041152 | 13264 | RC3 | rabconnectin-3 |
| 494 | L10333 | 99947 | RTN1 | reticulon 1 |
| 495 | M32313 | 552 | SRD5A1 | steroid-5-alpha-reductase, alpha polypeptide 1 |
| 496 | U04735 | 352341 | STCH | stress 70 protein chaperone, microsome- |
| | | | | associated, 60 kDa |
| 497 | U66035 | 125565 | TIMM8A | translocase of inner mitochondrial membrane 8 |
| | | | | homolog A (yeast) |
| 498 | AA907673 | 432605 | UGCG | UDP-glucose ceramide glucosyltransferase |
| 499 | AA164237 | 279840 | ZNF222 | zinc finger protein 222 |
| 500 | NM_006300 | 193583 | ZNF230 | zinc finger protein 230 |

function unknown

| | | | | |
|---|---|---|---|---|
| 501 | AK023414 | 22972 | FLJ13352 | hypothetical protein FLJ13352 |
| 502 | AI341472 | 274337 | FLJ20666 | hypothetical protein FLJ20666 |
| 503 | N48613 | 311163 | FLJ30162 | hypothetical protein FLJ30162 |
| 504 | BG179141 | 7962 | FLJ30525 | hypothetical protein FLJ30525 |
| 505 | AW971484 | 105069 | LOC148418 | hypothetical protein LOC148418 |
| 506 | AK000569 | 107444 | LOC90075 | hypothetical protein LOC90075 |
| 507 | D43948 | 76989 | KIAA0097 | KIAA0097 gene product |
| 508 | AB011085 | 301658 | KIAA0513 | KIAA0513 gene product |
| 509 | AB011127 | 43107 | KIAA0555 | KIAA0555 gene product |
| 510 | AI151160 | 155983 | KIAA0677 | KIAA0677 gene product |
| 511 | T55178 | 9846 | KIAA1040 | KIAA1040 protein |
| 512 | AI094513 | 21896 | KIAA1136 | KIAA1136 protein |
| 513 | AA206763 | 7991 | C20orf102 | chromosome 20 open reading frame 102 |
| 514 | AF131828 | 7961 | C9orf25 | chromosome 9 open reading frame 25 |
| 515 | AA825819 | 7535 | LOC55871 | LOC55871 |
| 516 | AW135763 | 6375 | HT010 | uncharacterized hypothalamus protein HT010 |
| 517 | AK025329 | 7158 | | DKFZP566H073 protein |
| 518 | AL390127 | 433788 | | Homo sapiens mRNA; cDNA DKFZp761P06121 |
| 519 | AI074176 | 31535 | | Homo sapiens, clone IMAGE: 3460742, mRNA, |
| | | | | partial cds |
| 520 | AI133467 | 95612 | | ESTs |
| 521 | BF514823 | 119065 | | ESTs |
| 522 | AA897408 | 190065 | | ESTs |
| 523 | AI478401 | 104591 | | ESTs |
| 524 | AA430571 | 104881 | | ESTs |
| 525 | AA521342 | 101428 | | ESTs |
| 526 | N62332 | 102728 | | ESTs |
| 527 | H17800 | 438858 | | ESTs |
| 528 | AA826048 | 117887 | | ESTs |
| 529 | AA677094 | 117035 | | ESTs |
| 530 | AA682521 | 117261 | | ESTs |
| 531 | AI554006 | 112694 | | ESTs |
| 532 | AI004966 | 445098 | | ESTs |
| 533 | N52767 | 23406 | | EST |
| 534 | BF109251 | 353121 | | ESTs, Weakly similar to hypothetical protein |
| | | | | FLJ20378 |
| 535 | AI700341 | 110406 | | ESTs, Weakly similar to hypothetical protein |
| | | | | FLJ20489 |
| 536 | AA743154 | 373991 | | ESTs, Weakly similar to neuronal thread protein |
| 537 | AI352507 | 263600 | | ESTs, Weakly similar to RL17_HUMAN 60S |
| | | | | ribosomal protein L17 (L23) |

TABLE 8
Down-regulated Genes in 10 PINs

| | | | | |
|---|---|---|---|---|
| PRC | Accession | | | |
| Assignment | No | Hs. | Symbol | Title |

function known

| | | | | |
|---|---|---|---|---|
| 538 | K03000 | 76392 | ALDH1A1 | aldehyde dehydrogenase 1 family, member A1 |
| 539 | AF055024 | 153489 | ASB1 | ankyrin repeat and SOCS box-containing 1 |
| 540 | M81844 | 87268 | ANXA8 | annexin A8 |
| 541 | X82206 | 153961 | ACTR1A | ARP1 actin-related protein 1 homolog A, |
| | | | | centractin alpha (yeast) |
| 542 | AW014316 | 1578 | BIRC5 | baculoviral IAP repeat-containing 5 (survivin) |
| 543 | S67310 | 69771 | BF | B-factor, properdin |
| 544 | AF132972 | 279772 | CGI-38 | brain specific protein |
| 545 | BE826171 | 100686 | BCMP11 | breast cancer membrane protein 11 |
| 546 | AF134640 | 7235 | CACNG3 | calcium channel, voltage-dependent, gamma |
| | | | | subunit 3 |
| 547 | AF177775 | 76688 | CES1 | carboxylesterase 1 (monocyte/macrophage serine |
| | | | | esterase 1) |
| 548 | Z18951 | 74034 | CAV1 | caveolin 1, caveolae protein, 22 kDa |
| 549 | K01144 | 84298 | CD74 | CD74 antigen |
| 550 | NM_002996 | 80420 | CX3CL1 | chemokine (C-X3-C motif) ligand 1 |
| 551 | U58514 | 154138 | CHI3L2 | chitinase 3-like 2 |
| 552 | W19536 | 363572 | CEPT1 | choline/ethanolaminephosphotransferase |
| 553 | U16306 | 81800 | CSPG2 | chondroitin sulfate proteoglycan 2 (versican) |
| 554 | AF101051 | 7327 | CLDN1 | claudin 1 |
| 555 | AI150272 | 258811 | COPG2 | coatomer protein complex, subunit gamma 2 |
| 556 | AV712344 | 285401 | CSF2RB | colony stimulating factor 2 receptor, beta, low- |
| | | | | affinity (granulocyte-macrophage) |
| 557 | NM_001733 | 1279 | C1R | complement component 1, r subcomponent |
| 558 | K02765 | 284394 | C3 | complement component 3 |
| 559 | AF081287 | 4076 | CTDP1 | CTD (carboxy-terminal domain, RNA |
| | | | | polymerase II, polypeptide A) phosphatase, |
| | | | | subunit 1 |
| 560 | L12579 | 147049 | CUTL1 | cut-like 1, CCAAT displacement protein |
| | | | | (Drosophila) |
| 561 | D86977 | 78054 | DDX38 | DEAD/H (Asp-Glu-Ala-Asp/His) box |
| | | | | polypeptide 38 |
| 562 | M26602 | 274463 | DEFA1 | defensin, alpha 1, myeloid-related sequence |
| 563 | AF097021 | 273321 | GW112 | differentially expressed in hematopoietic lineages |
| 564 | NM_006182 | 71891 | DDR2 | discoidin domain receptor family, member 2 |
| 565 | NM_001953 | 73946 | ECGF1 | endothelial cell growth factor 1 (platelet-derived) |
| 566 | BF981201 | 408061 | FABP5 | fatty acid binding protein 5 (psoriasis-associated) |
| 567 | AF112152 | 11494 | FBLN5 | fibulin 5 |
| 568 | U60115 | 239069 | FHL1 | four and a half LIM domains 1 |
| 569 | NM_002083 | 2704 | GPX2 | glutathione peroxidase 2 (gastrointestinal) |
| 570 | NM_002084 | 386793 | GPX3 | glutathione peroxidase 3 (plasma) |
| 571 | NM_002081 | 2699 | GPC1 | glypican 1 |
| 572 | AI887814 | 4953 | GOLGA3 | golgi autoantigen, golgin subfamily a, 3 |
| 573 | D21239 | 9195 | GRF2 | guanine nucleotide-releasing factor 2 (specific for |
| | | | | crk proto-oncogene) |
| 574 | NM_006308 | 41707 | HSPB3 | heat shock 27 kDa protein 3 |
| 575 | AK001601 | 69594 | HMG20A | high-mobility group 20A |
| 576 | J02770 | 36602 | IF | I factor (complement) |
| 577 | S81914 | 76095 | IER3 | immediate early response 3 |
| 578 | AI922295 | 413826 | IGHG3 | immunoglobulin heavy constant gamma 3 (G3m |
| | | | | marker) |
| 579 | X67301 | 153261 | IGHM | immunoglobulin heavy constant mu |
| 580 | AW518944 | 76325 | IGJ | immunoglobulin J polypeptide, linker protein for |
| | | | | immunoglobulin alpha and mu polypeptides |
| 581 | AK026991 | 61790 | IPO4 | importin 4 |
| 582 | M31159 | 77326 | IGFBP3 | insulin-like growth factor binding protein 3 |
| 583 | AK026736 | 57664 | ITGB6 | integrin, beta 6 |
| 584 | NM_002198 | 80645 | IRF1 | interferon regulatory factor 1 |
| 585 | U72882 | 50842 | IFI35 | interferon-induced protein 35 |
| 586 | M13143 | 1901 | KLKB1 | kallikrein B, plasma (Fletcher factor) 1 |
| 587 | U07643 | 105938 | LTF | lactotransferrin |
| 588 | AF025534 | 77062 | LILRB5 | leukocyte immunoglobulin-like receptor, |
| | | | | subfamily B (with TM and ITIM domains), |
| | | | | member 5 |
| 589 | AI563896 | 1569 | LHX2 | LIM homeobox protein 2 |
| 590 | AA644276 | 102267 | LOX | lysyl oxidase |
| 591 | M81141 | 73931 | HLA-DQB1 | major histocompatibility complex, class II, DQ |
| | | | | beta 1 |
| 592 | BF697545 | 365706 | MGP | matrix Gla protein |
| 593 | NM_004530 | 111301 | MMP2 | matrix metalloproteinase 2 (gelatinase A) |
| 594 | AW298180 | 2256 | MMP7 | matrix metalloproteinase 7 (matrilysin) |
| 595 | NM_005928 | 3745 | MFGE8 | milk fat globule-EGF factor 8 protein |
| 596 | AI023878 | 406591 | MTIF3 | mitochondrial translational initiation factor 3 |
| 597 | J05581 | 89603 | MUC1 | mucin 1, transmembrane |
| 598 | M94132 | 315 | MUC2 | mucin 2, intestinal/tracheal |
| 599 | AJ293659 | 12909 | MCOLN1 | mucolipin 1 |
| 600 | J02854 | 9615 | MYL9 | myosin, light polypeptide 9, regulatory |
| 601 | AB037787 | 26229 | NLGN2 | neuroligin 2 |
| 602 | NM_006169 | 364345 | NNMT | nicotinamide N-methyltransferase |
| 603 | S51033 | 79396 | MPG | N-methylpurine-DNA glycosylase |
| 604 | N35034 | 8121 | NOTCH2 | Notch homolog 2 (Drosophila) |
| 605 | NM_006163 | 75643 | NFE2 | nuclear factor (erythroid-derived 2), 45 kDa |
| 606 | AW949776 | 3187 | NFX1 | nuclear transcription factor, X-box binding 1 |
| 607 | M13692 | 572 | ORM1 | orosomucoid 1 |
| 608 | BF115519 | 14125 | PA26 | p53 regulated PA26 nuclear protein |
| 609 | L03203 | 103724 | PMP22 | peripheral myelin protein 22 |
| 610 | AA398096 | 198278 | PFKFB4 | 6-phosphofructo-2-kinase/fructose-2,6- |
| | | | | biphosphatase 4 |
| 611 | AI660921 | 107125 | PLVAP | plasmalemma vesicle associated protein |
| 612 | D29833 | 2207 | PROL3 | proline rich 3 |
| 613 | N26005 | 303090 | PPP1R3C | protein phosphatase 1, regulatory (inhibitor) |
| | | | | subunit 3C |
| 614 | BF673741 | 71119 | N33 | Putative prostate cancer tumor suppressor |
| 615 | AI004873 | 198281 | PKM2 | pyruvate kinase, muscle |
| 616 | H46145 | 27744 | RAB3A | RAB3A, member RAS oncogene family |
| 617 | AK026092 | 180040 | RIN3 | Ras and Rab interactor 3 |
| 618 | BG054844 | 6838 | ARHE | ras homolog gene family, member E |
| 619 | NM_003979 | 194691 | RAI3 | retinoic acid induced 3 |
| 620 | AA927661 | 201675 | RBM5 | RNA binding motif protein 5 |
| 621 | BF027943 | 2962 | S100P | S100 calcium binding protein P |
| 622 | AI719545 | 278431 | SCO2 | SCO cytochrome oxidase deficient homolog 2 |
| | | | | (yeast) |
| 623 | X16150 | 82848 | SELL | selectin L (lymphocyte adhesion molecule 1) |
| 624 | J05176 | 234726 | SERPINA3 | serine (or cysteine) proteinase inhibitor, clade A, |
| | | | | member 3 |
| 625 | BF126636 | 332053 | SAA1 | serum amyloid A1 |
| 626 | NM_004175 | 1575 | SNRPD3 | small nuclear ribonucleoprotein D3 polypeptide |
| | | | | 18 kDa |
| 627 | AF036109 | 193665 | SLC28A2 | solute carrier family 28 (sodium-coupled |
| | | | | nucleoside transporter), member 2 |
| 628 | AF058918 | 5699 | SEDLP | spondyloepiphyseal dysplasia, late, pseudogene |
| 629 | NM_000348 | 1989 | SRD5A2 | steroid-5-alpha-reductase, alpha polypeptide 2 |
| 630 | AF059203 | 20580 | SOAT2 | sterol O-acyltransferase 2 |
| 631 | AA853967 | 124574 | TAS1R1 | taste receptor, type 1, member 1 |
| 632 | AF082185 | 8375 | TRAF4 | TNF receptor-associated factor 4 |
| 633 | AI091425 | 9030 | TONDU | TONDU |
| 634 | AA682533 | 44269 | TRIPIN | tripin |
| 635 | AB025254 | 283761 | PCTAIRE2BP | tudor repeat associator with PCTAIRE 2 |
| 636 | D17517 | 301 | TYRO3 | TYRO3 protein tyrosine kinase |
| 637 | AF000993 | 13980 | UTX | ubiquitously transcribed tetratricopeptide repeat |
| | | | | gene, X chromosome |
| 638 | AW574558 | 121102 | VNN2 | vanin2 |
| 639 | H20162 | 2126 | VIPR2 | vasoactive intestinal peptide receptor 2 |
| 640 | BE382636 | 25960 | MYCN | v-myc myelocytomatosis viral related oncogene, |
| | | | | neuroblastoma derived (avian) |
| 641 | X63187 | 2719 | WFDC2 | WAP four-disulfide core domain 2 |

function unknown

| | | | | |
|---|---|---|---|---|
| 642 | AI042017 | 23756 | C1orf13 | chromosome 1 open reading frame 13 |
| 643 | AA614050 | 267566 | C14orf58 | chromosome 14 open reading frame 58 |
| 644 | AK023453 | 334721 | FLJ13391 | hypothetical protein FLJ13391 |
| 645 | BE465676 | 353196 | FLJ14564 | hypothetical protein FLJ14564 |
| 646 | AK026924 | 105642 | FLJ21936 | hypothetical protein FLJ21936 |
| 647 | AW195243 | 108812 | FLJ22004 | hypothetical protein FLJ22004 |
| 648 | BF965831 | 135121 | FLJ22415 | hypothetical protein FLJ22415 |
| 649 | AK026486 | 118183 | FLJ22833 | hypothetical protein FLJ22833 |
| 650 | AW271223 | 5890 | FLJ23306 | hypothetical protein FLJ23306 |
| 651 | AI359551 | 22015 | FLJ90119 | hypothetical protein FLJ90119 |
| 652 | BG054529 | 206501 | LOC57228 | hypothetical protein from clone 643 |
| 653 | AI149729 | 120557 | LOC285286 | hypothetical protein LOC285286 |
| 654 | AI089621 | 22051 | MGC15548 | hypothetical protein MGC15548 |
| 655 | AW005320 | 236547 | MGC22916 | hypothetical protein MGC22916 |
| 656 | AI076840 | 40808 | MGC33926 | hypothetical protein MGC33926 |
| 657 | AW340131 | 56382 | FLJ32384 | hypothetical protein MGC39389 |
| 658 | AK025996 | 209614 | MGC4415 | hypothetical protein MGC4415 |
| 659 | AA827188 | 351605 | MGC45417 | hypothetical protein MGC45417 |
| 660 | H04833 | 6336 | KIAA0672 | KIAA0672 product |
| 661 | AB033103 | 6385 | KIAA1277 | KIAA1277 protein |
| 662 | BG054798 | 26204 | KIAA1295 | KIAA1295 protein |
| 663 | AI694131 | 29002 | KIAA1706 | KIAA1706 protein |
| 664 | AL137345 | 298850 | KIAA1936 | KIAA1936 protein |
| 665 | AK025585 | 380169 | | DKFZp727A071 |
| 666 | AB037861 | 112184 | | DKFZP586J0619 protein |
| 667 | W58516 | 12396 | | Homo sapiens cDNA FLJ33095 fis, clone |
| | | | | TRACH2000708. |
| 668 | AW967916 | 31944 | | Homo sapiens cDNA FLJ33236 fis, clone |
| | | | | ASTRO2002571. |
| 669 | AF052090 | 106620 | | Homo sapiens clone 23950 mRNA sequence |
| 670 | AL110236 | 321022 | | Homo sapiens mRNA; cDNA DKFZp566P1124 |
| | | | | (from clone DKFZp566P1124) |
| 671 | BE348293 | 29283 | | Homo sapiens proteoglycan link protein mRNA, |
| | | | | complete cds. |
| 672 | AI139601 | 120590 | | Homo sapiens, clone IMAGE: 5750475, mRNA |
| 673 | H42381 | 348805 | | hypothetical protein DKFZp667B0210 |
| 674 | AA180005 | 115029 | | ESTs |
| 675 | AA648546 | 230703 | | ESTs |
| 676 | AI916303 | 7444 | | ESTs |
| 677 | AA700898 | 113117 | | ESTs |
| 678 | AI246644 | 259679 | | ESTs |
| 679 | AI807279 | 443735 | | ESTs |
| 680 | AI160304 | 28313 | | ESTs |
| 681 | AA768888 | 446195 | | ESTs |
| 682 | BE502928 | 445376 | | ESTs |
| 683 | AA568515 | 293510 | | ESTs |
| 684 | AI732560 | 215976 | | ESTs |
| 685 | AI821961 | 126215 | | ESTs |
| 686 | AA928743 | 132527 | | ESTs |
| 687 | AA910771 | 130421 | | ESTs |
| 688 | AA938326 | 127167 | | ESTs |
| 689 | AA897581 | 445725 | | ESTs |
| 690 | AA004313 | 446619 | | ESTs, Highly similar to HIRA-interacting protein 3 |
| 691 | H21968 | 285520 | | ESTs, Moderately similar to hypothetical protein |
| | | | | FLJ20489 |
| 692 | AI223250 | 131365 | | ESTs, Weakly similar to T31613 hypothetical |
| | | | | protein Y50E8A.i - Caenorhabditis elegans] |

TABLE 2
Primer sequences for semi-quantitative RT-PCR experiments

| | | SEQ.ID. | | SEQ.ID. |
|---|---|---|---|---|
| Symbol | Forward primer | NO. | Reverse primer | NO. |
| AMACR | 5′-TCATGATCTCCCTCT | 22 | 5′-TGTTGCTGTGTGTTGGGTA | 23 |
| | AAGCACAT-3′ | | TAAG-3′ | |
| HOXC6 | 5′-CCTGGGGGTCATTA | 24 | 5′-TTCTCCTACTGGCTAAACA | 25 |
| | TGGCATTTT-3′ | | AACG-3′ | |
| POV1 | 5′-GGTGCCTCTTATCTC | 26 | 5′-CTTCCCTTTTTATTTC | 27 |
| | CTTCT-3′ | | CTCT-3′ | |
| ALBHD2 | 5′-GTACTTGGCTTAAA | 28 | 5′-CTCAGTGACCTGGATCTG | 29 |
| | AGCAACCAG-3′ | | ACCT-3′ | |
| C20ORF1 | 5′-AACCACTTCTTGCG | 30 | 5′-TATTCAGGTTGGCTGGTA | 31 |
| 02 | AGTCCTT-3′ | | GTCAC-3′ | |
| β-actin | 5′-TTGGCTTGACTCAG | 32 | 5′-TGGACTTGGGAGAGGA | 33 |
| | GATTTA-3′ | | CTGG-3′ | |

### Example 3

Identification of a Novel Gene, CCDC4 (Coiled-Coil Domain Containing 4).

By our genome-wide cDNA microarray, the present inventoers identified one up-regulated spot, housing-name B3537, which represented one EST (Homo sapiens cDNA FLJ35632). Combined the information of other ESTs with the sequence obtained by RACE using prostate cancer cDNA, we identified a novel gene, CCDC4.

Northern-Blot Analysis.

Human multiple-tissue Northern blots (Clontech, Palo Alto, Calif.) were hybridized with a [α-³²P] dCTP-labeled PCR product of B3537. The 361-bp PCR product was prepared by RT-PCR using primers: 5′-GTGACAAATCCATTGATCCTGA-3′ (SEQ ID NO: 5) and 5′-GAACACGTGGCATTCTAGAGGTA-3′ (SEQ ID NO: 6). Pre-hybridization, hybridization and washing were performed according to the supplier's recommendations. The blots were auto-radiographed with intensifying screens at −80° C. for 7 days.

RT-PCR analysis validated the over-expression of CCDC4 in prostate cancer cells (FIG. 1A). Northern blot analysis (FIG. 1B) demonstrated that this transcript is approximately 8.7 kb and it consisted of 6 exons, which encodes 530 amino-acids protein with coiled-coil domain (Gene Bank Accession number: AB126828) (SEQ ID NO: 2). One alternative splicing form was also identified, which is expected to yield a short isoform 437 amino-acid protein lacking in C-terminal region of the long form (Gene Bank Accession number: AB126829) (SEQ ID NO: 4). This gene is expressed restrictedly in normal testis and prostate as shown in Northern blot analysis (FIG. 1B), indicating that targeting this molecule is expected to yield very little toxicity to normal human organs.

siRNA-Expressing Constructs and Colony Formation/MTT Assay.

The present inventors used siRNA-expression vector (psiU6BX) for RNAi effect to the target genes. The U6 promoter was cloned into the upstream of the gene specific sequence (19 nt sequence from the target transcript separated by a short spacer TTCAAGAGA (SEQ ID NO: 7) from the reverse complement of the same sequence) and five thymidines as a termination signal; furthermore neo cassette was integrated to become resistant to Geneticin (Sigma). The target sequences for CCDC4 are 5′-GATGGTTCTGCAGCACCAC-3′ (SEQ. ID. NO. 8) (si#1), and 5′-GAAGCAGCACGACTTCTTC-3′ (SEQ. ID. NO. 9) (siEGFP) as a negative control.

The oligonucleotides used for CCDC4 siRNA are shown below. si#l was prepared by cloning the following double-stranded oligonucleotide into the Bbsl site of the psiU6BX vector. The corresponding nucleotide position relative to the CCDC4 nucleic acid sequence of SEQ ID NO: 1 or 3 is shown below. The oligionucleotide is a combination of a sense nucleotide sequence and an antisense nucleotide sequence of the target sequence CCDC4. The nucleotide sequence of the hairpin loop structure of si#1 is shown in SEQ ID NO: 10 (endonuclease recognition cites are eliminated from each hairpin loop structure sequence).
si#1 (nucleotide numbers 1666-1684 of SEQ ID No: 1 or 3/SEQ ID NO: 8)
5′-caccgatggt tctgcagcac cacttcaaga gagtggtgct gcagaaccat c-3′ (SEQ ID NO: 11)
5′-aaaagatggt tctgcagcac cactctcttg aagtggtgct gcagaaccat c-3′ (SEQ ID NO: 12)

Prostate cancer cell lines, PC3 and DU145, were plated onto 10-cm dishes (5×105 cells/dish) and transfected with psiU6BX containing EGFP target sequence (EGFP) and psiU6BX containing CCDC4 target sequence using Lipofectamine 2000 (Invitrogen) according to manufacture's instruction. Cells were selected by 500 mg/ml Geneticin for one week, and preliminary cells were harvested 48 hours after transfection and analyzed by RT-PCR to validate knockdown effect on CCDC4. The primers of RT-PCR were the same ones described above. These cells were also stained by Giemsa solution and performed MTT assay to evaluate the colony formation and the cell number, respectively.

RT-PCR validated knockdown effect of CCDC4 mRNA by transfection of siRNA expression vectors si#1, but not by siEGFP. Colony formation assay showed drastic decrease of colony numbers in the cells after transfection with si#1 that were validated to knock down CCDC4 effectively by RT-PCR. MTT assay also showed drastic decreased number of the grown cells transfected with si#1. These findings strongly support that CCDC4 is essential to PRC cell growth and molecular targeting of CCDC4 is a promising approach to develop novel PRC therapy.

Construction of psiU6BX 3.0 Plasmid

The DNA flagment encoding siRNA was inserted into the GAP at nucleotide 485-490 as indicated (−) in the following plasmid sequence (SEQ ID No: 13).

GACGGATCGGGAGATCTCCCGATCCCCTATGGTGCACTCTCAGTACAATC
TGCTCTGGATCCACTAGTAACGGCCGCCAGTGTGCTGGAATTCGGCTTGG
GGATCAGCGTTTGAGTAAGAGCCCGCGTCTGAACCCTCCGCGCCGCCCCG
GCCCCAGTGGAAAGACGCGCAGGCAAAACGCACCACGTGACGGAGCGTGA
CCGCGCCCCGAGCGCCCGCCAAGGTCGGGCAGGAAGAGGGCCTATTTCCC
ATGATTCCTTCATATTTGCATATACGATACAAGGCTGTTAGAGAGATAAT
TAGAATTAATTTGACTGTAAACACAAAGATATTAGTACAAAATACGTGAC
GTAGAAAGTAATAATTTCTTGGGTAGTTTGCAGTTTTAAAATTATGTTTT
AAAATGGACTATCATATGCTTACCGTAACTTGAAAGTATTTCGATTTCTT
GGCTTTATATATCTTGTGGAAAGGACGAAACACC------TTTTTACATC
AGGTTGTTTTTCTGTTTGGTTTTTTTTTTACACCACGTTTATACGCCGGT
GCACGGTTTACCACTGAAAACACCTTTCATCTACAGGTGATATCTTTTAA
CACAAATAAAATGTAGTAGTCCTAGGAGACGGAATAGAAGGAGGTGGGGC
CTAAAGCCGAATTCTGCAGATATCCATCACACTGGCGGCCGCTCGAGTGA
GGCGGAAAGAACCAGCTGGGGCTCTAGGGGGTATCCCCACGCGCCCTGTA
GCGGCGCATTAAGCGCGGCGGGTGTGGTGGTTACGCGCAGCGTGACCGCT
ACACTTGCCAGCGCCCTAGCGCCCGCTCCTTTCGCTTTCTTCCCTTCCTT
TCTCGCCACGTTCGCCGGCTTTCCCCGTCAAGCTCTAAATCGGGGGCTCC
CTTTAGGGTTCCGATTTAGTGCTTTACGGCACCTCGACCCCAAAAAACTT
GATTAGGGTGATGGTTCACGTAGTGGGCCATCGCCCTGATAGACGGTTTT
TCGCCCTTTGACGTTGGAGTCCACGTTCTTTAATAGTGGACTCTTGTTCC
AAACTGGAACAACACTCAACCCTATCTCGGTCTATTCTTTTGATTTATAA
GGGATTTTGCCGATTTCGGCCTATTGGTTAAAAAATGAGCTGATTTAACA
AAAATTTAACGCGAATTAATTCTGTGGAATGTGTGTCAGTTAGGGTGTGG
AAAGTCCCCAGGCTCCCCAGCACGCAGAAGTATGCAAAGCATGCATCTCA
ATTAGTCAGCAACCAGGTGTGGAAAGTCCCCAGGCTCCCCAGCAGGCAGA
AGTATGCAAAGCATCGATCTCAATTAGTCAGCAACCATAGTCCCGCCCCT
AACTCCGCCCATCCCGCCCCTAACTCCGCCCAGTTCCCCCCATTCTCCGC
CCCATGGCTGACTAATTTTTTTTATTTATGCAGAGGCCGAGGCCGCCTCT
GCCTCTGAGCTATTCCAGAAGTAGTGAGGAGGCTTTTTTGGAGGCCTAGG
CTTTTGCAAAAAGCTCCCGGGAGCTTGTATATCCATTTTCGGATCTGATC
AAGAGACAGGATGAGGATCGTTTCGCATGATTGAACAAGATGGATTGCAC
GCAGGTTCTCCGGCCGCTTGGGTGGAGAGGCTATTCGGCTATGACTGGGC
ACAACAGACAATCGGCTGCTCTGATGCCGCCGTGTTCCGGCTGTCAGCGC
AGGGGCGCCCGGTTCTTTTTGTCAAGACCGACCTGTCCGGTGCCCTGAAT
GAACTGCAGGACGAGGCAGCGCGGCTATCGTGGCTGGCCACGACGGGCGT
TCCTTGCGCAGCTGTGCTCGACGTTGTCACTGAAGCGGGAAGGGACTGGC
TGCTATTGGGCGAAGTGCCGGGGCAGGATCTCCTGTCATCTCACCTTGCT
CCTGCCGAGAAAGTATCCATCATGGCTGATGCAATCCGGCGGCTGCATAC
GCTTGATCCGGCTACCTGCCCATTCGACCACCAAGCGAACATCGCATCGA
OCGAGCACGTACTCCGGATGGAAGCCGGTCTTGTCGATCAGGATGATCTG
GACGAAGAGCATCAGGGGCTCGCGCCAGCCGAACTGTTCGCCAGGCTCAA
GGCGCGCATGCCCGACGGCGAGGATCTCGTCGTGACCCATGGCGATGCCT
GCTTGCCGAATATCATGGTGGAAAATGGCCGCTTTTCTGGATTCATCGAC
TGTGGCCGGCTGGGTGTGGCGGACCGCTATCAGGACATAGCGTTGGCTAC
CCGTGATATTGCTGAAGAGCTTGGCGGCGAATGGGCTGACCGCTTCCTCG
TGCTTTACGGTATCGCCGCTCCCGATTCGCAGCGCATCGCCTTCTATCGC
CTTCTTGACGAGTTCTTCTGAGCGGGACTCTGGGGTTCGAAATGACCGAC
CAAGCGACGCCCAACCTGCCATCACGAGATTTCGATTCCACCGCCGCCTT
CTATGAAAGGTTGGGCTTCGGAATCGTTTTCCGGGACGCCGGCTGGATGA
TCCTCCAGCGCGGGGATCTCATGCTGGAGTTCTTCGCCCACCCCAACTTG
TTTATTGCAGCTTATAATGGTTACAAATAAAGCAATAGCATCACAAATTT
CACAAATAAAGCATTTTTTTCACTGCATTCTAGTTGTGGTTTGTCCAAAC
TCATCAATGTATCTTATCATGTCTGTATACCGTCGACCTCTAGCTAGAGC
TTGGCCTAATCATGGTCATAGCTGTTTCCTGTGTGAAATTGTTATCCGCT
CACAATTCCACACAACATACGAGCCGGAAGCATAAAGTGTAAAGCCTGGG
GTGCCTAATGAGTGAGCTAACTCACATTAATTGCGTTGCGCTCACTGCCC
GCTTTCCAGTCGGGAAACCTGTCGTGCCAGCTGCATTAATGAATCGGCCA
ACGCGCGGGGAGAGGCGGTTTGCGTATTGGGCGCTCTTCCGCTTCCTCGC
TCACTGACTCGCTGCGCTCGGTCGTTCGGCTGCGGCGAGCGGTATCAGCT
CACTCAAAGGCGGTAATACGGTTATCCACAGAATCAGGGGATAACGCAGG
AAAGAACATGTGAGCAAAAGGCCAGCAAAAGGCCAGGAACCGTAAAAAGG
CCGCGTTGCTGGCGTTTTTCCATAGGCTCCGCCCCCCTGACGAGCATCAC
AAAAATCGACGCTCAAGTCAGAGGTGGCGAAACCCGACAGGACTATAAAG
ATACCAGGCGTTTCCCCCTGGAAGCTCCCTCGTGCGCTCTCCTGTTCCGA
CCCTGCCGCTTACCGGATACCTGTCCGCCTTTCTCCCTTCGGGAAGCGTG
GCGCTTTCTCATAGCTCACGCTGTAGGTATCTCAGTTCGGTGTAGGTCGT
TCGCTCCAAGCTGGGCTGTGTGCACGAACCCCCCGTTCAGCCCGACCGCT
GCGCCTTATCCGGTAACTATCGTCTTGAGTCCAACCCGGTAAGACACGAC
TTATCGCCACTGGCAGCAGCCACTGGTAACAGGATTAGCAGAGCGAGGTA
TGTAGGCGGTGCTACAGAGTTCTTGAAGTGGTGGCCTAACTACGGCTACA
CTAGAAGAACAGTATTTGGTATCTGCGCTCTGCTGAAGCCAGTTACCTTC
GGAAAAAGAGTTGGTAGCTCTTGATCCGGCAAACAAACCACCGCTGGTAG
CGGTTTTTTTGTTTGCAAGCAGCAGATTACGCGCAGAAAAAAAGGATCTC
AAGAAGATCCTTTGATCTTTTCTACGGGGTCTGACGCTCAGTGGAACGAA
AACTCACGTTAAGGGATTTTGGTCATGAGATTATCAAAAAGGATCTTCAC
CTAGATCCTTTTAAATTAAAAATGAAGTTTTAAATCAATCTAAAGTATAT
ATGAGTAAACTTGGTCTGACAGTTACCAATGCTTAATCAGTGAGGCACCT
ATCTCAGCGATCTGTCTATTTCGTTCATCCATAGTTGCCTGACTCCCCGT
CGTGTAGATAACTACGATACGGGACGGCTTACCATCTGGCCCCAGTGCTG
CAATGATACCGCGAGACCCACGCTCACCGGCTCCAGATTTATCAGCAATA
AACCAGCCAGCCGGAAGGGCCGAGCGCAGAAGTGGTCCTGCAACTTTATC
CGCCTCCATCCAGTCTATTAATTGTTGCCGGGAAGCTAGAGTAAGTAGTT
CGCCAGTTAATAGTTTGCGCAACGTTGTTGCCATTGCTACAGGCATCGTG
GTGTCACGCTCGTCGTTTGGTATGGCTTCATTCAGCTCCGGTTCCCAACG
ATCAAGGCGAGTTACATGATCCCCCATGTTGTGCAAAAAAGCGGTTAGCT
CCTTCGGTCCTCCGATCGTTGTCAGAAGTAAGTTGGCCCCAGTGTTATCA
CTCATGGTTATGGCAGCACTGCATAATTCTCTTACTGTCATGCCATCCGT
AAGATGCTTTTCTGTGACTGGTGAGTACTCAACCAAGTCATTCTGAGAAT
AGTGTATGCGGCGACCGAGTTGCTCTTGCCCGGCGTCAATACGGGATAAT
ACCGCGCCACATAGCAGAACTTTAAAAGTGCTCATCATTGGAAAACGTTC
TTCGGGGCGAAAACTCTCAAGGATCTTACCGCTGTTGACATCCAGTTCGA
TGTAACCCACTCGTGCACCCAACTGATCTTCAGCATCTTTTACTTTCACC
AGCCTTTCTGGGTGAGCAAAAACAGGAAGGCAAAATGCCGCAAAAAAGGG
AATAAGGGCGACACCGAAATGTTGAATACTCATACTCTTCCTTTTTCAAT
ATTATTGAAGCATTTATCAGGGTTATTGTCTCATGAGCGGATACATATTT
GAATGTATTTAGAAAAATAAACAAATAGGGGTTCCGCGCACATTTCCCCG
AAAAGTGCCACCTGACGTC

snRNA U6 gene is reported to be transcribed by RNA polymerase III, which produce short transcripts with uridines at the 3′ end. The genomic fragment of the snRNA U6 gene containing the promoter region was amplified by PCR using a set of primers,

5′-GGGGATCAGCGTTTGAGTAA-3′ (SEQ ID No: 14), and 5′-TAGGCCCCACCTCCTTCTAT-3′ (SEQ ID No: 15) and human placental DNA as a template. The product was purified and cloned into pCR plasmid vector using a TA cloning kit according to the supplier's protocol (Invitrogen). The BamHI, XhoI fragment containing the snRNA U6 gene was purified and cloned into nucleotide 1257 to 56 fragment of pcDNA3.1 (+) plasmid, which was amplified by PCR with a set of primer, 5′-TGCGGATCCAGAGCAGATTGTACTGAGAGT-3′ (SEQ ID No: 16) and 5′-CTCTATCTCGAGTGAGGCGGAAAGAACCA-3′ (SEQ ID No: 17). The ligated DNA was used for a template of PCR with primers,

5′-TTTAAGCTTGAAGACTATTTTTACATCAGGTTGTTTTTCT-3′ (SEQ ID No: 18) and 5′-TTTAAGCTTGAAGACACGGTGTTTCGTCCTTTCCACA-3′ (SEQ ID No: 19). The product was digested with HindIII, which was subsequently self-ligated to produce psiU6BX vector plasmid. For the control, psiU6BX-EGFP was prepared by cloning double-stranded oligonucleotides of 5′-CACCGAAGCAGCACGACTTCTTCTTCAAGAGAGAAGAAGTCGTGCTGCTTC-3′ (SEQ ID No: 20) and 5′-AAAAGAAGCAGCACGACTTCTTCTCTCTTGAAGAAGAAGTCGTGCTGCTTC-3′ (SEQ ID No: 21) into the BbsI site in the psiU6BX vector.

### INDUSTRIAL APPLICABILITY

The gene-expression analysis of PRC and PIN described herein, obtained through a combination of laser-capture dissection and genome-wide cDNA microarray, has identified specific genes as targets for cancer prevention and therapy. Based on the expression of a subset of these differentially expressed genes, the present invention provides a molecular diagnostic markers for identifying or detecting either or both of PRC and PIN.

The methods described herein are also useful in the identification of additional molecular targets for prevention, diagnosis and treatment of either or both of PRC and PIN. The data reported herein add to a comprehensive understanding of PRC, facilitate development of novel diagnostic strategies, and provide clues for identification of molecular targets for therapeutic drugs and preventative agents. Such information contributes to a more profound understanding of prostatic tumorigenesis, and provide indicators for developing novel strategies for diagnosis, treatment, and ultimately prevention of PRC.

The methods of the invention are particularly useful for detecting the expression of CCDC4, which is markedly elevated in prostate cancer as compared to non-cancerous prostate duct epithelium. Accordingly, this gene is useful as a diagnostic marker of prostate cancer and the proteins encoded thereby are useful in diagnostic assays of prostate cancer.

The present inventors have also shown that the expression of novel protein CCDC4 promotes cell growth whereas cell growth is suppressed by small interfering RNAs corresponding to the CCDC4 gene. These findings show that CCDC4 protein stimulates oncogenic activity. Thus, each of these novel oncoproteins is a useful target for the development of anti-cancer pharmaceuticals. For example, agents that block the expression of CCDC4, or prevent its activity find therapeutic utility as anti-cancer agents, particularly anti-cancer agents for the treatment of prostate cancers. Examples of such agents include antisense oligonucleotides, small interfering RNAs, and ribozymes against the CCDC4 gene, and antibodies that recognize CCDC4.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference in their entirety for all purposes.

1. A method of diagnosing either or both of PRC and PIN or a predisposition to developing either or both of PRC and PIN in a subject, comprising determining a level of expression of a PRC-associated gene in a patient derived biological sample, wherein an increase or decrease of said level compared to a normal control level of said gene indicates that said subject suffers from or is at risk of developing either or both of PRC and PIN.

2. The method of claim 1, wherein said PRC-associated gene is selected from the group consisting of PRC 1-88, wherein an increase in said level compared to a normal control level indicates said subject suffers from or is at risk of developing either or both of PRC and PIN.

3. The method of claim 2, wherein said increase is at least 10% greater than said normal control level.

4. The method of claim 1, wherein said PRC-associated gene is selected from the group consisting of PRC 89-295, wherein a decrease in said level compared to a normal control level indicates said subject suffers from or is at risk of developing either or both of PRC and PIN.

5. The method of claim 4, wherein said decrease is at least 10% lower than said normal control level.

6. The method of claim 1, wherein said method further comprises determining said level of expression of a plurality of PRC-associated genes.

7. The method of claim 1, wherein the expression level is determined by any one method select from group consisting of:
(a) detecting the mRNA of the PRC-associated genes,
(b) detecting the protein encoded by the PRC-associated genes, and
(c) detecting the biological activity of the protein encoded by the PRC-associated genes.

8. The method of claim 1, wherein said level of expression is determined by detecting hybridization of a PRC-associated gene probe to a gene transcript of said patient-derived biological sample.

9. The method of claim 8, wherein said hybridization step is carried out on a DNA array.

10. The method of claim 1, wherein said biological sample comprises an epithelial cell.

11. The method of claim 1, wherein said biological sample comprises either or both of PRC and PIN cell.

12. The method of claim 8, wherein said biological sample comprises an epithelial cell from a PRC or PIN.

13. A PRC reference expression profile, comprising a pattern of gene expression of two or more genes selected from the group consisting of PRC 1-295.

14. A PRC reference expression profile, comprising a pattern of gene expression of two or more genes selected from the group consisting of PRC 1-88.

15. A PRC reference expression profile, comprising a pattern of gene expression of two or more genes selected from the group consisting of PRC 89-295.

16. A method of screening for a compound for treating or preventing either or both of PRC and PIN, said method comprising the steps of:
a) contacting a test compound with a polypeptide encoded by a nucleic acid selected from the group consisting of PRC 1-295;
b) detecting the binding activity between the polypeptide and the test compound; and
c) selecting a compound that binds to the polypeptide.

17. A method of screening for a compound for treating or preventing either or both of PRC and PIN, said method comprising the steps of:
a) contacting a candidate compound with a cell expressing one or more marker genes, wherein the one or more marker genes is selected from the group consisting of PRC 1-295; and
b) selecting a compound that reduces the expression level of one or more marker genes selected from the group consisting of PRC 1-88, or elevates the expression level of one or more marker genes selected from the group consisting of PRC 89-295.

18. A method of screening for a compound for treating or preventing either or both of PRC and PIN, said method comprising the steps of:
a) contacting a test compound with a polypeptide encoded by a nucleic acid selected from the group consisting of PRC 1-295;
b) detecting the biological activity of the polypeptide of step (a); and
c) selecting a compound that suppresses the biological activity of the polypeptide encoded by a nucleic acid selected from the group consisting of PRC 1-88 in comparison with the biological activity detected in the absence of the test compound, or enhances the the biological activity of the polypeptide encoded by a nucleic acid selected from the group consisting of PRC 89-295 in comparison with the biological activity detected in the absence of the test compound.

19. The method of claim 17, wherein said cell comprises a either or both of PRC and PIN cell.

20. A method of screening for compound for treating or preventing either or both of PRC and PIN, said method comprising the steps of:
a) contacting a candidate compound with a cell into which a vector comprising the transcriptional regulatory region of one or more marker genes and a reporter gene that is expressed under the control of the transcriptional regulatory region has been introduced, wherein the one or more marker genes are selected from the group consisting of PRC 1-295;
b) measuring the activity of said reporter gene; and
c) selecting a compound that reduces the expression level of said reporter gene when said marker gene is an up-regulated marker gene selected from the group consisting of PRC 1-88 or that enhances the expression level of said reporter gene when said marker gene is a down-regulated marker gene selected from the group consisting of PRC 89-295, as compared to a control.

21. A kit comprising a detection reagent which binds to two or more nucleic acid sequences selected from the group consisting of PRC 1-295.

22. An array comprising a nucleic acid which binds to two or more nucleic acid sequences selected from the group consisting of PRC 1-295.

23. A method of treating or preventing either or both of PRC and PIN in a subject comprising the step of administering to said subject a compound that decreases the expression or activity of a polypeptide encoded by a gene selected from the group consisting of PRC 1-88.

24. A method of treating or preventing either or both of PRC and PIN in a subject comprising administering to said subject an antisense nucleic composition, said composition comprising a nucleotide sequence complementary to a coding sequence selected from the group consisting of PRC 1-88.

25. A method of treating or preventing either or both of PRC and PIN in a subject comprising administering to said subject a siRNA composition, wherein said composition reduces the expression of a nucleic acid sequence selected from the group consisting of PRC 1-88.

26. A method for treating or preventing either or both of PRC and PIN in a subject comprising the step of administering to said subject a pharmaceutically effective amount of an antibody or fragment thereof that binds to a protein encoded by any one gene selected from the group consisting of PRC 1-88.

27. A method of treating or preventing either or both of PRC and PIN in a subject comprising administering to said subject a vaccine comprising a polypeptide encoded by a nucleic acid selected from the group consisting of PRC 1-88 or an immunologically active fragment of said polypeptide, or a polynucleotide encoding the polypeptide.

28. A method of treating or preventing either or both of PRC and PIN in a subject comprising administering to said subject a compoud that increases the expression or activity of PRC 89-295.

29. A method of treating or preventing either or both of PRC and PIN in a subject comprising administering to said subject a pharmaceutically effective amount of polynucleotide select from group consisting of PRC 89-295, or polypeptide encoded thereby.

30. A method for treating or preventing either or both of PRC and PIN in a subject, said method comprising the step of administering a compound that is obtained by the method according to claims 16.

31. A composition for treating or preventing either or both of PRC and PIN, said composition comprising a pharmaceutically effective amount of an antisense polynucleotide or small interfering RNA against a polynucleotide select from group consisting of PRC 1-88 as an active ingredient, and a pharmaceutically acceptable carrier.

32. A composition for treating or preventing either or both of PRC and PIN, said composition comprising a pharmaceutically effective amount of an antibody or fragment thereof that binds to a protein encoded by any one gene selected from the group consisting of PRC 1-88 as an active ingredient, and a pharmaceutically acceptable carrier.

33. A composition for treating or preventing either or both of PRC and PIN, said composition comprising a pharmaceutically effective amount of polynucleotide select from group consisting of PRC 89-295, or polypeptide encoded thereby as an active ingredient, and a pharmaceutically acceptable carrier.

34. A composition for treating or preventing either or both of PRC and PIN, said composition comprising a pharmaceutically effective amount of the compound selected by the method of any one of claims 16-20 as an active ingredient, and a pharmaceutically acceptable carrier.

35. A method of diagnosing PRC or a predisposition to developing PRC in a subject, comprising determining a level of expression of a PRC-associated gene in a patient derived biological sample, wherein an increase or decrease of said level compared to a normal control level of said gene indicates that said subject suffers from or is at risk of developing PRC.

36. The method of claim 35, wherein said PRC-associated gene is selected from the group consisting of PRC 296-321, wherein an increase in said level compared to a normal control level indicates said subject suffers from or is at risk of developing PRC.

37. The method of claim 36, wherein said increase is at least 10% greater than said normal control level.

38. The method of claim 35, wherein said PRC-associated gene is selected from the group consisting of PRC 322-457, wherein a decrease in said level compared to a normal control level indicates said subject suffers from or is at risk of developing PRC.

39. The method of claim 38, wherein said decrease is at least 10% lower than said normal control level.

40. The method of claim 35, wherein said method further comprises determining said level of expression of a plurality of PRC-associated genes.

41. The method of claim 35, wherein the expression level is determined by any one method select from group consisting of:
(a) detecting the mRNA of the PRC-associated genes,
(b) detecting the protein encoded by the PRC-associated genes, and
(c) detecting the biological activity of the protein encoded by the PRC-associated genes,

42. The method of claim 35, wherein said level of expression is determined by detecting hybridization of a PRC-associated gene probe to a gene transcript of said patient-derived biological sample.

43. The method of claim 42, wherein said hybridization step is carried out on a DNA array.

44. The method of claim 35, wherein said biological sample comprises an epithelial cell.

45. The method of claim 35, wherein said biological sample comprises PRC cell.

46. The method of claim 42, wherein said biological sample comprises an epithelial cell from a PRC.

47. A PRC reference expression profile, comprising a pattern of gene expression of two or more genes selected from the group consisting of PRC 296-457.

48. A PRC reference expression profile, comprising a pattern of gene expression of two or more genes selected from the group consisting of PRC 296-321.

49. A PRC reference expression profile, comprising a pattern of gene expression of two or more genes selected from the group consisting of PRC 322-457.

50. A method of screening for a compound for treating or preventing PRC, said method comprising the steps of:
a) contacting a test compound with a polypeptide encoded by a nucleic acid selected from the group consisting of PRC 296-457;
b) detecting the binding activity between the polypeptide and the test compound; and
c) selecting a compound that binds to the polypeptide.

51. A method of screening for a compound for treating or preventing PRC, said method comprising the steps of:
a) contacting a candidate compound with a cell expressing one or more marker genes, wherein the one or more marker genes is selected from the group consisting of PRC 296-457; and
b) selecting a compound that reduces the expression level of one or more marker genes selected from the group consisting of PRC 296-321, or elevates the expression level of one or more marker genes selected from the group consisting of PRC 322-457.

52. A method of screening for a compound for treating or preventing PRC, said method comprising the steps of:
a) contacting a test compound with a polypeptide encoded by a nucleic acid selected from the group consisting of PRC 296-457;
b) detecting the biological activity of the polypeptide of step (a); and
c) selecting a compound that suppresses the biological activity of the polypeptide encoded by a nucleic acid selected from the group consisting of PRC 296-321 in comparison with the biological activity detected in the absence of the test compound, or enhances the the biological activity of the polypeptide encoded by a nucleic acid selected from the group consisting of PRC 322-457 in comparison with the biological activity detected in the absence of the test compound.

53. The method of claim 51, wherein said cell comprises a PRC cell.

54. A method of screening for compound for treating or preventing PRC, said method comprising the steps of:
a) contacting a candidate compound with a cell into which a vector comprising the transcriptional regulatory region of one or more marker genes and a reporter gene that is expressed under the control of the transcriptional regulatory region has been introduced, wherein the one or more marker genes are selected from the group consisting of PRC 296-457;
b) measuring the activity of said reporter gene; and
c) selecting a compound that reduces the expression level of said reporter gene when said marker gene is an up-regulated marker gene selected from the group consisting of PRC 296-321 or that enhances the expression level of said reporter gene when said marker gene is a down-regulated marker gene selected from the group consisting of PRC 322-457, as compared to a control.

55. A kit comprising a detection reagent which binds to two or more nucleic acid sequences selected from the group consisting of PRC 296-457.

56. An array comprising a nucleic acid which binds to two or more nucleic acid sequences selected from the group consisting of PRC 296-457.

57. A method of treating or preventing PRC in a subject comprising the step of administering to said subject a compound that decreases the expression or activity of a polypeptide encoded by a gene selected from the group consisting of PRC 296-321.

58. A method of treating or preventing PRC in a subject comprising administering to said subject an antisense composition, said composition comprising a nucleotide sequence complementary to a coding sequence selected from the group consisting of PRC 296-321.

59. A method of treating or preventing PRC in a subject comprising administering to said subject a siRNA composition, wherein said composition reduces the expression of a nucleic acid sequence selected from the group consisting of PRC 296-321.

60. A method for treating or preventing PRC in a subject comprising the step of administering to said subject a pharmaceutically effective amount of an antibody or fragment thereof that binds to a protein encoded by any one gene selected from the group consisting of PRC 296-321.

61. A method of treating or preventing PRC in a subject comprising administering to said subject a vaccine comprising a polypeptide encoded by a nucleic acid selected from the group consisting of PRC 296-321 or an immunologically active fragment of said polypeptide, or a polynucleotide encoding the polypeptide.

62. A method of treating or preventing PRC in a subject comprising administering to said subject a compoud that increases the expression or activity of PRC 322-457.

63. A method of treating or preventing PRC in a subject comprising administering to said subject a pharmaceutically effective amount of polynucleotide select from group consisting of PRC 322-457, or polypeptide encoded thereby.

64. A method for treating or preventing PRC in a subject, said method comprising the step of administering a compound that is obtained by the method according to claims 50.

65. A composition for treating or preventing PRC, said composition comprising a pharmaceutically effective amount of an antisense polynucleotide or small interfering RNA against a polynucleotide select from group consisting of PRC 296-321 as an active ingredient, and a pharmaceutically acceptable carrier.

66. A composition for treating or preventing PRC, said composition comprising a pharmaceutically effective amount of an antibody or fragment thereof that binds to a protein encoded by any one gene selected from the group consisting of PRC 296-321 as an active ingredient, and a pharmaceutically acceptable carrier.

67. A composition for treating or preventing PRC, said composition comprising a pharmaceutically effective amount of polynucleotide select from group consisting of PRC 322-457, or polypeptide encoded thereby as an active ingredient, and a pharmaceutically acceptable carrier.

68. A composition for treating or preventing PRC, said composition comprising a pharmaceutically effective amount of the compound selected by the method of any one of claims 50-54 as an active ingredient, and a pharmaceutically acceptable carrier.

69. A method of diagnosing PIN or a predisposition to developing PIN in a subject, comprising determining a level of expression of a PRC-associated gene in a patient derived biological sample, wherein an increase or decrease of said level compared to a normal control level of said gene indicates that said subject suffers from or is at risk of developing PIN.

70. The method of claim 69, wherein said PRC-associated gene is selected from the group consisting of PRC 458-537, wherein an increase in said level compared to a normal control level indicates said subject suffers from or is at risk of developing PIN.

71. The method of claim 70, wherein said increase is at least 10% greater than said normal control level.

72. The method of claim 69, wherein said PRC-associated gene is selected from the group consisting of PRC 538-692, wherein a decrease in said level compared to a normal control level indicates said subject suffers from or is at risk of developing PIN.

73. The method of claim 72, wherein said decrease is at least 10% lower than said normal control level.

74. The method of claim 69, wherein said method further comprises determining said level of expression of a plurality of PRC-associated genes.

75. The method of claim 69, wherein the expression level is determined by any one method select from group consisting of:
(a) detecting the mRNA of the PRC-associated genes,
(b) detecting the protein encoded by the PRC-associated genes, and
(c) detecting the biological activity of the protein encoded by the PRC-associated genes.

76. The method of claim 69, wherein said level of expression is determined by detecting hybridization of a PRC-associated gene probe to a gene transcript of said patient-derived biological sample.

77. The method of claim 76, wherein said hybridization step is carried out on a DNA array.

78. The method of claim 69, wherein said biological sample comprises an epithelial cell.

79. The method of claim 69, wherein said biological sample comprises PIN cell.

80. The method of claim 76, wherein said biological sample comprises an epithelial cell from a PIN.

81. A PRC reference expression profile, comprising a pattern of gene expression of two or more genes selected from the group consisting of PRC 458-692.

82. A PRC reference expression profile, comprising a pattern of gene expression of two or more genes selected from the group consisting of PRC 458-537.

83. A PRC reference expression profile, comprising a pattern of gene expression of two or more genes selected from the group consisting of PRC 538-692.

84. A method of screening for a compound for treating or preventing PIN or preventing PRC, said method comprising the steps of:
a) contacting a test compound with a polypeptide encoded by a nucleic acid selected from the group consisting of PRC 458-692;
b) detecting the binding activity between the polypeptide and the test compound; and
c) selecting a compound that binds to the polypeptide.

85. A method of screening for a compound for treating or preventing PIN or preventing PRC, said method comprising the steps of:
a) contacting a candidate compound with a cell expressing one or more marker genes, wherein the one or more marker genes is selected from the group consisting of PRC 458-692; and
b) selecting a compound that reduces the expression level of one or more marker genes selected from the group consisting of PRC 458-537, or elevates the expression level of one or more marker genes selected from the group consisting of PRC 538-692.

86. A method of screening for a compound for treating or preventing PIN or preventing PRC, said method comprising the steps of:
a) contacting a test compound with a polypeptide encoded by a nucleic acid selected from the group consisting of PRC 458-692;
b) detecting the biological activity of the polypeptide of step (a); and
c) selecting a compound that suppresses the biological activity of the polypeptide encoded by a nucleic acid selected from the group consisting of PRC 458-537 in comparison with the biological activity detected in the absence of the test compound, or enhances the the biological activity of the polypeptide encoded by a nucleic acid selected from the group consisting of PRC 538-692 in comparison with the biological activity detected in the absence of the test compound.

87. The method of claim 85, wherein said cell comprises a PIN cell.

88. A method of screening for compound for treating or preventing PIN, or preventing PRC, said method comprising the steps of:
a) contacting a candidate compound with a cell into which a vector comprising the transcriptional regulatory region of one or more marker genes and a reporter gene that is expressed under the control of the transcriptional regulatory region has been introduced, wherein the one or more marker genes are selected from the group consisting of PRC 458-692;
b) measuring the activity of said reporter gene; and
c) selecting a compound that reduces the expression level of said reporter gene when said marker gene is an up-regulated marker gene selected from the group consisting of PRC 458-537 or that enhances the expression level of said reporter gene when said marker gene is a down-regulated marker gene selected from the group consisting of PRC 538-692, as compared to a control.

89. A kit comprising a detection reagent which binds to two or more nucleic acid sequences selected from the group consisting of PRC 458-692.

90. An array comprising a nucleic acid which binds to two or more nucleic acid sequences selected from the group consisting of PRC 458-692.

91. A method of treating or preventing PIN or preventing PRC in a subject comprising the step of administering to said subject a compound that decreases the expression or activity of a polypeptide encoded by a gene selected from the group consisting of PRC 458-537.

92. A method of treating or preventing PIN or preventing PRC in a subject comprising administering to said subject an antisense composition, said composition comprising a nucleotide sequence complementary to a coding sequence selected from the group consisting of PRC 458-537.

93. A method of treating or preventing PIN or preventing PRC in a subject comprising administering to said subject a siRNA composition, wherein said composition reduces the expression of a nucleic acid sequence selected from the group consisting of PRC 458-537.

94. A method for treating or preventing PIN or preventing PRC in a subject comprising the step of administering to said subject a pharmaceutically effective amount of an antibody or fragment thereof that binds to a protein encoded by any one gene selected from the group consisting of PRC 458-537.

95. A method of treating or preventing PIN or preventing PRC in a subject comprising administering to said subject a vaccine comprising a polypeptide encoded by a nucleic acid selected from the group consisting of PRC 458-537 or an immunologically active fragment of said polypeptide, or a polynucleotide encoding the polypeptide.

96. A method of treating or preventing PIN or preventing PRC in a subject comprising administering to said subject a compoud that increases the expression or activity of PRC 538-692.

97. A method of treating or preventing PIN or preventing PRC in a subject comprising administering to said subject a pharmaceutically effective amount of polynucleotide select from group consisting of PRC 538-692, or polypeptide encoded thereby.

98. A method for treating or preventing PIN or preventing PRC in a subject, said method comprising the step of administering a compound that is obtained by the method according to claims 84.

99. A composition for treating or preventing PIN or preventing PRC, said composition comprising a pharmaceutically effective amount of an antisense polynucleotide or small interfering RNA against a polynucleotide select from group consisting of PRC 458-537 as an active ingredient, and a pharmaceutically acceptable carrier.

100. A composition for treating or preventing PIN or preventing PRC, said composition comprising a pharmaceutically effective amount of an antibody or fragment thereof that binds to a protein encoded by any one gene selected from the group consisting of PRC 458-537 as an active ingredient, and a pharmaceutically acceptable carrier.

101. A composition for treating or preventing PIN or preventing PRC, said composition comprising a pharmaceutically effective amount of polynucleotide select from group consisting of PRC 538-692, or polypeptide encoded thereby as an active ingredient, and a pharmaceutically acceptable carrier.

102. A composition for treating or preventing PIN or preventing PRC, said composition comprising a pharmaceutically effective amount of the compound selected by the method of any one of claims 84-88 as an active ingredient, and a pharmaceutically acceptable carrier.

103. A substantially pure polypeptide selected from the group consisting of:
(a) a polypeptide comprising the amino acid sequence of SEQ ID NO: 2 or 4;
(b) a polypeptide that comprises the amino acid sequence of SEQ ID NO: 2 or 4 or a sequence having at least about 80% homology to SEQ ID NO: 2 or 4; and
(c) a polypeptide encoded by a polynucleotide that hybridizes under stringent conditions to a polynucleotide consisting of the nucleotide sequence of SEQ ID NO:1 or 3, wherein the polypeptide has a biological activity equivalent to a polypeptide consisting of the amino acid sequence of any one of SEQ ID NO: 2 or 4.

104. An isolated polynucleotide encoding the polypeptide of claim 103.

105. A vector comprising the polynucleotide of claim 104.

106. A host cell harboring the polynucleotide of claim 104 or the vector of claim 105.

107. A method for producing the polypeptide of claim 103, said method comprising the steps of:
(a) culturing a host cell comprising a polynucleotide encoding the polypeptide or a vector comprising a polynucleotide encoding the polypeptide;
(b) allowing the host cell to express the polypeptide; and
(c) collecting the expressed polypeptide.

108. An antibody binding to the polypeptide of claim 103.

109. A polynucleotide that is complementary to the polynucleotide encoding the polypeptide of claim 103 or to the complementary strand thereof and that comprises at least 15 nucleotides.

110. An antisense polynucleotide or small interfering RNA against the polynucleotide encoding the polypeptide of claim 103.

111. The small interfering RNA of claim 110, wherein the sense strand thereof comprises the nucleotide sequence of SEQ ID NO: 8 as the target sequence and less than 75 nucleotides in length.

112. A method for diagnosing prostate cancer, said method comprising the steps of:
(a) detecting the expression level of the gene encoding the amino acid sequence of SEQ ID NO: 2 or 4 in a biological sample; and
(b) relating an elevation of the expression level to the disease.

113. The method of claim 112, wherein the expression level is detected by any one of the method select from the group consisting of:
(a) detecting the mRNA encoding the amino acid sequence of SEQ ID NO: 2 or 4,
(b) detecting the protein comprising the amino acid sequence of SEQ ID NO: 2 or 4, and
(c) detecting the biological activity of the protein comprising the amino acid sequence of SEQ ID NO: 2 or 4.

114. A method of screening for a compound for treating or preventing prostate cancer, said method comprising the steps of:
(a) contacting a test compound with a polypeptide selected from the group consisting of:
(1) a polypeptide comprising the amino acid sequence of SEQ ID NO: 2 or 4;
(2) a polypeptide that comprises the amino acid sequence of SEQ ID NO: 2 or 4 or a sequence having at least about 80% homology to SEQ ID NO: 2 or 4; and
(3) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4;
(b) detecting the binding activity between the polypeptide and the test compound; and
(c) selecting a compound that binds to the polypeptide.

115. A method of screening for a compound for treating or preventing prostate cancer, said method comprising the steps of:
(a) contacting a test compound with a polypeptide selected from the group consisting of:
(1) a polypeptide comprising the amino acid sequence of SEQ ID NO: 2 or 4;
(2) a polypeptide that comprises the amino acid sequence of SEQ ID NO: 2 or 4 or a sequence having at least about 80% homology to SEQ ID NO: 2 or 4; and
(3) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4;
(b) detecting the biological activity of the polypeptide of step (a); and
(c) selecting a compound that suppresses the biological activity of the polypeptide in comparison with the biological activity detected in the absence of the test compound.

116. The method of claim 115, wherein the biological activity is cell-proliferating activity.

117. A method of screening for a compound for treating or preventing prostate cancer, said method comprising the steps of:
(a) contacting a test compound with a cell expressing one or more polynucleotides comprising the nucleotide sequence of SEQ ID NO: 1 or 3; and
(b) selecting a compound that reduces the expression level of one or more polynucleotides comprising the nucleotide sequence of SEQ ID NO: 1 or 3 in comparison with the expression level detected in the absence of the test compound.

118. The method of claim 117, wherein the cell is prostate cancer cell.

119. A method of screening for a compound for treating or preventing prostate cancer, said method comprising the steps of:
(a) contacting a test compound with a cell into which a vector comprising the transcriptional regulatory region of one or more marker genes and a reporter gene that is expressed under the control of the transcriptional regulatory region has been introduced, wherein the one or more marker genes comprise any one of nucleotide sequence selected from the group consisting of SEQ ID NO: 1 and 3,
(b) measuring the expression level or activity of said reporter gene; and
(c) selecting a compound that reduces the expression level or activity of said reporter gene as compared to a control.

120. A composition for treating or preventing prostate cancer, said composition comprising a pharmaceutically effective amount of an antisense polynucleotide or small interfering RNA against a polynucleotide and pharmaceutically acceptable carrier, wherein the polynucleotide encodes a polypeptide selected from the group consisting of:
(a) a polypeptide that comprises the amino acid sequence of SEQ ID NO: 2 or 4;
(b) a polypeptide that comprises the amino acid sequence of SEQ ID NO: 2 or 4 in which one or more amino acids are substituted, deleted, inserted and/or added and that has a biological activity equivalent to a protein consisting of the amino acid sequence of SEQ ID NO: 2 or 4; and
(c) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4 as an active ingredient, and a pharmaceutically acceptable carrier.

121. The composition of claim 120, wherein said small interfering RNA comprises the nucleotide sequence of SEQ ID NO: 8 as the target sequence.

122. The composition of claim 121, said siRNA has the general formula 5′-[A]-[B]-[A′]-3′, wherein [A] is a ribonucleotide sequence coresponding to the nucleotide sequence of SEQ ID NO: 8,
[B] is a ribonucleotide sequence consisting of 3 to 23 nucleotides, and
[A′] is a ribonucleotide sequence consisting of the complementary sequence of [A].

123. The composition of claim 120, wherein said composition comprises a transfection-enhancing agent.

124. A composition for treating or preventing prostate cancer, said composition comprising a pharmaceutically effective amount of an antibody against a polypeptide selected from the group consisting of:
(a) a polypeptide that comprises the amino acid sequence of SEQ ID NO: 2 or 4;
(b) a polypeptide that comprises the amino acid sequence of SEQ ID NO: 2 or 4 in which one or more amino acids are substituted, deleted, inserted and/or added and that has a biological activity equivalent to a protein consisting of the amino acid sequence of SEQ ID NO: 2 or 4; and
(c) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4 as an active ingredient, and a pharmaceutically acceptable carrier.

125. A composition for treating or preventing prostate cancer, said composition comprising a pharmaceutically effective amount of the compound selected by the method of claim 114 as an active ingredient, and a pharmaceutically acceptable carrier.

126. A method for treating or preventing prostate cancer, said method comprising the step of administering a pharmaceutically effective amount of an antisense polynucleotide, or small interfering RNA against a polynucleotide encoding a polypeptide selected from the group consisting of:
(1) a polypeptide comprising the amino acid sequence of SEQ ID NO: 2 or 4;
(2) a polypeptide that comprises the amino acid sequence of SEQ ID NO: 2 or 4 in which one or more amino acids are substituted, deleted, inserted and/or added and that has a biological activity equivalent to a protein consisting of the amino acid sequence of SEQ ID NO: 2 or 4; and
(3) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4.

127. The method of claim 126, wherein said siRNA comprises the nucleotide sequence of SEQ ID NO: 8 as the target sequence.

128. The method of claim 127, said siRNA has the general formula 5′-[A]-[B]-[A′]-3′, wherein [A] is a ribonucleotide sequence coresponding to the nucleotide sequence of SEQ ID NO: 8,
[B] is a ribonucleotide sequence consisting of 3 to 23 nucleotides, and
[A′] is a ribonucleotide sequence consisting of the complementary sequence of [A].

129. The method of claim 126, wherein said composition comprises a transfection-enhancing agent.

130. A method for treating or preventing prostate cancer, said method comprising the step of administering a pharmaceutically effective amount of an antibody against a polypeptide selected from the group consisting of:
(a) a polypeptide that comprises the amino acid sequence of SEQ ID NO: 2 or 4;
(b) a polypeptide that comprises the amino acid sequence of SEQ ID NO: 2 or 4 in which one or more amino acids are substituted, deleted, inserted and/or added and that has a biological activity equivalent to a protein consisting of the amino acid sequence of SEQ ID NO: 2 or 4; and
(c) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4.

131. A method for treating or preventing prostate cancer, said method comprising the step of administering a pharmaceutically effective amount of a compound selected by the method of claims 114.

132. A method for treating or preventing prostate cancer, said method comprising the step of administering a pharmaceutically effective amount of a polypeptide selected from the group consisting of (a)-(c), or a polynucleotide encoding the polypeptide:
(a) a polypeptide comprising the amino acid sequence of SEQ ID NO: 2 or 4 or fragment thereof;
(b) a polypeptide that comprises the amino acid sequence of SEQ ID NO: 2 or 4 in which one or more amino acids are substituted, deleted, inserted and/or added and that has a biological activity equivalent to a protein consisting of the amino acid sequence of SEQ ID NO: 2 or 4 in which one or more amino acids are substituted, deleted, inserted and/or added and that has a biological activity equivalent to a protein consisting of the amino acid sequence of SEQ ID NO: 2 or 4;
(c) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4, or fragment thereof.

133. A method for inducing an anti tumor immunity, said method comprising the step of contacting a polypeptide selected from the group consisting of (a)-(c) with antigen presenting cells, or introducing a polynucleotide encoding the polypeptide or a vector comprising the polynucleotide to antigen presenting cells:
(a) a polypeptide comprising the amino acid sequence of SEQ ID NO: 2 or 4, or fragment thereof;
(b) a polypeptide that comprises the amino acid sequence of SEQ ID NO: 2 or 4 in which one or more amino acids are substituted, deleted, inserted and/or added and that has a biological activity equivalent to a protein consisting of the amino acid sequence of SEQ ID NO: 2 or 4;
(c) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4, or fragment thereof.

134. The method for inducing an anti tumor immunity of claim 133, wherein the method further comprising the step of administering the antigen presenting cells to a subject.

135. A pharmaceutical composition for treating or preventing prostate cancer, said composition comprising a pharmaceutically effective amount of polypeptide selected from the group of (a)-(c), or a polynucleotide encoding the polypeptide:
(a) a polypeptide comprising the amino acid sequence of SEQ ID NO: 2 or 4, or fragment thereof;
(b) a polypeptide that comprises the amino acid sequence of SEQ ID NO: 2 or 4 in which one or more amino acids are substituted, deleted, inserted and/or added and that has a biological activity equivalent to a protein consisting of the amino acid sequence of SEQ ID NO: 2 or 4;
(c) a polypeptide encoded by a polynucleotide that hybridizes under stringent conditions to a polynucleotide consisting of the nucleotide sequence of SEQ ID NO: 1 or 3, wherein the polypeptide has a biological activity equivalent to a polypeptide consisting of the amino acid sequence of SEQ ID NO: 2 or 4, or fragment thereof as an active ingredient, and a pharmaceutically acceptable carrier.

136. The pharmaceutical composition of claim 135, wherein the polynucleotide is incorporated in an expression vector.

137. A diagnostic agent comprises an oligonucleotide that hybridizes to the polynucleotide encoding the polypeptide of claim 103, or an antibody that binds to the polypeptide of claim 103.

138. A double-stranded molecule comprising a sense strand and an antisense strand, wherein the sense strand comprises a ribonucleotide sequence corresponding to SEQ ID NO: 8, and wherein the antisense strand comprises a ribonucleotide sequence which is complementary to said sense strand, wherein said sense strand and said antisense strand hybridize to each other to form said double-stranded molecule, and wherein said double-stranded molecule, when introduced into a cell expressing the CCDC4 gene, inhibits expression of said gene.

139. The double-stranded molecule of claim 138, wherein said sense strand comprises from about 19 to about 25 contiguous nucleotides from SEQ ID No: 1.

140. The double-stranded molecule of claim 138, wherein said sense strand consists of the ribonucleotide sequence corresponding to SEQ ID NO: 8.

141. The double-stranded molecule of claim 138, wherein a single ribonucleotide transcript comprises the sense strand and the antisense strand, said double-stranded molecule further comprising a single-stranded ribonucleotide sequence linking said sense strand and said antisense strand.

142. A vector encoding the double-stranded molecule of claim 138.

143. The vector of claim 142, wherein the vector encodes a transcript having a secondary structure, wherein the transcript comprises the sense strand and the antisense strand.

144. The vector of claim 142, wherein the transcript further comprises a single-stranded ribonucleotide sequence linking said sense strand and said antisense strand.
